(19) United States
(12) Patent Application Publication
(10) Pub. No.: US 2024/0267067 A1
(43) Pub. Date: Aug. 8, 2024

(54) SELF-TUNABLE IoT DEVICE AND RADIATING SYSTEM BASED ON NON-RESONANT RADIATION ELEMENTS

(71) Applicant: IGNION, S.L., Barcelona (ES)

(72) Inventors: Jaume ANGUERA, Vinaròs (ES); Aurora ANDÚJAR, Barcelona (ES); Carles PUENTE, Barcelona (ES); Rosa Maria MATEOS, Barberà del Vallès (ES); Jaap GROOT, Barcelona (ES); José Luis LEIVA, Barcelona (ES); Elena GARCÍA, Barcelona (ES)

(21) Appl. No.: 18/640,890

(22) Filed: Apr. 19, 2024

Related U.S. Application Data
(63) Continuation of application No. PCT/EP2022/079487, filed on Oct. 21, 2022.
(60) Provisional application No. 63/270,722, filed on Oct. 22, 2021.
(60) Provisional application No. 63/284,705, filed on Dec. 1, 2021.

(30) Foreign Application Priority Data
Oct. 22, 2021 (EP) 21382956.7
Dec. 1, 2021 (EP) 21211848.3

(51) Int. Cl. H04B 1/04; H01Q 5/335; H04B 1/18

(52) U.S. Cl. CPC H04B 1/0458; H01Q 5/335; H04B 1/18

(57) ABSTRACT

A wireless device or wireless communications system comprises a transceiver module, a processor, an energy-supplying device, and a radiating system comprising a non-resonant element, a ground plane element, and a wireless matching core (WMC). The wireless device may further comprise an intelligent database or look-up table and at least one sensor. The database contains information about the environment where the device is going to work and/or about the material of the objects where the device can be mounted and/or form factors of the device, and it is used for configuring the operation mode of the device. The ground plane element may be a ground plane layer printed on a printed circuit board. The WMC can be a universal matching network, a self-adaptive matching network, or a self-adaptive universal matching network. The non-resonant element can be a radiation booster.

### CROSS REFERENCE TO RELATED APPLICATIONS

This application is a bypass continuation application of PCT International Application No. PCT/EP2022/079487, filed on Oct. 21, 2022, which claims priority to European Application No. 21382956.7, filed on Oct. 22, 2021, U.S. Provisional Application No. 63/270,722, filed Oct. 22, 2021, European Application No. 21211848.3, filed on Dec. 1, 2021, and U.S. Provisional Application No. 63/284,705, filed on Dec. 1, 2021, the entire contents of which are hereby incorporated by reference.

### TECHNICAL FIELD

The present disclosure relates to the field of wireless devices or wireless communications systems and devices and, in particular, to the Internet of Things (IoT) class of systems and devices such as for instance those for the applications of asset-tracking, smart meters, health monitoring, smart home and domotics, smart cities, IoT sensors and alarms, which operate in at least one frequency band comprised within at least one frequency region, for very different platforms and environments.

### BACKGROUND

Wireless devices capable of operating in multiple radio scenarios and in changing environments are required for many applications. Having a single wireless communications system capable of operating in multiple, different wireless devices would be an advantageous solution as it would provide a scalable non-customized solution to be easily integrated into different devices. There exists in literature antenna tuning techniques for avoiding degradation of the communications system performance due to changes in the environment in the vicinity of the antenna, like for example the tuning and optimization technique provided in US 2013/0122836 A1. Other tunable antenna techniques are disclosed in US 2017/0244166 A1, U.S. Pat. No. 7,215,283 B2 or U.S. Pat. No. 8,884,835 B2. Usually, those tuning circuits comprise switches. Regarding switches, a switch contains one or more inputs and one or more outputs, even if a switch normally is bidirectional, meaning that a signal can travel from an input to an output and from an output to an input. The inputs normally are named poles P and the outputs throughs T. So, an MPNT switch is a switch containing M poles and N throughs, M and N being integer numbers. If the switch contains just one pole P and two throughs T, the switch is named an SPDT or an SP2T switch (single pole-double through), and similarly with other input/output configurations, as for example SPNT (single pole-multiple throughs), as for instance SP4T (one pole-four throughs), or DP6T (double pole-6 throughs). There also exist multiple path or multi-path switches able to route or connect a pole to two or more throughs simultaneously.

Some literature provides assemblies providing tuning capability, as for example U.S. Pat. No. 10,141,655 or “QM13021 Configurable Impedance Tuner” (https://www.gorvo.com/products/p/QM13021). Those antenna systems comprise conventional antennas that are bulky in terms of size while they are partially customized. On the other hand, a radiating system comprising a radiation booster, a matching network (hereinafter also abbreviated as a MN) and a ground plane, like those described in, for example, the patent documents U.S. Pat. No. 8,203,492 B2; U.S. Pat. No. 8,237,615 B2; U.S. Pat. No. 9,960,478 B2; WO 2014/012842 A1 and WO2019/008171 A1, provide an advantageous solution as no customization of the antenna component is needed. Those radiation booster systems can be adapted to different platform sizes by changing the matching network. For instance, they can be adapted to different ground plane dimensions or clearance dimensions, see for instance “RUN mXTEND™—clearance length and ground plane length experiments” (Design center: Ignion^{NN}, January 2021, https://ignion.io/files/AN_NN02-224_LengthClearance.pdf) and “ALL mXTEND™: impact of clearance size and PCB size on efficiency” (Design center: Ignion^{NN}, February 2021, https://ignion.io/files/AN_NN02-220_Clearance-Length_GP.pdf). Those documents show that those radiation boosters and antenna components can be matched by a matching network with a fixed topology but changing several of the lumped circuit components, so the overall radiofrequency system still requires to be partially customized for every ground plane and clearance size. In summary, all those solutions are still at least partially customized, requiring a significant engineering time and effort when adapting those solutions to a specific device. Therefore, a non-customized radiating system able to match different devices and/or able to match a device in changing environments at their operating frequencies would be an advantageous solution.

Regarding circuit manufacturing techniques, some technologies for developing tunable antennas and tuning circuits are available for example, in the form of RoG (Radio on Glass) by 3DGS manufacturer (https://3dgsinc.com/). According to 3DGS, such a manufacturing technique is able to provide antenna in package solutions and to manufacture high performance/high-Q 3D RF passive components. A RoG or other low-loss/high Q packaging techniques can be advantageously used to embed some or all or the needed passive components into a package.

### SUMMARY

The present disclosure relates to a wireless device or wireless communications system for the use in, for instance, the Internet of Things (IoT) class of systems and devices all those systems or devices being capable of operating in at least one frequency band comprised within at least one frequency region, in very different platforms, environments and devices. Examples of different platforms, environments and devices are asset-tracking (FIG. 3), smart meters, health monitoring, wearables, smart home and domotics, smart cities, IoT sensors and alarms (FIG. 7), all of those featuring different needs in terms of device size, installation (FIG. 8) and frequency range of operation (FIG. 6); the wireless device may also be an assembly that can be integrated in another wireless device such as, e.g., any one of the previously mentioned or others. There exists multiple environmental factors that may have an impact in the performance of the device or system, as for instance the material of the object or platform where the device is going to be mounted, the noise detected in the environment, whether the environment is an outdoor or an indoor environment, and the climatic conditions such as humidity or temperature. Typical materials of the objects where the wireless device or wireless communications system is going to be mounted on are wood, metal, concrete, ceramic bricks, and biological tissue (human or animal), but there is no limitation for those in the context of the present disclosure (FIG. 8).

A wireless device or wireless communications system according to the disclosure comprises a radiating system that comprises: a non-resonant element, a ground plane element, a wireless matching core, hereinafter as well WMC. The device or system also comprises a transceiver module, also named transmission/reception RF module, a processor and a means of supplying energy or power supply, being for example a battery, a solar panel, an ultra-capacitor, an energy harvesting element or an electricity-based system, but not limited to those elements. In some embodiments, the ground plane element is a ground plane layer printed on a printed circuit board or PCB. A WMC is an element that can comprise one or more sections that optimizes the transfer of RF energy from the radiating system to the transceiver and vice-versa. A non-resonant element is, in the context of this disclosure, an element that does not resonate at one or more of the frequency regions of operation of the radiating system when mounted within the wireless device and its input impedance is measured while being electrically substantially disconnected and uncoupled from the WMC, so that the WMC does not substantially affect the impedance of the non-resonant element. In particular, a non-resonant element within the present disclosure does not resonate within the lowest frequency range of operation of the radiating system when disconnected from the WMC. In some embodiments, a non-resonant element within the present disclosure does not resonate within the two lowest non-adjacent frequency ranges of operation of the radiating system. In addition, a non-resonant element according to the present disclosure also injects or boosts wireless energy, i.e., RF energy in a ground plane element, so that such a ground plane is capable of contributing to the transmission and reception of electromagnetic signals through one or mode radiation current modes supported on a surface of the ground plane. In the context of this disclosure, examples of non-resonant elements include an electrically conductive element, a dielectric element, a slot, gap or hole in a conductive or dielectric element or a combination of all those, all of them being small enough compared to the longest operating wavelength so its lowest resonant frequency is outside and above the lowest frequency range of operation of the radiating system. Some mechanisms for making sure a non-resonant element does not resonate in the low frequency regions include shaping the element through a simple geometry with a low complexity factor and including low permittivity dielectrics into the element. A low complexity means a Complexity Factor F21, F32 as defined in U.S. Pat. No. 9,130,267B2 (the entire specification being incorporated by reference herein and in particular col.11-17 and its associated figures). While in U.S. Pat. No. 9,130,267 such Complexity Factors are applied to an antenna element, in the present disclosure they are applied to non-resonant elements and even to non-radiating elements such as a radiation booster. Some characteristic low Complexity Factors that contribute the non-resonant elements to resonate outside and above the lowest frequency range of operation are factors smaller than 1.5, or even smaller than 1.3, 1.2, 1.1 or even smaller than 1.05.

A low dielectric permittivity means in the present disclosure a relative permittivity smaller than 8, while preferably smaller than 4, 3, 2.5, 2 and 1.5.

In the context of the present disclosure, a radiating system is a reciprocal system that is capable to both transmit and receive electromagnetic waves to a far field distance.

In the context of the present disclosure, a length L is defined as a first bigger dimension of a parallelepiped, a width W is defined as a second bigger dimension of the parallelepiped and the thickness H is defined as the smallest dimension of the parallelepiped, being L×W×H the dimensions of the parallelepiped. If the thickness H is zero or substantially close to zero then the parallelepiped is a planar structure, more particularly a parallelogram characterized by L×W dimensions.

In some radiating system embodiments, the non-resonant element is a type of an antenna booster, also named radiation booster. In the context of this disclosure, an antenna booster or radiation booster refers for instance to a radiation booster described and defined in the patent documents U.S. Pat. No. 8,203,492 B2, U.S. Pat. No. 8,237,615 B2, U.S. Pat. No. 9,379,443 B2, U.S. Pat. No. 9,960,478 B2, U.S. Pat. No. 9,331,389 B2, WO 2014/012842 A1 and WO2019/008171 A1 incorporated by reference herein, and in particular col.7-9 from the U.S. Pat. No. 8,203,492 B2 and col. 5-6 from the U.S. Pat. No. 9,331,389 B2 and the associated figures and embodiments. A radiation booster according to the present disclosure includes a non-resonant element for a radiating system with a maximum size smaller than the longest operating wavelength divided by 20. In some embodiments, a radiation booster features a maximum size smaller than 1/30th of the longest operating wavelength of a radiating system. A maximum size is for instance the diameter of the smallest sphere that circumscribes the radiation booster. A radiation booster contributes minimally to radiation by itself but mostly transfer most of the RF energy from an RF transmitter to a conductive ground plane or ground element, so that the ground element radiates and receives electromagnetic waves in a reciprocal process. Due to the minimal contribution to radiation, a radiation booster can be considered as a non-radiating element, so that effectively the radiation from the radiating system is obtained from a ground element.

The WMC, comprises in some embodiments a universal matching network, hereinafter UMN, a universal matching network being a matching network comprising at least a matching element that enables operation within different wireless devices or radiating systems (FIG. 7). A matching element is, according to this disclosure, an element that provides impedance matching, preferably at the end or output of a WMC, of a radiating system that includes the WMC. Also, according to this disclosure, such a UMN operates in at least one frequency band comprised in at least one frequency region of operation. A single UMN enables wireless operation in a plurality of different devices or radiating systems featuring for example, different sizes and/or shapes, including for instance ground planes with different form factors (FIG. 7). In addition, such a plurality of different devices and radiating systems might comprise different non-resonant elements, include ground plane elements of different shapes and/or sizes, and/or adapt to different operability requirements in terms of frequency bands of operation (FIG. 6). Featuring a single UMN across a variety of different products and form factor makes the engineering of the device much simpler, faster, predictable and more reliable as no matching network is to be customized for every single product and form factor.

In other embodiments, the WMC comprises a self-adaptive matching network, hereinafter SMN, a self-adaptive matching network being a matching network comprising at least a matching element that allows the device to adapt to a diversity of scenarios, use contexts and environments (FIG. 8). In some other embodiments, the WMC comprises a self-adaptive universal matching network, hereinafter as well SUMN, a self-adaptive universal matching network being a self-adaptive and a universal matching network at the same time, that is, a single circuital network capable of adapting a radiating system to different devices with different form factors, working in different frequency bands and standards and being used in diversity of configurations and mounting scenarios.

In some embodiments, a wireless device or wireless communications system according to the disclosure comprises an intelligent database or look-up table and one or more sensors (FIG. 5B). In those, the WMC is tuned according to the information provided by the sensors and the one stored in the database. More concretely, the database or look-up table contains information about, for example, the environment where the device is going to work and/or about the material of the objects where the device is going to be mounted and/or the possible operating frequency bands of the device and/or form factors of the device. In some embodiments, the database is stored in a cloud server, or set of servers, which contains the database and/or updates containing one or more device configurations; in some other embodiments, the device or system comprises the database or at least part thereof stored therein, e.g. in at least one memory thereof, for instance stored as part of its manufacturing process or stored upon retrieval of the database or part thereof from the cloud server. The wireless device or system is configured to communicate with the cloud server(s) for downloading or updating the configuration database in the at least one memory with the environment and operation mode information. The wireless device or system is configured, in some embodiments, to communicate directly with the cloud, and, in other embodiments, to communicate via another computing device, terminal or memory device, for instance with a wired connection such a USB, a Wi-Fi or a Bluetooth connection, more in general a short-range communication connection, the terminal being for example a smartphone or a tablet.

A wireless device or wireless communications system related to this disclosure is also able to automatically tune or match the comprised radiating system to different frequency bands or communication standards according to regional frequency allocations across the world (FIG. 6). In the context of this document, a frequency band refers to a range or set of frequencies used by a particular wireless communication standard, as for example cellular communication standards (for instance 2G, 3G, 4G, 5G, 6G, NB-IoT, LTE-M, LTE-M-Cat-1 communication standards), but also LoRa, Sigfox, WiSUN, Wi-Fi, Bluetooth, GNSS, UWB, Wise, Satellite IoT, Z-Wave, MyIoT and alike; while a frequency region refers to a continuum of frequencies of the electromagnetic spectrum. For example, the NB-IoT B20 band is allocated in a frequency band going from 791 MHz to 862 MHz; and the NB-IoT B8 band is allocated in a frequency band going from 880 MHz to 960 MHz. A wireless device operating in both the NB-IoT B20 and the NB-IoT B8 bands operates in a frequency region going from 791 MHz to 960 MHz. A wireless device that additionally operates at a third band, for instance the NB-IoT B3 band ranging from 1710 MHz to 1880 MHz, could be the to operate in two different frequency regions, a first frequency region going from 791 MHz to 960 MHz and a second frequency region going from 1710 MHz to 1880 MHz.

Then, a self-adaptive universal matching network (SUMN) is disclosed in the present disclosure, the SUMN being a matching network able to provide impedance matching at least at one frequency band within at least a frequency region, for different devices or radiating systems related to the present disclosure, featuring for instance, different sizes and/or shapes or, for example, including different non-resonant elements, or featuring different ground plane element sizes and/or shapes, and also being able to provide impedance matching for changing scenario sand different environments. The SUMN is also able to provide operation, in some devices or radiating system embodiments, at large or wide frequency bands or frequency regions.

Also, a self-adaptive matching network (SMN) able to match a device in changing scenarios and different environments is disclosed in the present disclosure. A universal matching network (UMN) able to provide impedance matching for different devices or radiating systems related to this disclosure is disclosed as well.

An advantage of comprising a SUMN, a SMN or a UMN in a radiating system comprised in a device related to this disclosure is that the WMC comprising the SUMN, SMN or UMN is non-customized and versatile, so that the design and engineering of the end IoT device becomes easier, faster resulting in a shorter time-to-market. In addition, by reusing a single WMC across a portfolio of different IoT devices an important reduction of cost can be obtained through economies of scale.

A feature of a UMN, a SMN or a SUMN is that the impedance values of the matching elements comprised in, can change or vary according to the changing environments surrounding the device for the case of a SMN or a SUMN, or can change according to the characteristics of the device or radiating system, such as the form factor or the ground plane element size, where the UMN is included, for the case of a UMN or SUMN. In some embodiments, the impedance values of those matching elements vary according to a switch system, the switch system comprising at least a switch, included in the WMC. In other embodiments, the impedance values of the matching elements vary by means of tunable components or elements. And in some other embodiments, those impedance values vary according to both a switches system and tunable components or vary according to other configurable elements not limited to switches or tunable components.

Additionally, a UMN, a SMN and a SUMN according to this disclosure features in some embodiments a reconfigurable topology, advantageously being self-configurable, which comprises, in some embodiments, at least a switch system, the topology configured for implementing an adequate matching network or matching network configuration according to the radiating system or device technical needs and features, as for example the size of the ground plane element, and according to the environment conditions. The switches system typically comprises ON/OFF switches for implementing, for example, short-circuit connections, open connections or connections to ground. Then, the configurable elements comprised in the reconfigurable topology are in some embodiments switch systems, comprising in some of those embodiments active circuit components, like transistors or Micro Electronic Mechanical elements (MEMs), but include other reconfigurable techniques or elements that uses electric or mechanical means to commute ON/OFF electrical paths.

In some embodiments of a radiating system or a device according to this disclosure, the WMC is comprised in a System on a Chip or in a System in a Package, hereinafter as well SoC or SiP, respectively. Having a WMC comprised in a SoC or in a SiP allows to have a multi-use stand-alone component ready to be easily integrated in different devices or radiating systems. Some embodiments of a SiP related to this disclosure further comprise an embedded non-resonant element, being typically connected by a conductive strip to the WMC. Some other SiP embodiments comprise a transceiver; and some others are enabled to be connected to more than one resonant elements, supporting operation at more than one communication standards.

A SoC related to this disclosure provides a reconfigurable system, typically contained in a chip that comprises at least one module or chip component, the reconfigurable system being able to implement a WMC according to this disclosure. As previously mentioned, a WMC can be comprised in a SiP, typically comprising further components or elements. Consequently, a SoC related to the disclosure can be comprised in a SiP.

A WMC, a SoC or a SiP related to this disclosure, provides versatility in the matching networks or matching network configurations that can be implemented with the WMC or with the SoC or SiP, providing, for example, the possibility of implementing a single-band or a multiband matching network, or the possibility of covering different bands of operation, or the possibility of making a device operative in different environments or environmental conditions. Some WMC or SiP embodiments comprise matching elements that implement a single-band matching network. Some other embodiments comprise matching elements that implement a multiband matching network. And there are other embodiments that comprise matching elements able to implement both a single-band and a multiband matching network, one at a time. Additionally, a WMC, a SoC and a SiP related to the disclosure provide versatility on the bands of operation covered. Some of all those WMC, SoC or SiP embodiments comprise a switches system for providing versatility. And some of these embodiments comprise a reduced number of switches so that the related losses are minimized. Some WMC or SiP embodiments include tunable or variable components, as for example tunable capacitors or/and tunable inductors. Those tunable components are external to the SiP in some embodiments and internal to the SiP in other embodiments. Furthermore, some WMC or SiP embodiments contain at least one embedded printed inductors, each of them featuring a particular inductance value. Banks of embedded printed inductors are comprised in some other embodiments, so that tunable embedded printed inductors are implemented. And other SoC or SiP embodiments comprise more than one module or chip component for implementing the required WMC.

More particularly, a WMC, a SoC or a SiP comprising more than one UMNs, concretely two, and able to implement all those UMNs, and more concretely those two UMNs, are herein disclosed. Two particular universal matching networks able to provide impedance matching for sub1 GHz frequencies on one side and for cellular/mobile frequencies on the other one, have been found. The UMN covering operation at sub1 GHz frequencies (e.g. for instance LoRa, Sigfox, Zwave, WiSUN, MyIoT, Wise bands) features an inverted-L configuration and it comprises a series inductor within the 20 nH to 40 nH range, preferably within the 25 nH to 35 nH and in particular of a value substantially close or equal to 30 nH, connected to a parallel inductor of 10 to 30 nH, preferably within the 15 nH to 25 nH range or even substantially close or equal to 20 nH in a series, parallel configuration (in short SP where ‘S’ is a series component and ‘P’ is a parallel component). Examples of those inductors are Murata's part numbers LQW18AN30NG00 and LQW18AN20NG00, respectively. The UMN that covers operation for mobile frequencies comprises seven circuit components arranged in a topology of several circuit elements arranged in the following sequence: series, parallel, series, parallel, parallel, series, series (in short SPSPPSS where hereinafter ‘S’ is a series component and ‘P’ is a parallel component). In some embodiments, such a SPSPPSS architecture is configured as follows: a series inductance connected to a parallel inductance, which is connected to a series capacitor, followed by and connected to a parallel arrangement comprising a parallel capacitor and a parallel inductor, which is connected to a series capacitor followed by and connected to a final series inductor. Some of those last embodiments comprise a first series inductor within the 2.0 nH to 6.0 nH range, preferably within the 3.0 nH to 5.0 nH, a second parallel inductor within the 15 nH to 25 nH range, preferably within the 17 nH to 21 nH, a series capacitor within the 0.5 pF to 0.9 pF range, preferably within the 0.6 pF to 0.8 pF, a parallel capacitor within the 0.4 pF to 0.8 pF range, preferably within the 0.5 pF to 0.7 pF, a parallel inductor within the 8.0 nH to 16.0 nH range, preferably within the 10.0 nH to 14.0 nH, a series capacitor within the 1.1 pF to 1.9 pF range, preferably within the 1.4 pF to 1.6 pF and a last series inductor within the 4.0 nH to 5.0 nH range, preferably within the 4.4 nH to 4.6 nH. In one embodiment, the values and the part numbers of those circuit components are by order in the topology described, 4.0 nH, with part number LQW15AN4NOG80, 19 nH with part number LQW18AN19NG80, 0.7 pF with part number GJM1555C1HR70WB01, 0.6 pF with part number GJM1555C1HR60WB01, 12 nH with part number LQW18AN12NG10, 1.5 pF with part number GJM1555C1H1R5WB01 and 4.5 nH with part number LQW15AN4N5G80. A particularity of those UMNs is that the LoRa universal matching network can be contained in the mobile universal matching network, so that a SoC or SiP component can implement both matching networks at a same time.

Those matching networks or matching network configurations cover operation for a wide range of device sizes or radiating system sizes, being the size of a device or a radiating system related to this disclosure defined by a length Ls and a width Ws of a minimum box that entirely encompasses the device or radiating system. A device or a radiating system also features a thickness or height Hs defined by the height of the minimum box of size Ls×Ws×Hs that encompasses it.

More particularly, a SP matching network is able to cover operation at sub1 GHz bands, as for example at least one LoRa band comprised within the range going from 863 MHz to 928 MHz. A SPSPPSS matching network is able to cover at least at one mobile frequency band within the frequency regions going from 824 MHz to 960 MHz and/or from 1710 MHz to 2690 MHz, for a radiating system or a device according to the present disclosure. In some embodiments such a radiating system includes a non-resonant element, for instance a radiation booster. Advantageously some embodiments are using Ignion's RUN mXTEND™ radiation booster, while others are using an off-the-shelf chip antenna component of the mXTEND™ family (i.e., the Virtual Antenna™ family) such as for instance: RUN mXTEND™, CUBE mXTEND™, BAR mXTEND™ and the alike. Those non-resonant elements are coupled to a ground plane element through a WMC. The ground plane element is for these radiating systems a ground plane layer printed on a printed circuit board featuring a width Wb dimension and a length Lb dimension. The non-resonant element is provided on a clearance area, an area where the ground plane is removed, preferably of dimensions We mm×Cc mm, being Cc a value preferably substantially close to 11 mm along the length Lb dimension such as for instance a value within 5 mm and 15 mm or within 10 mm to 12 mm. Preferably, the non-resonant element is located at a distance substantially close to 5 mm along the width dimension Wb from the corner of the PCB, e.g., within the range of 3 mm to 7 mm or preferably within the 4 mm to 6 mm.

Embodiments of such radiating system featuring different dimensions of the ground plane layer Wg×Lg are matched with the LoRa UMN. Some of these embodiments feature ground plane width Wg values bigger than 85 mm and smaller than 140 mm and ground plane lengths Lg bigger than 85 mm and smaller than 140 mm, or advantageously, Wg values between 110 mm and 140 mm and Lg values between 110 mm and 140 mm. Some other radiating systems feature a ground plane length Lg bigger than 85 mm and smaller than 160 mm and a ground plane width Wg bigger than 20 mm but smaller than 85 mm, or advantageously, a length Lg between 160 mm and 200 mm and a width Wg between 80 mm and 200 mm.

Radiating system embodiments comprising ground plane layers characterized by a length bigger than 110 mm but smaller than 130 mm and a width larger than 50 mm but smaller than 60 mm, or advantageously, by an Lg bigger than 110 mm but smaller than 122 mm and a Wg bigger than 55 mm but smaller than 60 mm, or by an Lg bigger than 122 mm and smaller than 130 mm and a Wg bigger than 50 mm but smaller than 55 mm, are matched with the mobile universal matching network presented before, at the frequency regions going from 824 MHz to 960 MHz and from 1710 MHz to 2690 MHz.

Different embodiments of the SoC or SiP previously described, comprising the LoRa and the mobile UMNs also previously disclosed, are provided. The SoC or SiP advantageously include, in some embodiments, a minimized number of switches, particularly four or less internal switches, and some SiPs further comprise an internal tunable capacitor. Another embodiment related to the SoC or SiP is presented, these embodiments comprising a seven-switch system. Other embodiments are modular, comprising, in some of them, modules or chip components comprising two switches, a first one connected in series followed by a second one connected in parallel arrangement. All those SoC embodiments comprise SoC pins or pads needed for connecting external matching elements, such as for instance external circuit components.

Embodiments of a wireless device or a wireless communications system according to the present disclosure that comprises a non-resonant element, a WMC comprising a SUMN and a PCB comprising a ground plane element, are provided. As mentioned, the WMC comprised in those embodiments comprises a self-adaptive universal matching network or SUMN, which matches the device or system at more than one frequency bands of operation, so that the device can adapt its operability to a diversity of scenarios and use contexts, or so that it can optimize its performance by selecting an optimal frequency band of operation. The SUMN has also been used for matching a wireless device including a PCB featuring a variable length Lb and/or a variable width Wb. The SUMN features a reconfigurable topology and it comprises an RF switch that is connected to some matching elements, which are arranged and comprised, in some embodiments, in a first matching network transceiver section and in a second at least one matching network booster section, both connected to the switch: the MN transceiver section being connected between the switch and an RF transceiver, and the at least one MN booster section being connected between the non-resonant element and the switch, so that the at least one MN booster section is connected to the MN transceiver section through the switch (see FIG. 33). In the SUMNs that comprise a MN transceiver section and at least a MN booster section, both the MN transceiver section and each of the at least one MN booster sections comprise at least one circuit element or component. In some embodiments, the MN transceiver section and/or at least one MN booster section comprise at least two circuit elements or components. In some of those embodiments, the MN transceiver section and/or at least one MN booster section comprise 3 circuit elements or components, in other embodiments, it or they comprise 4 circuit elements or components, in other embodiments, it or they comprise 5 circuit elements or components, in other embodiments, it or they comprise 6 circuit elements or components, and in other embodiments, it or they comprise 7 or more circuit elements or components. Some of all those embodiments comprise an inductor or a capacitor in the MN transceiver section and/or in at least one MN booster sections. Some of these embodiments comprise at least two inductors in at least one of the MN transceiver section and the at least one MN booster section or in both, and some other embodiments comprise at least two capacitors in at least one of the MN transceiver section and the at least one MN booster section or in both. Some of the SUMN embodiments comprised in a wireless device or communications system that can feature different dimensions, advantageously comprise a 0 ohms resistance, comprised in at least one MN booster section and/or in the MN transceiver section for the case of SUMNs comprising a MN transceiver section and at least one MN booster section. Other SUMN embodiments comprising a MN transceiver section and at least one MN booster sections comprise a same circuit component in both the MN transceiver section and a MN booster section. In other embodiments of a SUMN comprised in a wireless device or a wireless communications system of variable dimensions, the RF switch comprises at least a pole or input P and at least two throughs or outputs T, and more concretely, in some other embodiments, the RF switch comprises a single pole and N throughs (SPNT switch). Additionally, the RF switch is, in some embodiments, a multi-path switch able to route or connect a pole to two or more throughs simultaneously, which allows to combine matching elements connected to different throughs between them, so that more matching network topologies or matching network configurations can be implemented by the reconfigurable topology. In some embodiments, the RF switch also allows the matching elements to be connected to ground with an internal connection, again providing the WMC with more configurable matching network topologies. A SUMN comprising a multi-path switch, able to connect or not matching elements to ground, comprises at least one circuit element or component, comprising in some embodiments an inductor, and in other embodiments, a capacitor. Some of these SUMN embodiments comprise at least two circuit elements or components and some of these embodiments comprise 3 circuit elements or components, other embodiments comprise 4 circuit elements or components, or 5 circuit elements or components, or 6 circuit elements or components, and other embodiments, even 7 or more circuit elements or components. Some of all those embodiments comprise at least two inductors, and some other embodiments comprise at least two capacitors. All those SUMNs can be configured by configuring different switch states to implement different matching network topologies in function of the platform and/or the operating bands requirements, or in function of the environment conditions. Wireless devices or radiating systems including a PCB of dimensions between Lb×Wb=50 mm×50 mm and 130 mm×80 mm for operating in two frequency regions going from 617 MHz to 960 MHz and from 1710 MHz to 2170 MHz have been matched with a SUMN comprising a MN transceiver section, four MN booster sections and a multi-path switch able to connect internally matching elements to ground. More particularly, in some embodiments, the multi-path switch comprises four throughs or outputs (e.g., a SP4T switch). All the possible combinations of the states of the throughs (named here T1, T2, T3 and T4 respectively) of the switch that provide an acceptable matching of the device or the radiating system at the sought frequencies, as well as their related matching networks, are examples of use of the SUMN. In some wireless devices or radiating systems embodiments, at least one matching element comprised in the wireless matching core of the device or the radiating system is connected to a ground internal connection of the RF switch. The same SUMN has been comprised in a WMC comprised in a radiating system according to the disclosure for enabling operation of the radiating system above different platforms of different materials, as for example, a metallic object, wood, biological tissue or a brick. The SUMN matches the radiating system or the device at two operation frequency regions, as for example from 698 MHz to 960 MHz and from 1.71 GHz to 2.17 GHz. The radiating system or device can be placed at different distances from the platforms, being also matched with the SUMN comprised.

In some embodiments of a WMC, a SoC or a SiP comprising a UMN, a SMN or a SUMN that comprises at least one MN booster section, or in some embodiments at least two MN booster sections, connected between a non-resonant element and a switch, and also in some embodiments a MN transceiver section, connected between the switch and an RF transceiver, the different matching network configurations implemented with those reconfigurable matching networks comprise a first common parallel circuit component, being in some embodiments an inductance and, in some other embodiments, a capacitor. The first common parallel circuit component is connected to one of the non-resonant elements comprised in the radiating system and connected to a ground. In some embodiments, the common parallel circuit component is directly connected to the non-resonant element. It has been found that by including a first parallel component that is common to the different configured matching networks, the matching impedance obtained before the MN transceiver section for every matching network at the corresponding frequency region of operation can feature a value close to the matching impedances obtained for the other matching networks at their corresponding frequency regions of operation also before the MN transceiver section. Then, the different matchings performed with the different matching networks can be easily completed with a common transceiver matching section, resulting in better reflection coefficients before the transceiver for all the configured switches system states or matching networks. The closer the matching impedances obtained before the MN transceiver section are between them and to a 50 Ohms impedance, the better reflection coefficients before the transceiver obtained and, so, the antenna efficiencies. Then, a UMN, a SMN or a SUMN, preferably comprising in some embodiments a common MN transceiver section for the different matching networks implemented with the UMN, the SMN or the SUMN, wherein the matching networks comprise a first or initial common parallel circuit component are advantageous embodiments of the present disclosure. The common parallel circuit component is, in some embodiments, an inductance, and in others, it can be a capacitor. In some of those embodiments of a UMN, a SMN or a SUMN, comprising a first common parallel component for the different matching networks configured and implemented, the input impedances obtained before the MN transceiver section for every matching network within the corresponding frequency region of operation feature a value with a real part between 4 Ohms and 76 Ohms for the fully configured system (e.g. FIG. 33). In other embodiments, such impedances feature a real part smaller than 51 Ohms but bigger than 4 Ohms, and in other embodiments feature a real part smaller than 26 Ohms but bigger than 4 Ohms. In some embodiments, the impedances feature a capacitive imaginary part, and in other embodiments, the impedances feature an inductive imaginary part.

Also, some radiating system embodiments according to the present disclosure comprise a WMC comprising only one part that is connected to the radiation booster comprised in the radiating system and to the transceiver. Other embodiments of a radiating system comprise a WMC comprising at least two parts: a tunable part comprising an active or a tunable element and a part comprising at least one electronic component wherein all the components are passive components. In these last embodiments, one of the parts comprised in the WMC is connected to a ground and to a first connection point comprised in the radiation booster comprised in the radiating system, and a second part comprised in the WMC is connected to a transceiver and to a second connection point comprised in the radiation booster. In some of those embodiments, it is the tunable part the one connected to ground, and in other embodiments, it is the passive matching network the one connected to ground.

Another aspect of the disclosure relates to a method comprising: storing a table with a plurality of matching network configurations in at least one memory of a wireless device; and providing, by at least one processor of the wireless device, at least one electrical signal for acting on at least one reconfigurable electronic component of a self-adaptive universal matching network of a radiating system the wireless device for selecting a particular state thereof for selecting a particular matching network configuration of the plurality of matching network configurations by processing the table according to a predetermined matching network configuration selection process. The radiating system is, for example, one as previously described. Hence, the radiating system, for example but without limitation, comprises: at least one non-resonant element; a ground plane element; a transceiver; a wireless matching core comprising the self-adaptive universal matching network that comprises: at least one reconfigurable electronic component configured to support a plurality of states, wherein in each state of the plurality the at least one electronic component defines a different electrical path, the at least one electronic component comprising an RF switch; at least two matching network sections each connected at least with the at least one electronic component and the at least one non-resonant element; at least one network section connected with the at least one electronic component and the transceiver; and at least a matching element in at least one of the at least two matching network sections; and a means of supplying energy; and at least some of the different electric paths of the self-adaptive universal matching network are each configured to provide impedance matching in at least at one frequency band within at least a frequency region, for the wireless device.

In some embodiments, the wireless device comprises at least one sensor adapted to measure at least one environment-related parameter or physical magnitude corresponding to environmental conditions that the radiating system is in; wherein the method further comprises processing, by the at least one processor, at least one environment-related parameter or physical magnitude from each sensor of the at least one sensor to determine environmental conditions that the radiating system is in; and wherein the predetermined matching network configuration selection process comprises processing the table at least based on the determined environment conditions that the radiating system is in.

In some embodiments, the method further comprises arranging the radiating system on a platform of a predetermined material; and processing the table comprises selecting a state of the plurality of states that is associated with the predetermined material of the platform.

In some embodiments, the predetermined matching network configuration selection process comprises processing the table at least based on a size of the ground plane element. For instance, the size of the ground plane element can be provided to the at least one processor in the form of data that is e.g. introduced into the wireless device by a person with a user input device (e.g. touchscreen, keyboard, etc.), transmitted to the wireless device from a computing device via a wired or wireless communications link, etc.; that data may be provided during manufacturing of the wireless device for dynamic, automatic configuration thereof.

In some embodiments, the method further comprises, upon arranging the radiating system in the wireless device, providing data to the at least one processor indicative of the size of the ground plane element so that the at least one processor preferably actuates on the self-adaptive universal matching network for readapting itself.

In some embodiments, the predetermined matching network configuration selection process comprises sweeping over some or all states of the plurality of states to subsequently select a state of the plurality states based on the impedance matching achieved by each swept state.

Another aspect of the disclosure relates to a data processing device comprising means for carrying out the steps of the method of the previous aspect.

Another aspect of the disclosure relates to a computer program product comprising instructions which, when the program is executed by at least one processor of a wireless device as e.g., a wireless device as previously described, cause the wireless device to carry out the steps of the method previously described. The computer program product may for instance be embodied in a non-transitory computer-readable storage medium or be part of a data carrier signal.

### BRIEF DESCRIPTION OF THE DRAWINGS

The mentioned and further features and advantages of the disclosed invention become apparent in view of the detailed description which follows with some examples of the invention, referenced by means of the accompanying drawings, given for purposes of illustration only and in no way meant as a definition of the limits of the invention.

FIG. 1 is an example of a smart tuning device from prior-art, containing a bank of matching networks and two switches.

FIG. 2 is an example of a System on Chip (SoC).

FIG. 3 illustrates an IoT tracking system providing location of a moving platform such as a vehicle to a cloud.

FIG. 4 illustrates a wireless device or wireless communications system (400) according to the disclosure, comprising a radiating system that comprises a non-resonant element (402), a ground plane layer (401) and a wireless matching core (403).

FIG. 5A illustrates a wireless device or wireless communications system (500) according to the disclosure, comprising a radiating system that comprises a non-resonant element, a ground plane layer and a wireless matching core, and that further comprises an intelligent database or look-up table and sensors that provide the device with the capability of self-tuning the wireless matching core from the environment data captured by the sensors.

FIG. 5B shows a wireless device (500) from FIG. 5A communicating with a cloud server or to a computer or memory device for downloading or updating a database or look-up table comprised in it.

FIG. 5C shows a planar view of an example of a wireless device or a radiating system with a circular shape, as well as some dimensions related to some of its components.

FIG. 6 provides a communications system according to the disclosure that tunes the comprised radiating system automatically to different frequency bands according to regional frequency allocations across the world.

FIG. 7 shows how a single hardware architecture including a WMC system that is capable to adapt to a plurality of different devices or products with different sizes and form factors, such as a smart watch, a smart pen, a smart meter, etc.

FIG. 8 shows a single hardware architecture including a WMC system that can adapt to different mounting environments, including a ceramic brick, a metal container, wood or biological tissue.

FIG. 9 provides a generic circuit topology for a UMN, for a SMN or for a SUMN, including matching elements values or circuit components values Zx, e.g., Z1 through Z6.

FIG. 10 illustrates a system on a chip (SoC) or system-in-package (SiP) embodiment related to the generic circuit topology presented in FIG. 9. The SoC includes a switches system comprising six switches.

FIG. 11 provides a particular example of the generic circuit topology provided in FIG. 9.

FIG. 12 provides an example of a modular SoC that implements the circuit topology from FIG. 11. This modular SoC comprises three modules arranged in a cascade or linear distribution.

FIG. 13 presents another modular SoC embodiment that implements the circuit topology from FIG. 11. This modular SoC comprises three modules arranged in a distribution other than cascade (non-linear).

FIG. 14 provides another circuit topology for a UMN, for a SMN or for a SUMN, for instance a SPSPSPPSS topology.

FIG. 15 provides an example of a SoC that implements the circuit topology from FIG. 14. This SoC includes a switch system based on the one in FIG. 10.

FIG. 16 illustrates a UMN that covers operation at LoRa bands comprised within the frequency region going from 863 MHz to 928 MHz for a radiating system according to the disclosure.

FIG. 17 illustrates a UMN that covers operation at mobile bands comprised within the frequency regions going from 824 MHz to 960 MHz and from 1710 MHz to 2690 MHz for a radiating system according to the disclosure.

FIG. 18 shows a dimensions mapping for a ground plane layer comprised in a radiating system according to the disclosure that would provide operation, considering an input reflection coefficient below −6 dB, when comprising the UMN from FIG. 16.

FIG. 19 shows a dimensions mapping for a ground plane layer comprised in a radiating system according to the disclosure that would provide operation, considering an input reflection coefficient below −5.5 dB, when comprising the UMN from FIG. 17.

FIG. 20 shows a WMC SoC embodiment able to implement the two universal matching networks (UMNs) provided in FIG. 16 and FIG. 17.

FIG. 21 shows the switch states needed for implementing the UMNs from FIG. 16 (row 1) and FIG. 17 (row 2) with a SoC embodiment from FIG. 20.

FIG. 22 illustrates another WMC SoC embodiment able to implement the two universal matching networks provided in FIG. 16 and FIG. 17.

FIG. 23 illustrates a modular SoC embodiment capable of implementing the universal matching networks provided in FIG. 16 and FIG. 17.

FIG. 24 illustrates a modular SoC embodiment able to implement the universal matching networks provided in FIG. 16 and FIG. 17, featuring an inverted-L module arrangement.

FIG. 25 illustrates an SoC embodiment containing embedded printed inductors and a variable capacitor.

FIG. 26 illustrates another SoC embodiment comprising embedded printed inductors.

FIG. 27 illustrates an SoC embodiment comprising a bank of embedded printed inductors arranged in parallel between them.

FIG. 28 shows a table of switches state combinations related to the switches that control the inductance value of the bank of printed inductors comprised in the SoC embodiment provided in FIG. 27.

FIG. 29 illustrates an SoC embodiment further comprising an embedded non-resonant element, connected to an also embedded WMC.

FIG. 30 illustrates an SoC embodiment further comprising an embedded transceiver, connected to an embedded WMC.

FIG. 31 illustrates an SoC embodiment further comprising an embedded transceiver, connected to an embedded WMC, configured to work at a plurality of frequency bands or communication standards.

FIG. 32 illustrates an SoC embodiment further comprising an embedded transceiver, connected to an embedded WMC, the WMC connected to a plurality of non-embedded non-resonant elements.

FIG. 33 illustrates a wireless device or wireless communications system according to the disclosure, comprising a PCB of diverse dimensions and a WMC that comprises a SUMN.

FIG. 34 illustrates an SUMN embodiment included in the wireless device or wireless communications system from FIG. 33, which comprises at least one MN booster section, a MN transceiver section and an RF switch. In particular, the switch is a multi-path SP4T switch able to connect its throughs to an internal ground connection or to a set of 4 MN booster sections.

FIG. 35 shows a switch states table related to the RF switch included in the SUMN from FIG. 34 for matching a device with a PCB of 50 mm×50 mm. The switch states used and the frequency sub-bands matched for each case are included.

FIG. 36 illustrates resulting matching networks as configured with the switch states provided in the table in FIG. 35. The corresponding frequency sub-bands matched for each case are included in the Figure.

FIGS. 37A and 37B show input reflection coefficient obtained with the switch states and the corresponding matching networks provided in FIG. 35 and FIG. 36. FIG. 37A provides the input reflection coefficients at low-frequency bands, and FIG. 37B provides the input reflection coefficients at high-frequency bands.

FIG. 38 shows a switch states table related to the RF switch included in the SUMN from FIG. 34 for matching a device with a PCB of 60 mm×65 mm. The switch states used and the frequency sub-bands matched for each case are included.

FIG. 39 illustrates matching networks configured with the switch states provided in the table from FIG. 38. The corresponding frequency sub-bands matched for each case are included in the Figure.

FIGS. 40A and 40B shows the input reflection coefficient obtained with the switch states and the corresponding matching networks provided in FIG. 38 and FIG. 39. FIG. 40A provides the input reflection coefficients at low-frequency bands, and FIG. 40B provides the input reflection coefficients at high-frequency bands.

FIG. 41 shows a switch states table related to the RF switch included in the SUMN from FIG. 34 for matching a device with a PCB of 70 mm×65 mm. The switch states used and the frequency sub-bands matched for each case are included.

FIG. 42 illustrates matching networks configured with the switch states provided in the table from FIG. 41. The corresponding frequency sub-bands matched for each case are included in the Figure.

FIGS. 43A and 43B show the input reflection coefficient obtained with the switch states and the corresponding matching networks provided in FIG. 41 and FIG. 42. FIG. 43A provides the input reflection coefficients at low-frequency bands, and FIG. 43B provides the input reflection coefficients at high-frequency bands.

FIG. 44 shows a switch states table related to the RF switch included in the SUMN from FIG. 34 for matching a device with a PCB of 115 mm×80 mm. The switch states used and the frequency sub-bands matched for each case are included.

FIG. 45 illustrate matching networks configured with the switch states provided in the table from FIG. 44. The corresponding frequency sub-bands matched for each case are included in the Figure.

FIGS. 46A and 46B show the input reflection coefficient obtained with the switch states and the corresponding matching networks provided in FIG. 44 and FIG. 45. FIG. 46A provides the input reflection coefficients at low-frequency bands, and FIG. 46B provides the input reflection coefficients at high-frequency bands.

FIG. 47 show a switch states table related to the RF switch included in the SUMN from FIG. 34 for matching a device with a PCB of 130 mm×80 mm. The switch states used and the frequency sub-bands matched for each case are included.

FIG. 48 illustrate matching networks configured with the switch states provided in the table from FIG. 47. The corresponding frequency sub-bands matched for each case are included in the figure.

FIGS. 49A and 49B show the input reflection coefficient obtained with the switch states and the corresponding matching networks provided in FIG. 47 and FIG. 48. FIG. 49A provides the input reflection coefficients at low-frequency bands, and FIG. 49B provides the input reflection coefficients at high-frequency bands.

FIG. 50 shows the antenna efficiency obtained at the frequency regions of operation of a wireless device comprising a PCB of different dimensions, as the one described in FIG. 33, and matched with a SUMN from FIG. 34.

FIG. 51 SMN embodiment comprising four MN booster sections, one MN transceiver section and an RF switch, wherein the switch is the switch comprised in the SUMN embodiment from FIG. 34.

FIGS. 52A and 52B show combinations of the MN booster sections elements comprised in the SMN from FIG. 51. The frequency sub-bands matched with each combination are also included in the figure.

FIGS. 53A and 53B show the input reflection coefficient obtained for each matching network resulting from each switches system state of the SMN provided in FIG. 51 for matching the sought sub-bands of operation.

FIG. 54 shows the antenna efficiency obtained at the frequency regions of operation of a radiating system or wireless device that comprises the SMN from FIG. 51.

FIG. 55 shows some schematics of a radiating system according to the disclosure are provided. Different configurations of the WMC comprised in those radiating systems are illustrated.

FIG. 56 provides radiating systems comprising a WMC that comprises at least two different parts wherein one is connected to ground.

FIG. 57 shows a radiating system according to the disclosure that comprises a WMC including two parts: a tunable part and a part comprising passive electronic components, the tunable part connected to a ground plane layer.

FIG. 58 provides the detail of the WMC parts of the WMC comprised in the embodiment from FIG. 57.

FIGS. 59A and 59B illustrate the input reflection coefficient obtained at LFR—FIG. 59A—and at HFR—FIG. 59B—for the embodiment provided in FIG. 57. The different sub-bands at LFR are obtained for different switch states of the switch comprised in the tunable part of the WMC.

FIGS. 60A and 60B provides the measured input reflection coefficient obtained at LFR—FIG. 60A—and at HFR—FIG. 60B—for the embodiment provided in FIG. 57 when it is placed above a metallic plate.

FIG. 61 provides the measured antenna efficiency for the embodiment provided in FIG. 57 when it is placed above a metallic plate.

FIGS. 62A and 62B show the measured input reflection coefficients related to a radiating system according to the disclosure, particularly the radiating system provided in FIG. 57, placed above platforms of different materials.

FIG. 63 shows the measured antenna efficiencies related to a radiating system according to the disclosure, particularly the radiating system provided in FIG. 57, placed above platforms of different materials, the radiating system matched as shown in FIGS. 62A and 62B.

### DETAILED DESCRIPTION

As described before, in the context of the present disclosure, a wireless device such as for instance an Internet of Things (IoT) device, and a wireless communications system providing operation in one or more frequency bands comprised within one or more frequency regions across a diversity of platforms and use environments are here disclosed. A wireless device or wireless communications system comprises a radiating system that comprises a non-resonant element, a ground plane element, a wireless matching core (WMC), a transceiver or communications module, a processor, and a means of supplying energy or power supply, being for example a battery, a solar panel, an ultra-capacitor, an energy harvesting element or an electricity-based system, but not limited to those elements.

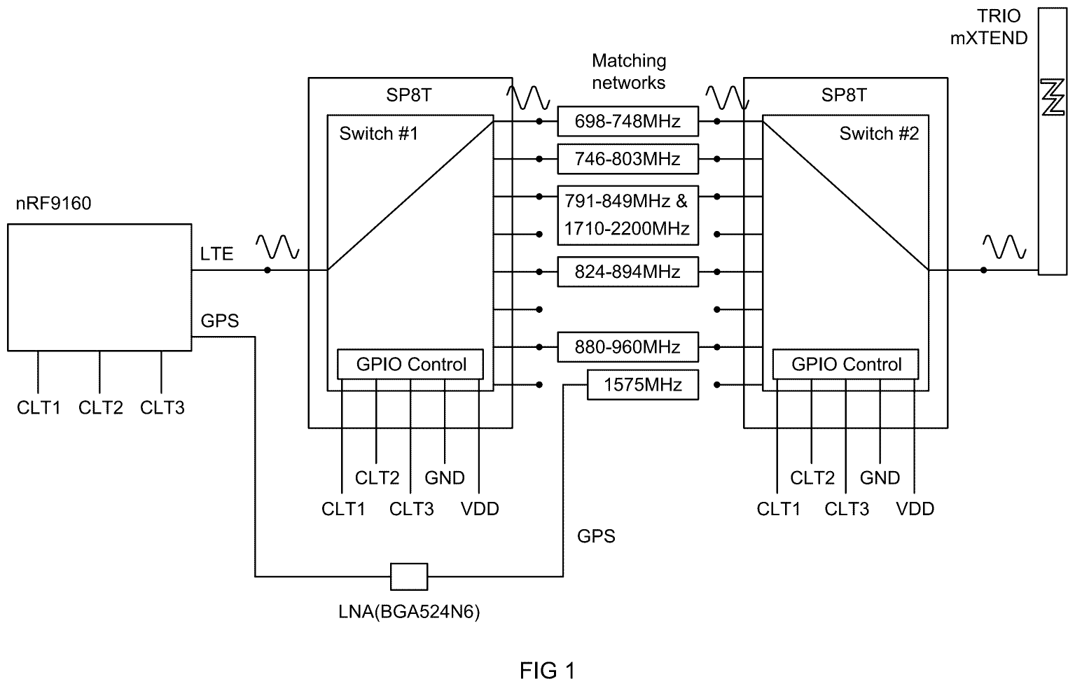

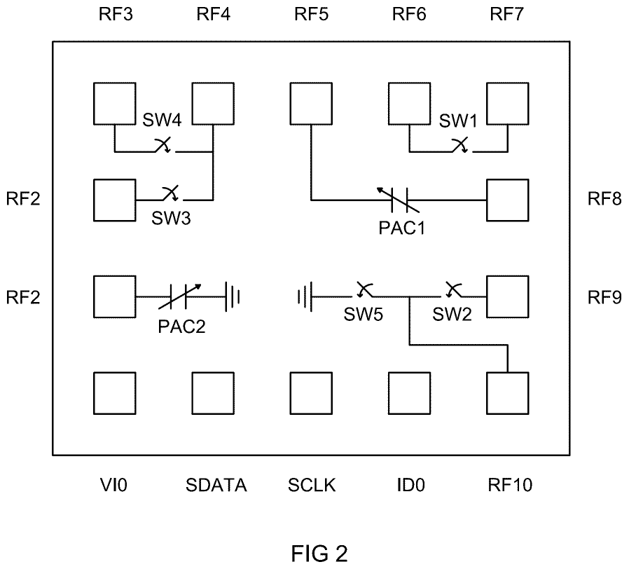

FIG. 1 is an example of a smart tuning device from prior-art, containing a bank of matching networks and two switches. FIG. 2 is an example of a System on Chip (SoC).

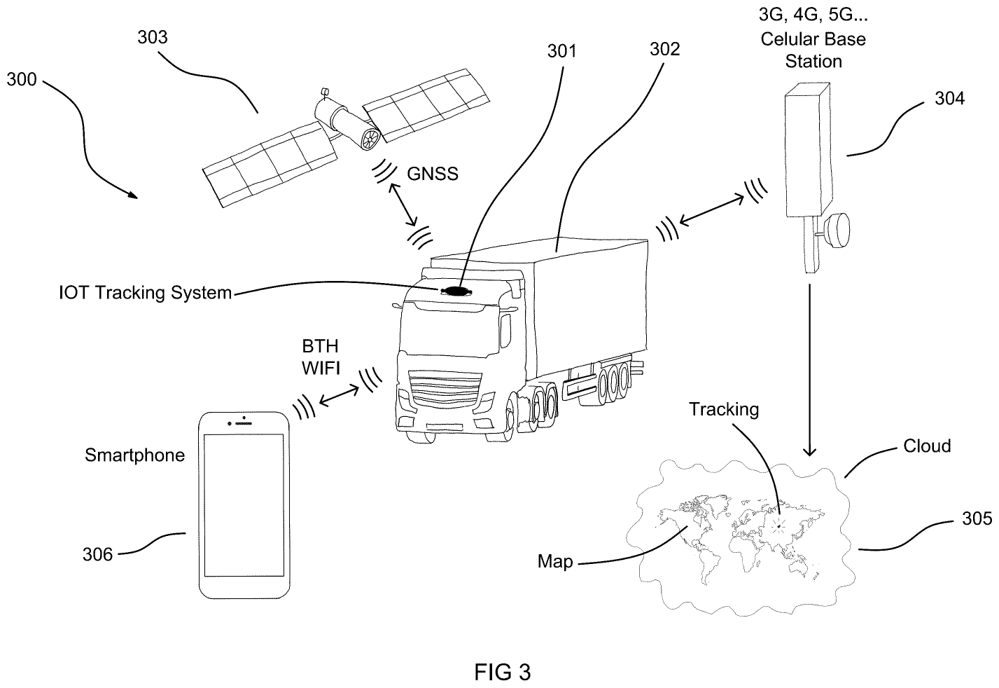

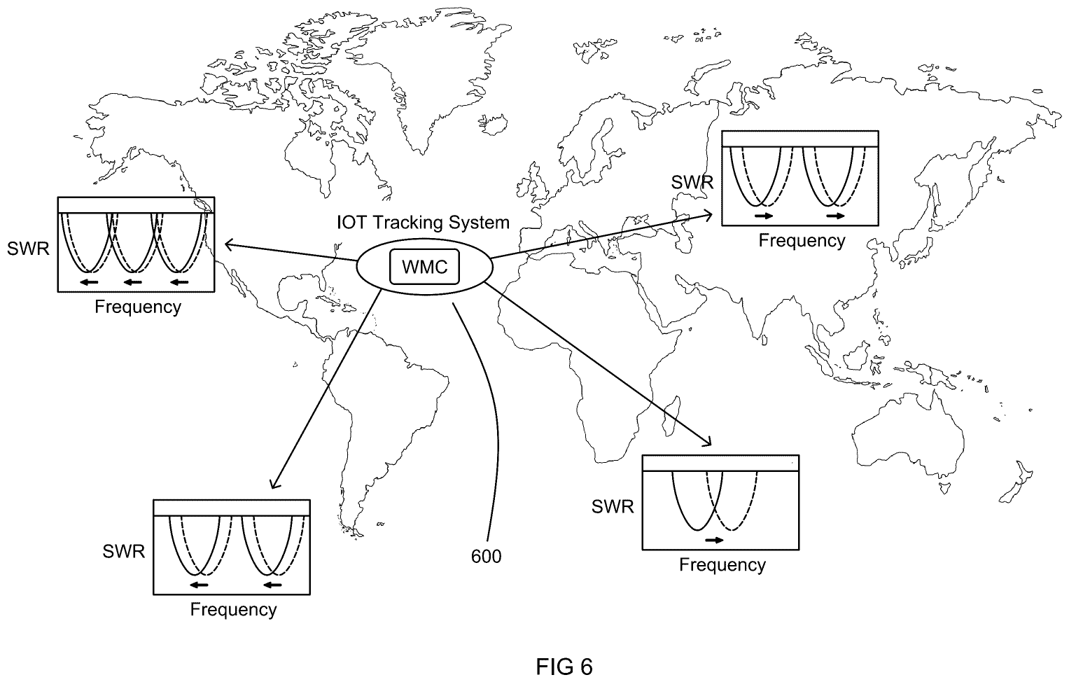

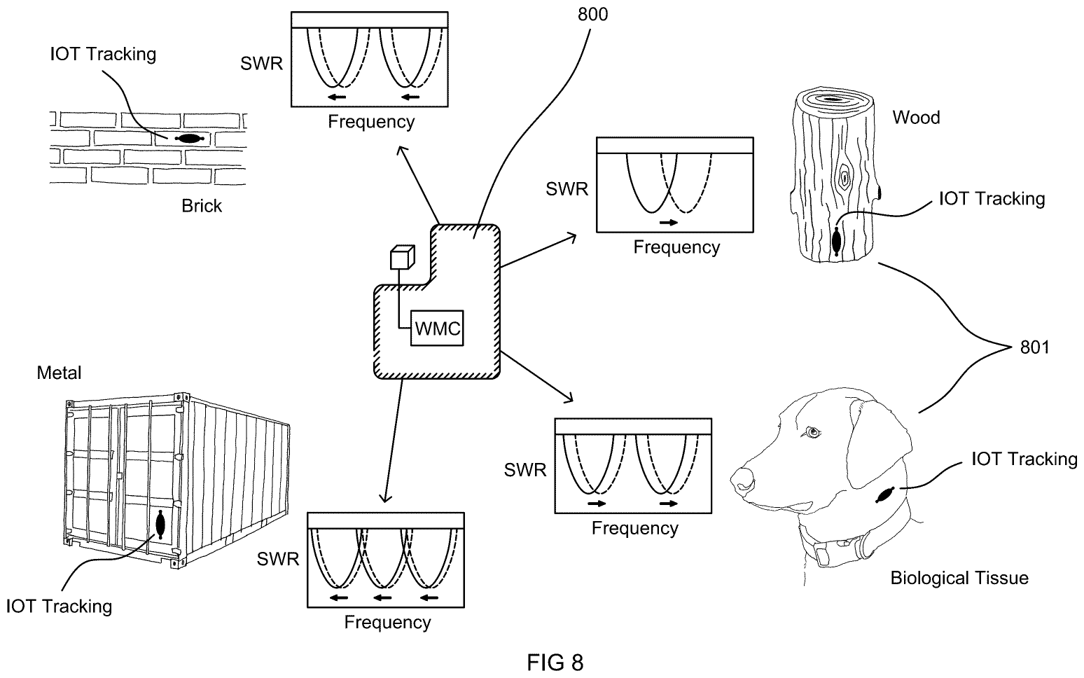

FIG. 3 shows an IoT tracking system (300) used for tracking a vehicle (302) and its goods. The tracker (301) connects to a GNSS satellite (303) constellation to obtain the position of the vehicle, to a cellular or LPWAN network (304) to transmit the position to the cloud (305), and to a configuration terminal (306) such a smartphone or alike to configure the tracker. A wireless device according to the present disclosure can advantageously be used as a tracking device (301) to connect to globally to different frequency bands available in different regions of the world (FIG. 6), while accommodating to different mounting scenarios (e.g., glass, plastic or metal mounting) owing to the flexibility provided by the disclosed system, as illustrated in FIG. 8.

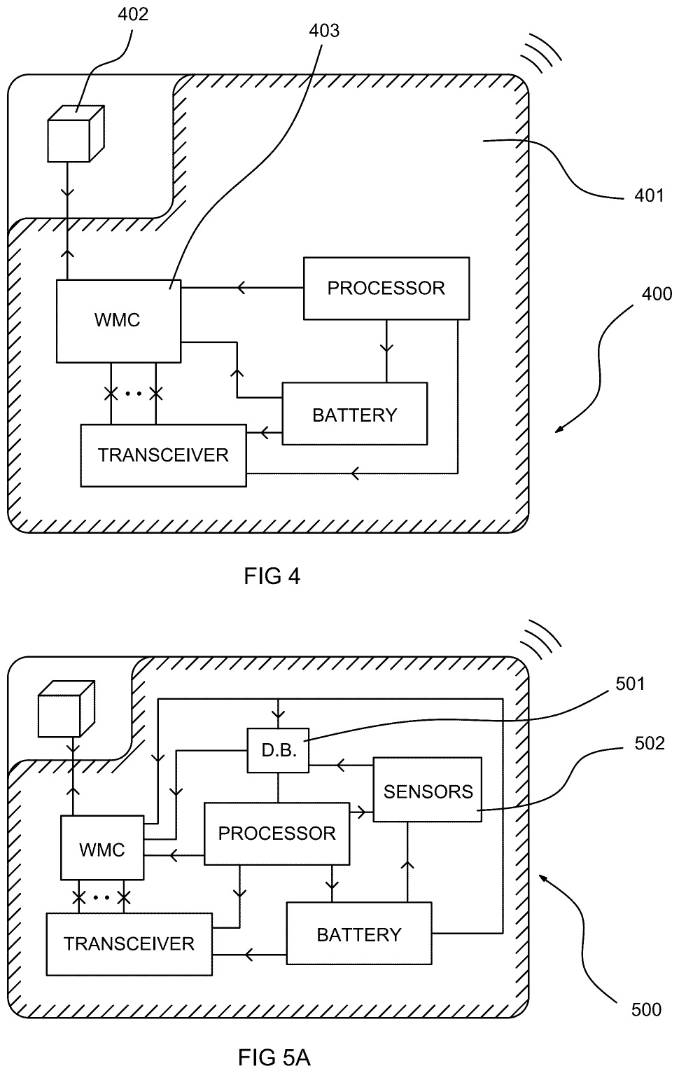

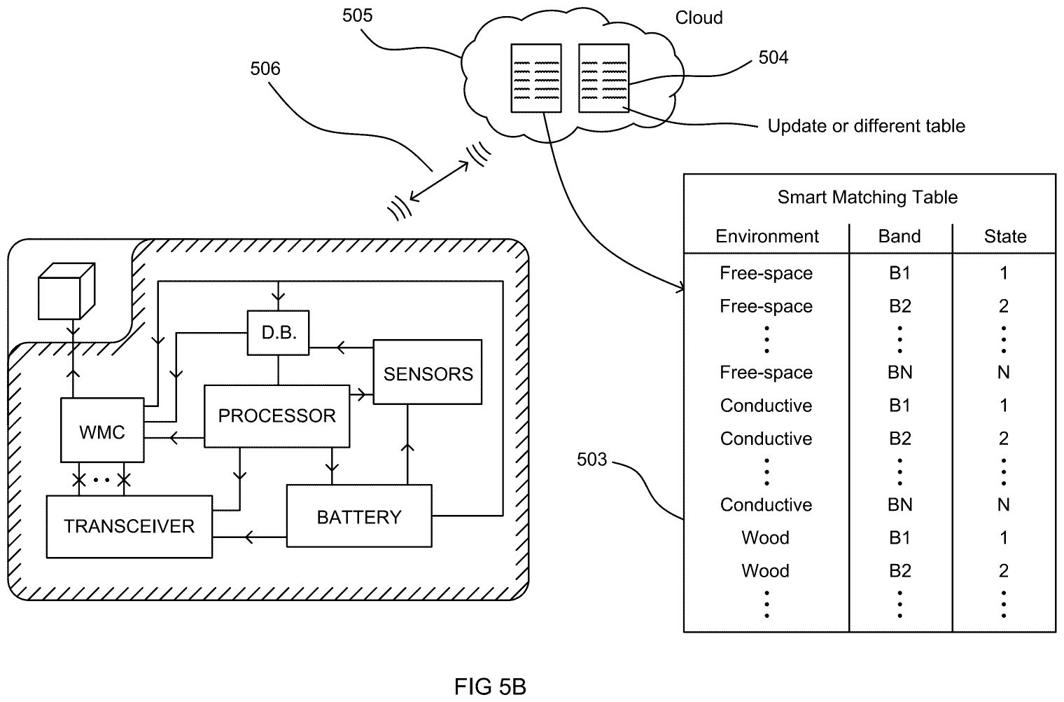

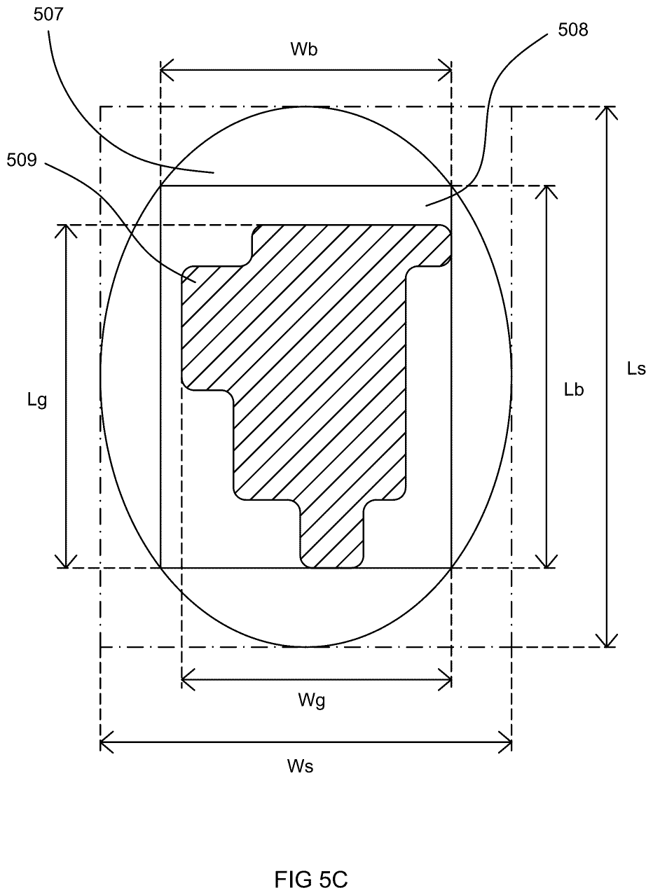

FIG. 4 shows an embodiment of a wireless device or wireless communications system (400) according to the disclosure, which can be used for instance as a tracking device. It includes a PCB comprising a ground plane element (401), a non-resonant element (402), a WMC (403), a processor, a communications module or transceiver, and a means of supplying energy or power supply, being for example a battery, a solar panel, an ultra-capacitor, an energy harvesting element or an electricity-based system, but not limited to those elements. The device is able to connect at multiple frequency bands and communication standards including, for instance, cellular, LPWAN, WiFi, Bluetooth and GNSS. For the purpose of clarity, the lines and arrows in FIG. 4 and FIGS. 5A and 5B and elsewhere in block diagrams for systems are displayed to express a possible direct or indirect relation or interaction between different elements or blocks of the system which are not limited to a physical connection. Likewise, the arrows are there to illustrate a possible sense in the interaction but interactions in the opposite sense to the arrow are also within the scope of the invention although not explicitly illustrated. Examples of direct or indirect relations or interactions include: a physical connection, a mechanical connection, an electrical connection, a wireless or a contactless connection, a logic connection through the direct or indirect interaction between the elements of the system. For instance, in one example of indirect interaction, a processor instructs the battery or power supply to lower or increase the current supply to other elements of the system depending on the configuration of the WMC.

FIG. 5A provides a device or communications system embodiment (500) according to the disclosure, further including an intelligent database or look-up table (501) and sensors (502) for tuning or reconfigure the WMC in view of the environment data provided by those sensors. The database or look-up table (501) contains information about, for example, the environment where the device might work in and/or about the material of the objects where the device might be mounted on and/or the operating frequency bands and/or form factors of the device. As shown in FIG. 5B, a database is a single database or a multiple database containing more than one record or table (504). This database is typically stored in the cloud (505), a server containing the database and/or updates (504) containing the possible device configurations. FIG. 5B shows a wireless device from FIG. 5B communicating with the cloud for downloading or updating the configuration database with the environment and operation mode information. The wireless device communicates (506) in some embodiments directly with the cloud, and, in other embodiments, via another device or terminal, typically comprising a WiFi or a Bluetooth connection, more in general a short-range communication connection, the terminal being for example a smartphone or a tablet. The one or more sensors in FIGS. 5A and 5B can take different forms, including proximity sensors, RF wave sensors, resistive, capacity or inductive sensors, piezo electric sensors, haptic sensors, accelerometers, temperature and light sensors, pressure sensors, humidity sensors and in general any means for providing information on the scenario where the wireless device is operating, including surrounding materials, radio wave propagation conditions and carrier frequencies. A sensor in some embodiments is a stand-alone component such as for instance an electronic piece, while in other embodiments a sensor is embedded into an element of the system such as for instance a transceiver or a processor. A sensor according to the present disclosure is in some embodiments an RF sensor capable of sensing the return-loss, VSWR or any other impedance match related parameter. Some sensors provide information on Total Radiated Power (TRP), Total Isotropic Sensitivity (TIS), Total Received Power in some embodiments as well. The RF sensor might be placed in between the non-resonant element (402) and the WMC (403), within the MWC and the transceiver, or within the WMC and the processor. In some embodiments, the RF sensor is embedded into the transceiver, while in other is embedded into the processor.

FIG. 5B discloses an embodiment including an intelligent database or look-up table and one or more sensors (FIG. 5B). In those, the WMC is tuned according to the information provided by the sensors and/or the one stored in the database. More concretely, the database or look-up table contains information about, for example, the environment where the device is going to work and/or about the material of the objects where the device is going to be mounted and/or the possible operating frequency bands of the device and/or form factors of the device. This database is typically stored in a cloud server which contains the database and/or updates containing one or more device configurations. The wireless device communicates with the cloud for downloading or updating the configuration database with the environment and operation mode information. The wireless device communicates in some embodiments to an external device, for instance a cloud server and, in some embodiments, to a computer device, to a terminal or to a memory device. This connection to an external device is done through a connectivity means, including for instance a wired connection such as for instance a USB, or more in general through a wireless means such as a WiFi, ZigBee or Bluetooth connection, the external device being for example a smartphone or a tablet. In some embodiments, this connectivity means is provided within the wireless device according to the present disclosure to enable a software upgrade on the transceiver, processor or any other element in the system running a software.

In some embodiments, at least some information elements within the intelligent database or smart matching table in FIG. 5B is copied and stored in a memory within the wireless device (400, 500) according to the present disclosure. These might include some or all of the registers and fields within the database. Some elements in the database define one or more user profiles. A profile might include for instance the relevant information so that the wireless device according to the present disclosure is optimally mounted and operated, in one case, in proximity of biological tissue such as cattle, human bodies, or alike. In another example, a profile would define for instance the configuration needed to optimize the performance of the wireless device when mounted on metal containers. In general, a profile might define one or more configurations for the scenarios illustrated without any limiting purpose in FIGS. 6-8 and every possible combination of those.

FIG. 5C shows a planar view of an example of a wireless device or a radiating system with a circular shape (507) defined by a length Ls and a width Ws of a minimum box (dashed dotted line in FIG. 5C) that entirely encompasses the device or radiating system. A device or a radiating system also features a thickness or height Hs defined by the height of the minimum box of size Ls×Ws×Hs that encompasses it. The PCB (508) comprised in the wireless device or radiating system features a length named Lb and a width named Wb as shown in FIG. 5C, and the ground plane element (509) comprised in the PCB features a length Lg and a width Wg. As already mentioned in this text, a length is a first bigger dimension of a parallelepiped or a parallelogram, and a width is a second bigger dimension of the parallelepiped or parallelogram.

One or more of those profiles are stored in a memory within a wireless device according to the present disclosure in different ways according to different business or use case needs. For instance, the profiles might be stored in some cases within the manufacturing process of the wireless device. In some embodiments, the profiles are stored upon commissioning/provisioning (first use) of the wireless device on over the air (OtA) when in the field. In some embodiments, a generic profile is provided in manufacturing, while other application specific or optimized profiles are updated during or after first use. Those profiles might be made available to the client or end user on a subscription base. This subscription might be included in the sales price of the wireless device or might be part of a maintenance, upgrade or renewal service.

In some embodiments, an intelligent database or look-up table according to the present disclosure includes one or more of the following fields: mounting material; size and form factor of a wireless or IoT device, switch state of the WMC and a combination of those, frequency plan for transmission (Tx) and/or reception (Rx), geo region of operation, profile number or ID, register identification or ID, IoT application, software version, sensor state and/or sensor data, wireless RF data including impedance related data (VSWR, Return-Loss, Resonance) and active data (TRP, TIS, etc.).

An aspect of the present disclosure includes connecting hundreds of thousands and even millions of IoT devices through a wireless device according to the present disclosure. In one embodiment, all those many devices provide data on performance to a cloud server, the cloud server including a Machine Learning (ML), an Artificial Intelligence (AI) software and/or processor and the alike (hereinafter an AI means). Such an AI means learns from the data obtained from the many connected devices in terms of performance, mounting configuration, and explores new configurations and profiles to optimize the overall performance of the connected devices. This includes for instance generating new combinations of a switch states within the WMC in the wireless device.

While the configuration of some embodiments of a wireless device is optimized based on the data provided by one or more sensors, by the information in the database or a combination of both, in some others where a minimum complexity is required (for instance to minimize the power consumption and complexity of the processor and the transceiver), the configuration is optimized through a trial and error means or algorithm. A trial an error means includes scanning, sweeping or testing on one or more or even all possible configurations until a most suitable one is obtained in terms of power consumption, connectivity reliability and alike.

FIG. 6 shows a WMC system (600) according to the disclosure that tunes the radiating system and the device comprising the WMC system, automatically to different frequency bands according to regional frequency allocations across the world; so, one single hardware system adapts to the different regions. The WMC comprised in the radiating system automatically tunes the frequency of operation to the regional frequency bands.

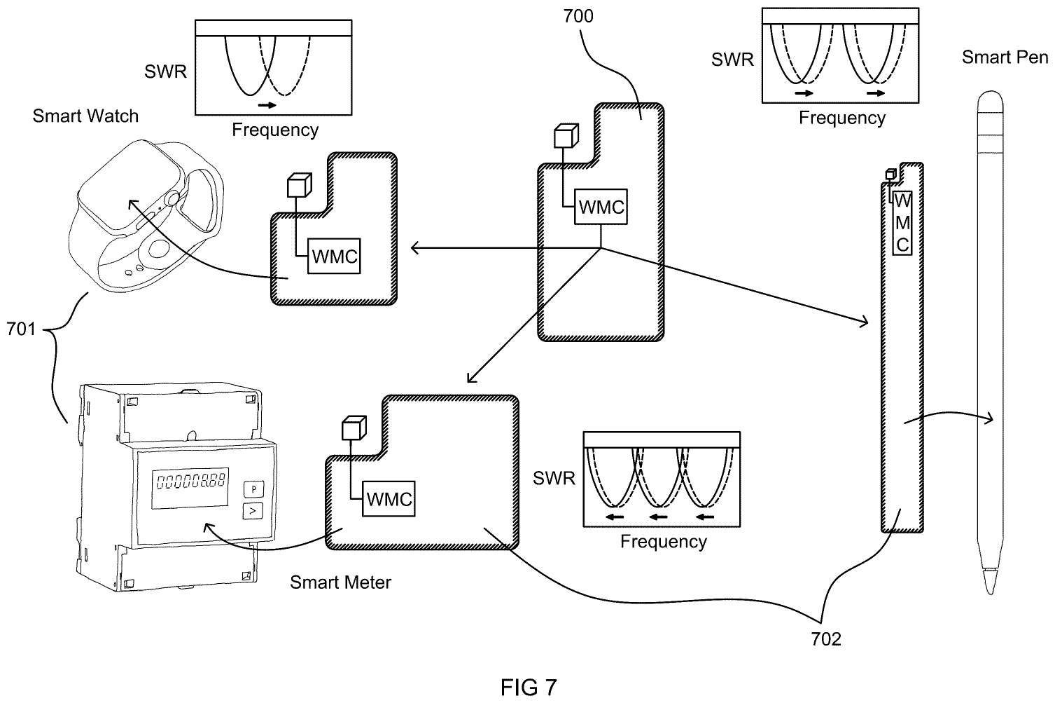

FIG. 7 shows how a single hardware architecture (700) including a WMC system including a UMN or SUMN can adapt to different devices or products (701) with different sizes and form factors, such as smart watch, smart pen, a smart meter, etc. All of them have very different PCB sizes, proportions and form factors for the ground plane element (702) that have an impact in the resonant frequencies of operation of the radiating system. The WMC automatically reconfigures to the different board sizes and tunes the radiating system to maximize radiation in every platform or device. So, one single hardware architecture adapts to different devices or products with minimal engineering effort, reducing engineering costs, production and logistics costs and time to market.

FIG. 8 shows a single hardware architecture including a WMC system (800) including a SMN or SUMN that can adapt to different mounting environments (801). In close proximity of different materials, as for example, brick, metal, wood or biological tissue, the radiating system can be detuned due to the interaction and reflection of radiated waves into the different materials. The WMC system retunes the single hardware architecture to the required frequency bands to optimize the performance in every environment.

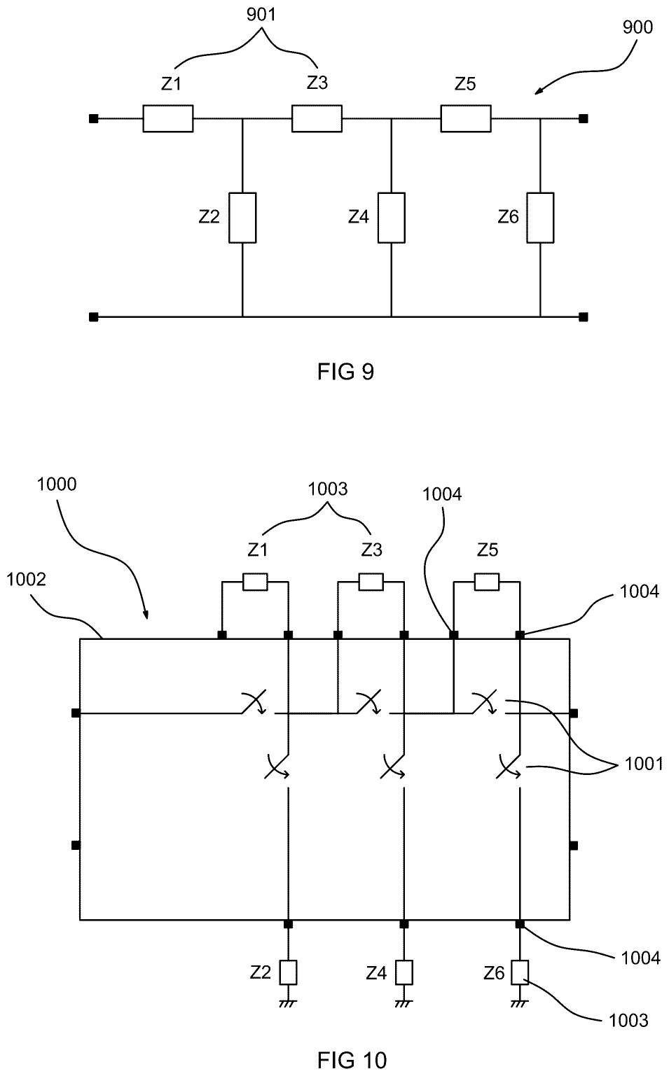

FIG. 9 provides a generic circuit topology (900) for a universal matching network (UMN), for a self-adaptive matching network (SMN) or for a self-adaptive universal matching network (SUMN) according to the disclosure, including matching elements impedance values Zx. The circuit topology comprises six matching circuit elements (901), arranged in a 3 stages of series (S) and parallel (P) elements in a SPSPSP matching circuit elements configuration. Each of those 6 matching circuits comprise one or more circuit components such as for instance one or more lumped elements. The topology begins with a series component with value Z₁, which is followed by a parallel component with value Z₂, both components connected to a second series component with value Z₃, followed by a second parallel component with value Z₄, both second circuit components connected to a third series component with value Z₅, which is followed by and connected to a third parallel component with value Z₆. It has been found that particular combinations of the values Z₁ to Z₆ provide impedance matching to a wide range of radiating systems or devices, being a same values combination convenient for different radiating systems or devices, which provides a non-customized universal matching network able to cover impedance matching for more than one radiating system or device. The particular combinations include, in some radiating system embodiments, at least one tunable or reconfigurable circuit component for providing more degrees of freedom to the implementable matching networks and for readjusting or fine-tuning purposes. For the case of a SMN or a SUMN, the values of the matching elements vary in view of the changing environment conditions. So, a radiating system or a device including a SMN or a SUMN comprises at least one tunable or reconfigurable matching element, also providing a non-customized SMN or SUMN, and so that the device or radiating system is able to operate in different environments.

A system in package or SiP embodiment (1000) related to the generic circuit topology (900) presented in FIG. 9 is illustrated in FIG. 10. A switches system comprising six switches (1001) is included in a SoC (1000). A SoC according to the disclosure is a reconfigurable system contained in a chip (1002), comprising at least one module or chip component (1002), able to implement a WMC according to the disclosure, and therefore, able to provide more than one matching network topologies or configurations and, consequently, more than one matching networks. The SiP embodiment from FIG. 10 includes external matching elements or circuit components (1003), connected to the SoC by means of pads or pins (1004). Those circuit components are, in other embodiments, included inside the SiP. In some embodiments, the circuit components comprised in the SiP are tunable or reconfigurable components.

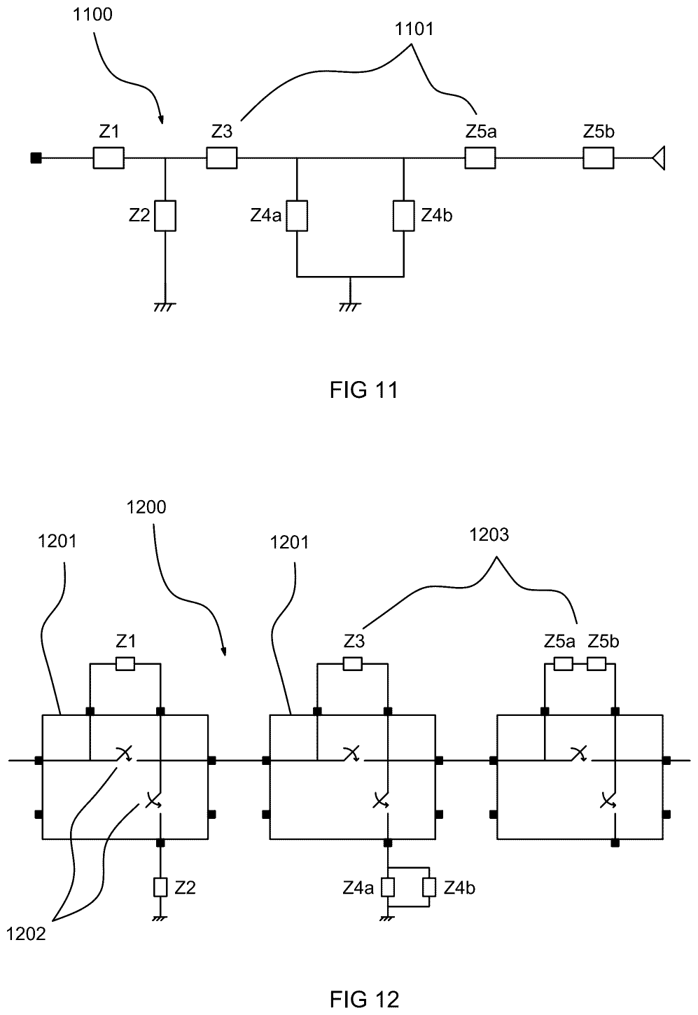

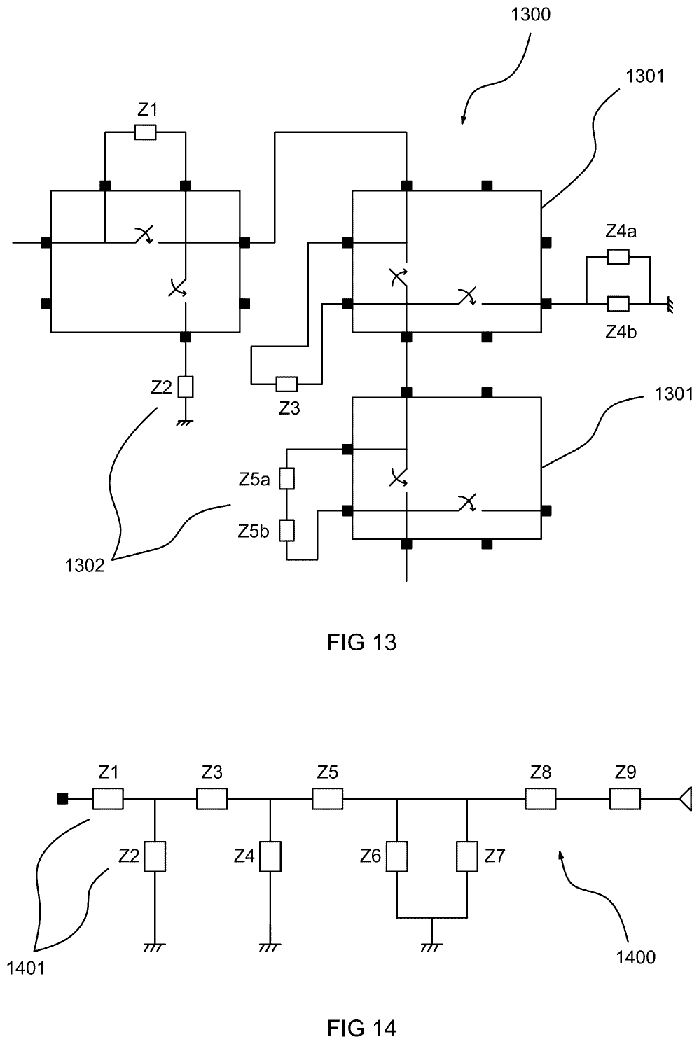

FIG. 11 provides another circuit topology (1100) for a universal matching network (UMN), for a self-adaptive matching network (SMN) or for a self-adaptive universal matching network (SUMN) according to the disclosure, including matching elements or circuit components (1101) with impedance values Zx. The circuit topology is a particular example of the generic circuit topology (900) provided in FIG. 9. This network topology comprises four series circuit components and three parallel circuit components, beginning by a series component, followed by a parallel component, both connected to another series component, which is followed by two parallel components connected between them also in a parallel arrangement, and connected to two series components, one followed by the other (i.e., a SPSPPSS configuration). FIG. 12 provides an example of a SiP (1200) that implements the circuit topology (1100) from FIG. 11. The SiP comprises a SoC comprising a plurality of one module or chip component (1201), wherein each SoC module or chip component comprises a switches system including two switches (1202). This particular embodiment contains SoC components including a switch in series that is connected to another switch in parallel. Each SoC module is connected to another SoC module. Having SoC components comprising a small number of switches reduces the losses related to the SoC component and, consequently, the losses of the entire SoC. Another advantage of having a modular SoC and SiP is the flexibility it provides for being mounted on areas or spaces of different sizes and shapes. A modular SiP or SoC comprises at least two modules or components. FIG. 13 presents another modular SiP embodiment (1300) that implements the circuit topology (1100) from FIG. 11. This modular SiP comprises a modular SoC that comprises three modules or chip components (1301) arranged in a non-cascade, non-linear distribution. Each module includes a switches system comprising two switches, a switch in series that is connected to a switch in parallel. The three modules are connected between them in an inverted-L arrangement. The switches system states are configured as illustrated in FIG. 12 and FIG. 13 so that the network topology from FIG. 11 is implemented. Circuit components or matching elements (1203), (1302) are externally connected to the respective SoCs for both SiP modular examples.

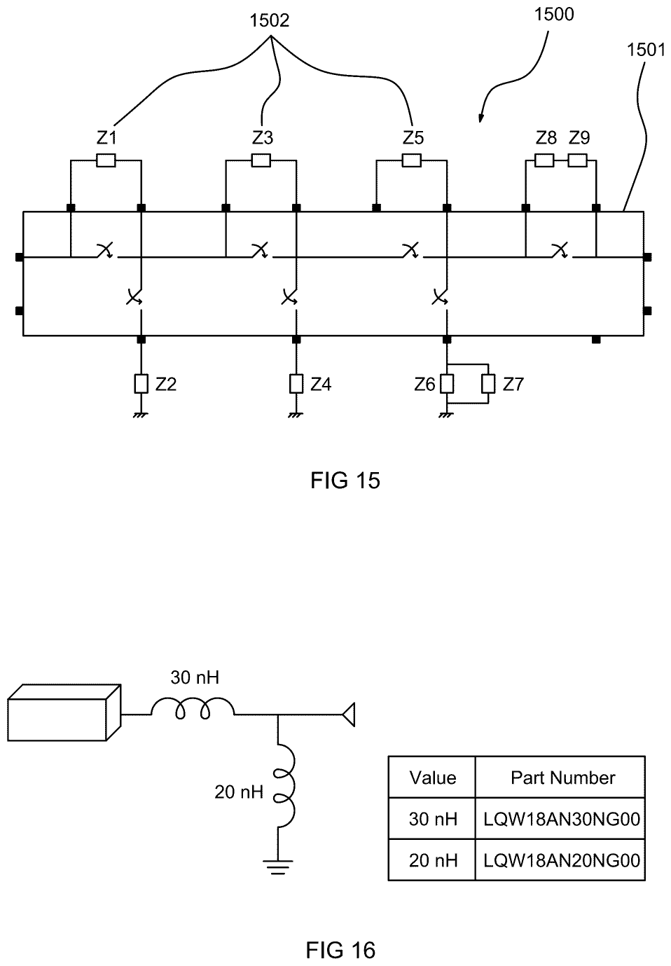

FIG. 14 provides another circuit topology (1400) for a UMN, for a SMN or for a SUMN, featuring a network topology that comprises five series circuit components and four parallel circuit components, so nine circuit components, beginning by a series component, followed by a parallel component, both connected to a series component, followed by another parallel component, connected to another series component, which is connected to two parallel components connected between them also in a parallel arrangement, which are followed and connected to two series components, one followed by the other (i.e., SPSPSPPSS circuit components configuration). Also, the Zx values of the circuit components or matching elements (1401) comprised in this matching network topology are included in the drawing from FIG. 14. FIG. 15 provides an example of a SiP (1500) comprising a SoC component (1501) that implements the circuit topology (1400) from FIG. 14. This SoC includes a switches system based on the one provided in FIG. 10. Again, the circuit components (1502) comprised in the SiP embodiment from FIG. 15 are externally connected to the SoC component, but they are, in other embodiments, comprised inside the SoC and they are also tunable in others.

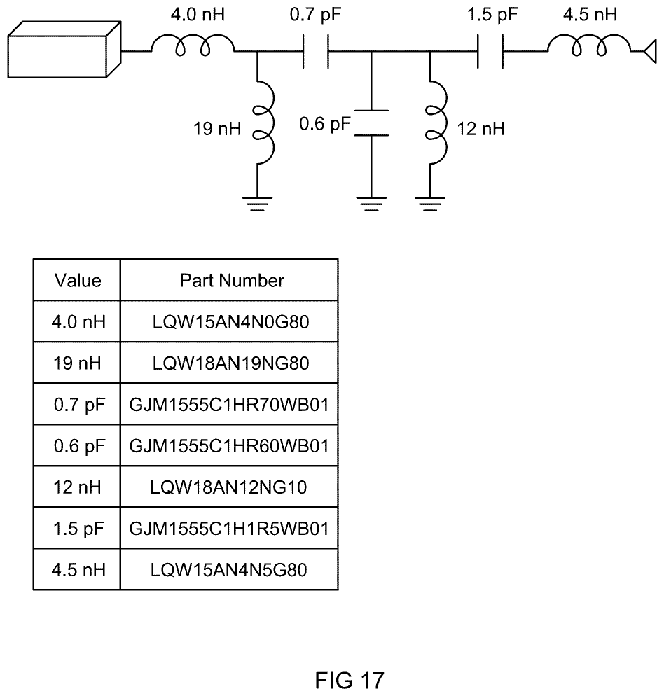

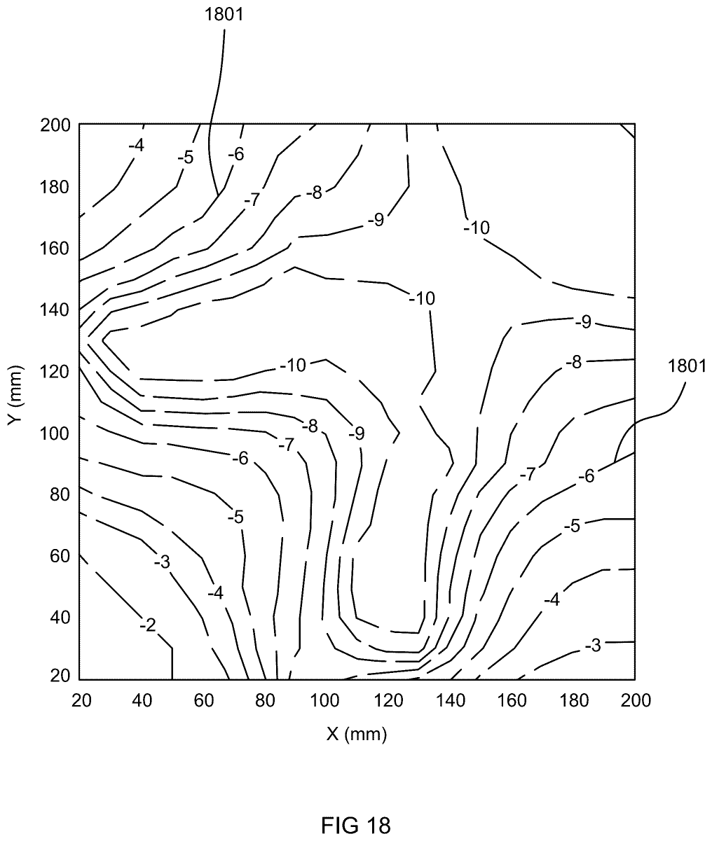

Two universal matching networks able to cover operation for a radiating system according to the disclosure at sub 1 GHz bands, more particularly at least at one LoRa band comprised in the frequency region going from 863 MHz to 928 MHz, and at mobile bands comprised in the frequency regions of operation going from 824 MHz to 960 MHz and from 1710 MHz to 2690 MHz, are disclosed. The UMN covering operation at LoRa bands is provided in FIG. 16. This matching network features an inverted-L configuration and it comprises a series inductor of 30 nH connected to a parallel inductor of 20 nH, advantageously of part numbers LQW18AN30NG00 and LQW18AN20NG00, respectively (SP configuration). The UMN that covers operation within the frequency regions going from 824 MHz to 960 MHz and from 1710 MHz to 2690 MHz is illustrated in FIG. 17. It comprises seven circuit components arranged in the configuration provided in this figure (SPSPPSS), that is a series inductance connected to a parallel inductance, which is connected to a series capacitor, followed by and connected to a parallel arrangement comprising a parallel capacitor and a parallel inductor, which is connected to a series capacitor followed by and connected to a series inductor. The values and the part numbers of the circuit components comprised in it are also provided in FIG. 17, being those values and part numbers by order in the topology described, 4.0 nH, with part number LQW15AN4N0G80, 19 nH with part number LQW18AN19NG80, 0.7 pF with part number GJM1555C1HR70WB01, 0.6 pF with part number GJM1555C1HR60WB01, 12 nH with part number LQW18AN12NG10, 1.5 pF with part number GJM1555C1H1R5WB01 and 4.5 nH with part number LQW15AN4N5G80. A particularity of those UMNs is that the LoRa universal matching network can be contained in the mobile universal matching network, so that a SoC or a SiP can implement both matching networks at a same time.

FIG. 18 provides a mapping of the return loss at the output of the WMC for a wireless device according to the present disclosure along a horizontal x axis and a vertical y axis, related to the dimensions, either the length Lg or the width Wg, of a ground plane layer comprised in a radiating system included in the wireless device. In particular, the radiating system operates at LoRa bands comprised within the range 863 MHz to 928 MHz, considering an input reflection coefficient below −6 dB, see curve (1801), for a range of values Wg and Lg. This map of values is obtained when including the UMN provided in FIG. 16. The radiating system advantageously comprises a RUN mXTEND™ radiation booster, allocated in a clearance area, an area without ground plane, of dimensions Wg×11 mm, 11 mm along the length dimension, and located at 5 mm along the width dimension from the corner of a PCB containing the radiating system. Those Wg and Lg values being for some embodiments of such radiating system, bigger than 85 mm and smaller than 140 mm for the ground plane width Wg and bigger than 85 mm and smaller than 140 mm for the ground plane length Lg, or advantageously, Wg values between 110 mm and 140 mm and Lg values between 110 mm and 140 mm. Also radiating systems featuring a ground plane length Lg bigger than 85 mm and smaller than 160 mm and a ground plane width Wg bigger than 20 mm but smaller than 85 mm, or a length Lg between 160 mm and 200 mm and a width Wg between 80 mm and 200 mm, are matched within that LoRa frequency range by means of the universal matching network from FIG. 16.

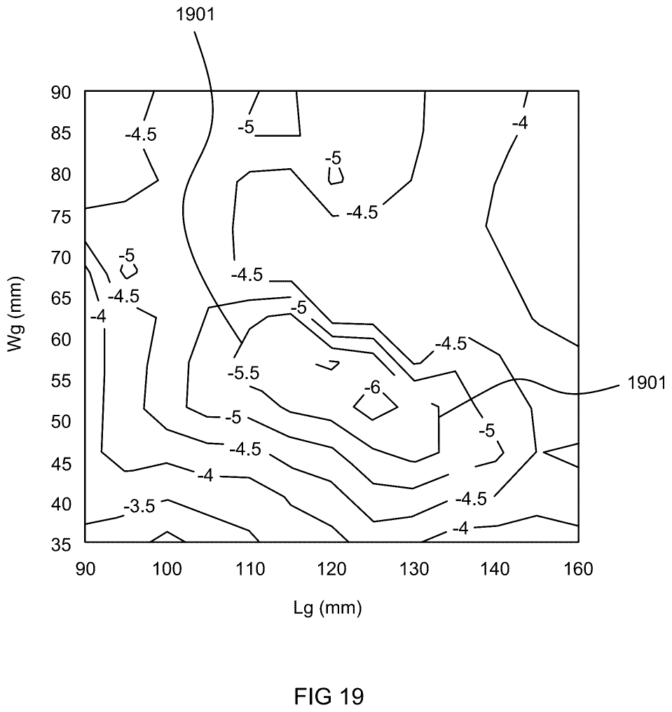

FIG. 19 provides a mapping of the return loss at the output of the WMC for a wireless device according to the present disclosure in function of the dimensions, Wg width and Lg length, of a ground plane layer comprised in a radiating system according to the disclosure, able to operate at mobile bands when including the UMN provided in FIG. 17. The radiating system advantageously comprises a RUN mXTEND™ radiation booster, allocated in a clearance area, an area without ground plane, of dimensions Wg×11 mm, 11 mm along the length dimension, and located at 5 mm along the width dimension from the corner of a PCB containing the radiating system. The radiating system operates at mobile bands comprised within the frequency regions going from 824 MHz to 960 MHz and from 1710 MHz to 2690 MHz, considering an input reflection coefficient below −5.5 dB, see curve (1901), for a range of values Wg and Lg. Radiating system embodiments comprising ground plane layers characterized by a length bigger than 110 mm but smaller than 130 mm and a width larger than 50 mm but smaller than 60 mm, or advantageously, by an Lg bigger than 110 mm but smaller than 122 mm and a Wg bigger than 55 mm but smaller than 60 mm, or by an Lg bigger than 122 mm and smaller than 130 mm and a Wg bigger than 50 mm but smaller than 55 mm, are matched with the universal matching network presented in FIG. 17, at the frequency regions going from 824 MHz to 960 MHz and from 1710 MHz to 2690 MHz. Since the LoRa universal matching network can be contained in the mobile universal matching network, some of those last radiating system embodiments can be operative at LoRa frequencies, within the range or frequency region going from 863 MHz to 928 MHz, and at mobile frequency bands within the frequency regions between 824 MHz to 960 MHz and from 1710 MHz to 2690 MHz, with just a change on the switch state.

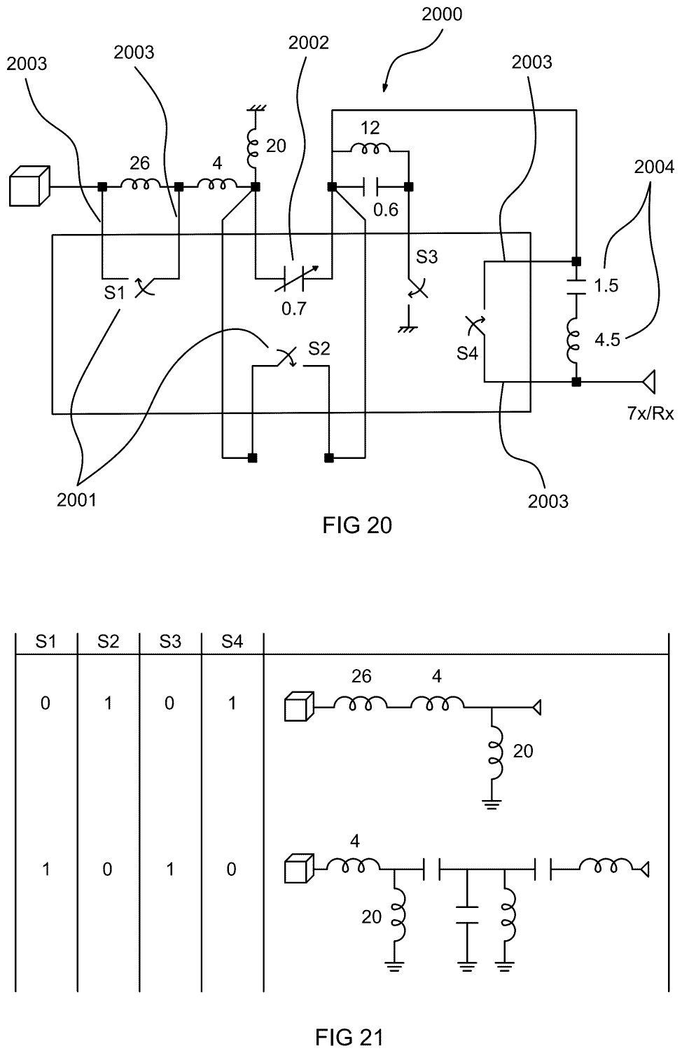

A SiP embodiment (2000) that implements the universal matching networks provided in FIG. 16 and FIG. 17 is illustrated in FIG. 20. The SiP advantageously comprises four switches (2001) and implements either the matching from FIG. 16 or the matching from FIG. 17. This SiP also comprises a fixed or a tunable capacitor (2002) inside the chip component and comprises SiP pins or pads (2003) for connecting external circuit components (2004). The circuit components comprised in the UMNs from FIG. 16 and FIG. 17 are comprised in the SiP as shown in FIG. 20 by connecting them to the SiP pads. The switches system state needed for implementing the LoRa matching network from FIG. 16 are S1, first switch, OFF, S2, the second switch, ON, S3, third switch, OFF and S4, fourth switch, ON, as provided in FIG. 21. The switches system state required for implementing the mobile frequencies matching network from FIG. 17 are S1, first switch, ON, S2, the second switch, OFF, S3, third switch, ON and S4, fourth switch, OFF, as also provided in FIG. 21.

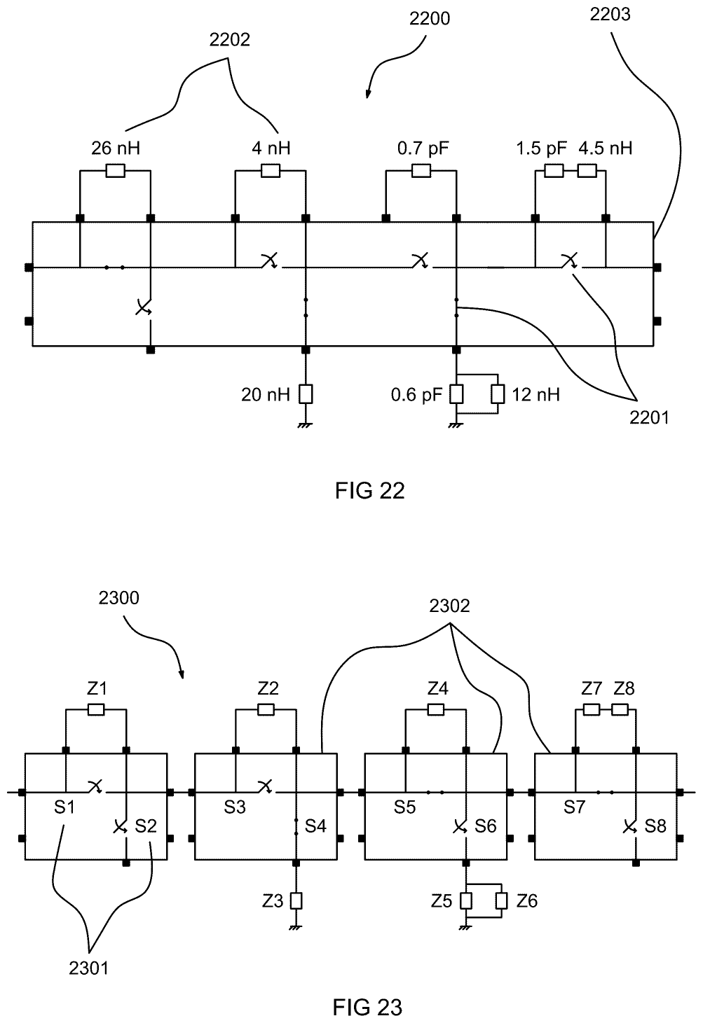

Another embodiment of a SiP (2200) able to implement the LoRa and mobile universal matching networks provided in FIG. 16 and FIG. 17, respectively, is presented in FIG. 22. This SiP comprises seven switches (2201) and all the matching elements (2202) should be connected externally to the SoC component (2203). The circuit components comprised in the UMNs from FIG. 16 and FIG. 17 are connected to the SiP. And the switches states (set of ON or OFF switches) represented in FIG. 22 are the required for implementing the universal mobile matching network from FIG. 17.

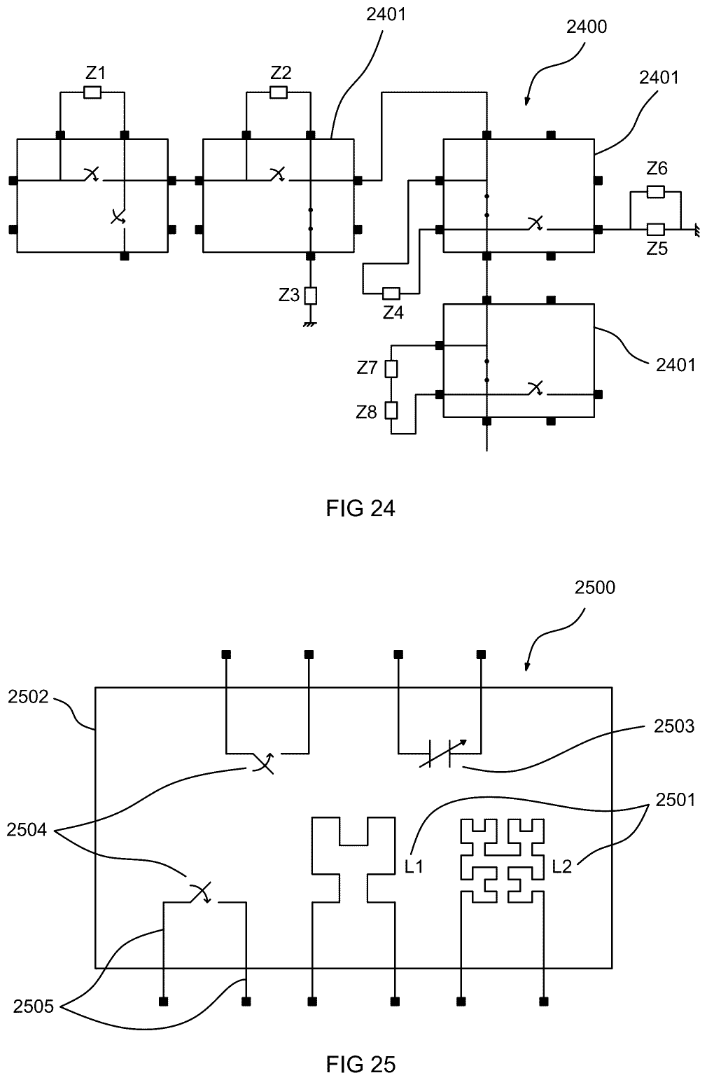

Additionally, a modular SiP embodiment (2300) in FIG. 23 can also be used for implementing the UMNs provided in FIG. 16 and FIG. 17, the modular SiP comprising a SoC that comprises, in some SoC embodiments, at least one module or chip component (2302) comprising two switches (2301), a first one connected in series followed by a second one connected in parallel arrangement. FIG. 23 and FIG. 24 provide two modular SiPs embodiments (2300), (2400) able to implement those universal matching networks. Z1 to Z8 represent the matching elements or circuit components values used in this embodiment for implementing them. In one embodiment Z1 is an inductor of value 26 nH, Z2 is 4 nH, Z3 is 20 nH, Z4 is a capacitor of value 0.7 pF, Z5 is 0.6 pF and Z6 is 12 nH, Z7 is 1.5 pF and Z8 is 4.5 nH. The switch system state (the set of ON/OFF switches) represented in FIG. 23 is such that the LoRa matching network provided in FIG. 16 is implemented. The switch system state required in both embodiments for implementing the mobile matching network from FIG. 17 is S1, first switch, ON, S2, second switch, OFF, S3 OFF, S4 ON, S5 OFF, S6 ON, S7 OFF and, finally, S8 OFF. The SoC embodiment illustrated in FIG. 23 provides a modular SoC embodiment comprising linearly arranged modules 2302. The SoC embodiment illustrated in FIG. 24 provides a modular SoC embodiment comprising modules or components (2401) arranged in an inverted-L configuration. Using modular SoC and SiP embodiments provides flexibility in allocating and integrating the SoC in the space available in the radiating system.

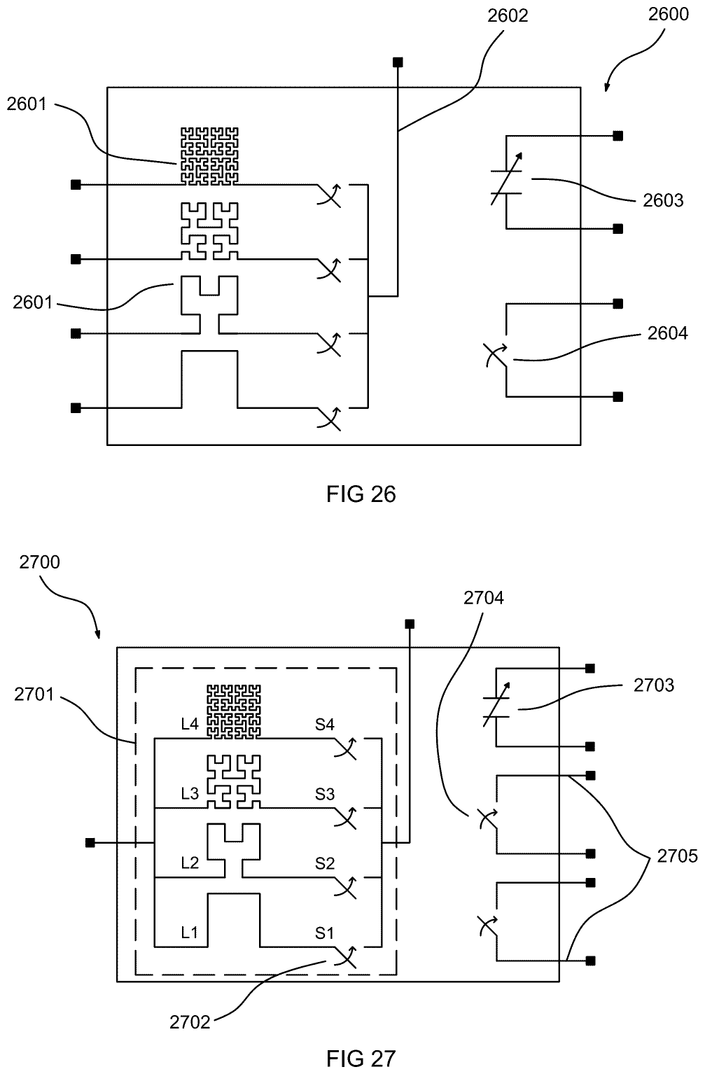

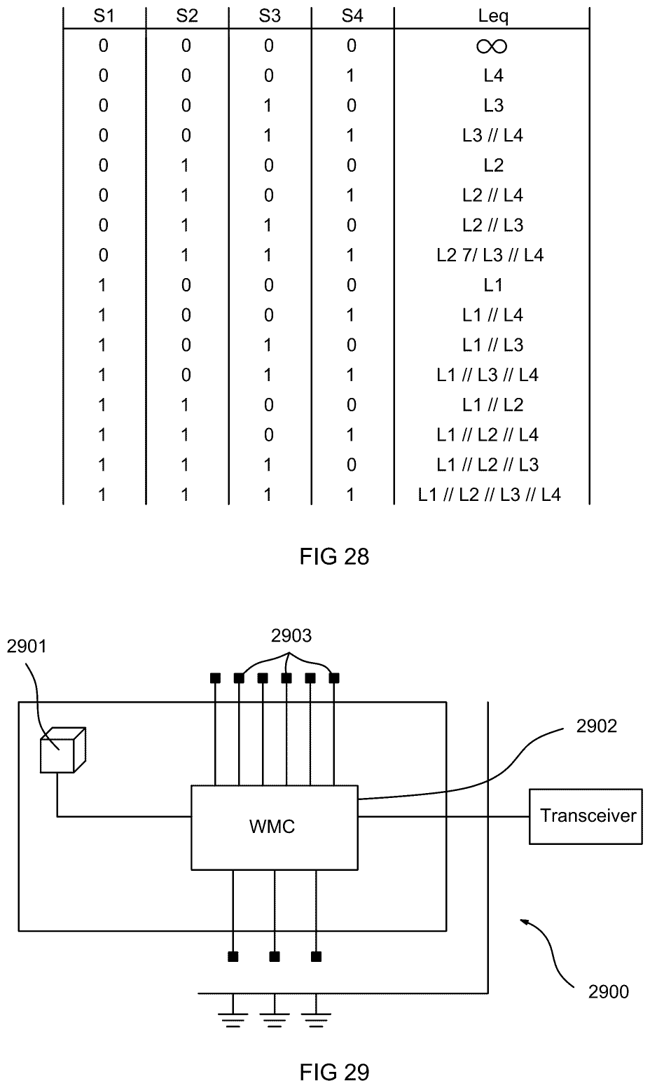

A SiP embodiment according to the present disclosure can contain matching elements, typically being circuit components, within the SiP, embedded in it. So, some SiP embodiments contain embedded integrated and/or printed inductors, as illustrated in FIGS. 25-27. FIG. 25 provides a SiP embodiment (2500) containing more than one embedded printed inductor (2501) in one chip component (2502), each of them representing a particular inductance value, L1, L2. This SiP embodiment further comprises a tunable capacitor (2503) inside the chip component, and a plurality of switches (2504) connected to external pins or pads (2505) available for adding external matching elements or circuit components. FIG. 26 provides another SiP embodiment (2600) comprising embedded printed inductors (2601). In this particular example, those printed inductors share a common external pad or pin (2602) for connecting them to external elements. This SiP embodiment also comprises an internal tunable capacitor (2603) and an internal switch (2604) able to be connected to external elements. Other SiP embodiments containing inset printed inductors (2700) comprise a bank (2701) of embedded printed inductors, as the example provided in FIG. 27. The bank of embedded printed inductors comprises at least one switch (2702) for interconnecting the printed inductors between them in a parallel arrangement, providing a variable inductance value. The example from FIG. 27 includes a table provided in FIG. 28, showing combinations of the switches states and the equivalent inductance related to each switches states combination. This SiP embodiment also comprises an embedded tunable capacitor (2703) and additional inset switches (2704) connected to external pads (2705) for connecting external matching elements or circuit components to the SiP chip component.

FIG. 29 presents a SiP embodiment (2900) further comprising an embedded, integrated or inset non-resonant element (2901), connected to an also embedded WMC (2902) by means of a conductive strip. A SiP embodiment that comprises an inset non-resonant element simplifies the integration of the radiating system comprising the SiP embodiment in a device. The WMC comprised in such a SiP embodiment is connected to SiP pins or pads (2903) that enable the connection of external matching elements to the WMC comprised in the SiP.

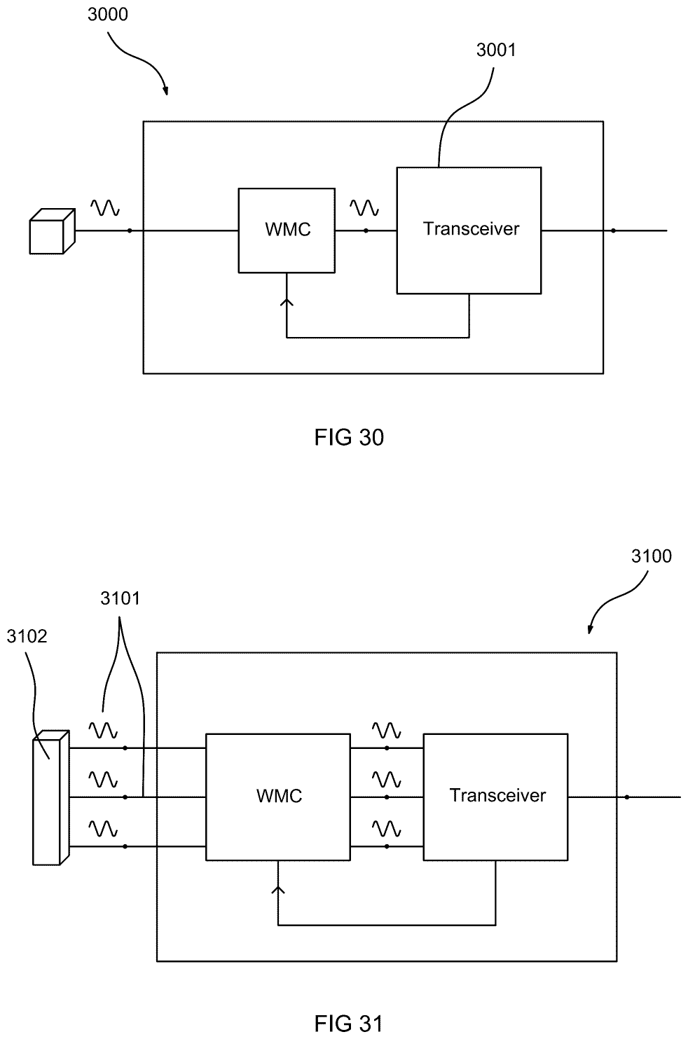

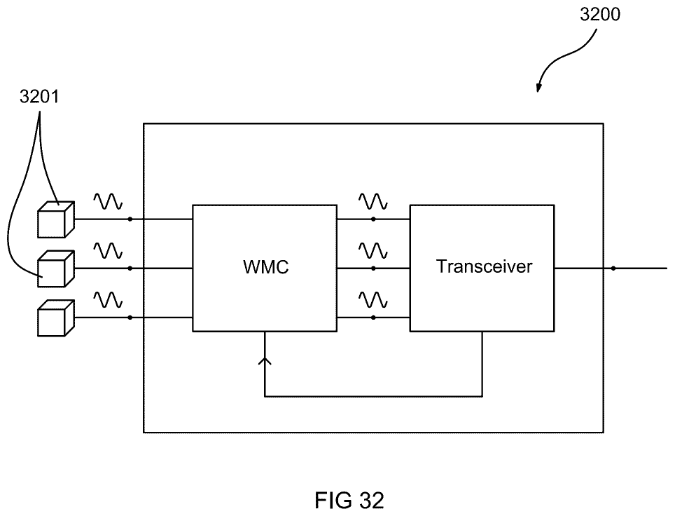

FIG. 30 shows a SiP embodiment comprising an embedded transceiver (3001), which is connected to a WMC also comprised in the SiP. The SiP is prepared for working at one communication standard, while other SiP embodiments are prepared for working at more than one (3101), like the one illustrated in FIG. 31. Particularly, the multi-communication standard embodiment also comprises an embedded transceiver in the SiP, which communicates with a WMC included in the SiP. This embodiment comprises more than one non-resonant element, comprised in this case in a single piece or component (3102). Other SiP embodiments according to the disclosure that comprises an embedded transceiver, like the one provided in FIG. 32, include more than one non-resonant elements comprised in different pieces or components (3201).

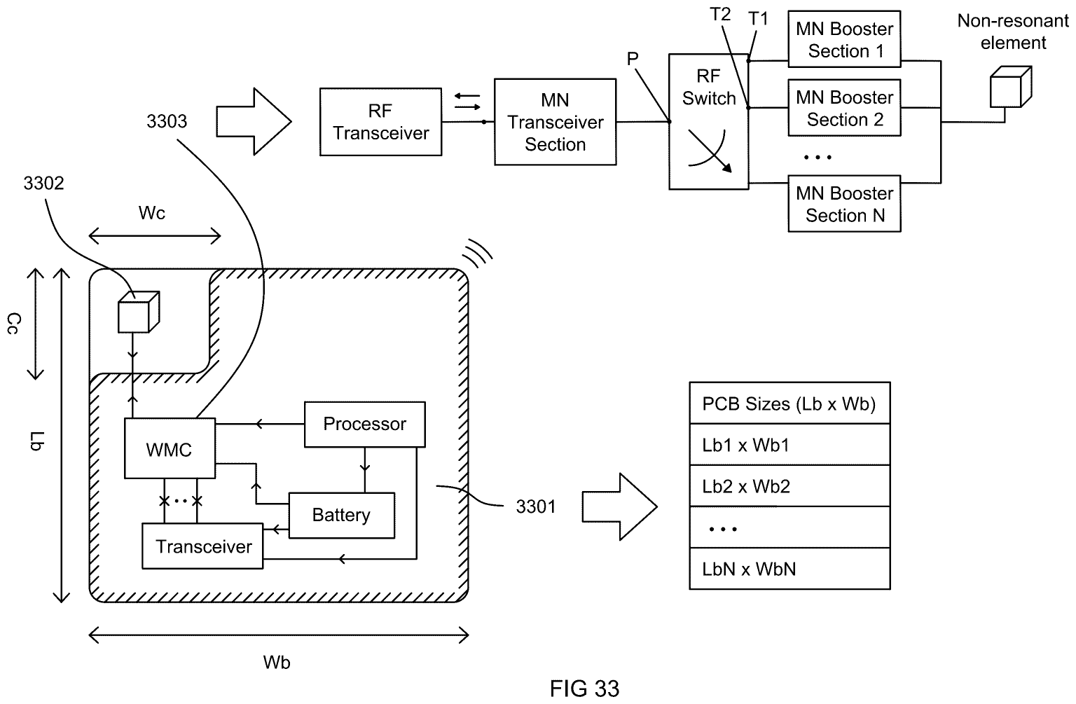

FIG. 33 provides an embodiment of a wireless device or a wireless communications system according to the disclosure that includes a non-resonant element (3302), a WMC (3303) and a PCB comprising a ground plane element (3301), the PCB featuring a variable length Lb and/or a variable width Wb. The WMC comprises a self-adaptive universal matching network, SUMN, that matches the device or system at more than one frequency bands of operation, so that the device can adapt its operability to different device dimensions or to a diversity of scenarios and use contexts or so that it can optimize its performance by selecting an optimal frequency band of operation. The SUMN comprised in the WMC comprised in the embodiment from FIG. 33 features a reconfigurable topology and comprises an RF switch that is connected to some matching elements, the RF switch comprising a single pole or input P and at least two throughs or outputs T. Additionally, the RF switch is multi-path and it also allows to connect the matching elements to a ground internal connection of the switch, providing the WMC with more configurable matching network topologies or matching network configurations. Also, the SUMN comprised in the WMC included in the wireless device or wireless communications system provided in FIG. 33 comprises a matching network (MN) transceiver section and at least one matching network (MN) booster section connected to the switch, the MN transceiver section being connected to the switch and to an RF transceiver and the at least one MN booster section being connected to the non-resonant element and to the switch, so that the at least one MN booster section is connected to the MN transceiver section through the switch.

A non-resonant element is connected to the MN booster sections connected to the switch by for instance at least one conducting strip or at least one transmission line. Those transmission lines or conducting strips can have an impact on the impedance seen at the throughs of the switch, after the matching network booster sections. Then, those transmission lines can be an additional matching element that helps to adjust the impedance matching obtained with the matching networks implementable with the SUMN.

Both a MN transceiver section and each of the at least one MN booster section comprise at least one circuit element or component. In some embodiments, the MN transceiver section and/or at least one MN booster section comprise at least two circuit elements or components. In some of those embodiments, the MN transceiver section and/or at least one MN booster section comprise 4 circuit elements or components, and in other embodiments, the MN transceiver section and/or at least one MN booster section comprise even 7 or more circuit elements or components. Some of all those embodiments comprise an inductor or a capacitor in the MN transceiver section and/or in at least one MN booster sections. Some of the SUMN embodiments comprised in the WMC provided in FIG. 33 advantageously comprise a 0 ohms resistance in at least one MN booster section and/or the MN transceiver section. In some other embodiments, at least one MN booster section comprises only one circuit component, and in others, each MN booster section comprises only one circuit component. In other embodiments, one MN booster section comprises a circuit component equal or substantially equal to a circuit component comprised in the matching network transceiver section, understood by substantially equal that their corresponding values differ between them a 20%, or a 10% or a 5%. All those circuit components are, in some embodiments, an inductance and, in some other embodiments, a capacitor. Additionally, the MN transceiver section can feature any topology, advantageously being in some embodiments a T-topology (i.e., SPS) that provides versatility for implementing other matching network topologies, like for example an L-topology (SP or PS) or a single-component (S or P) topology.

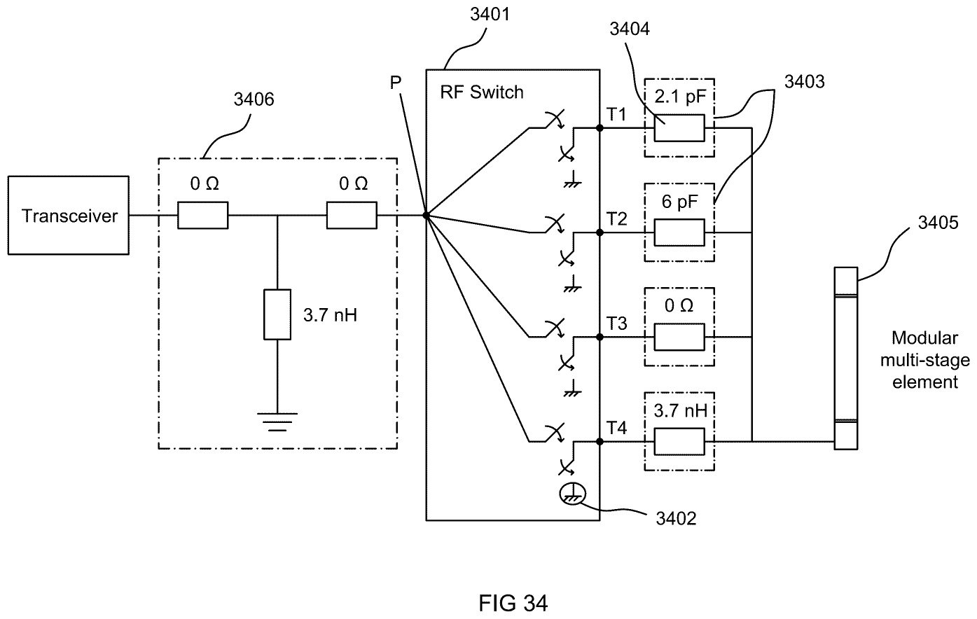

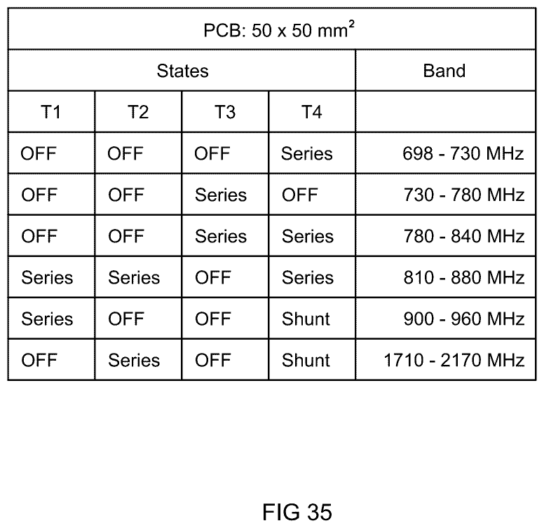

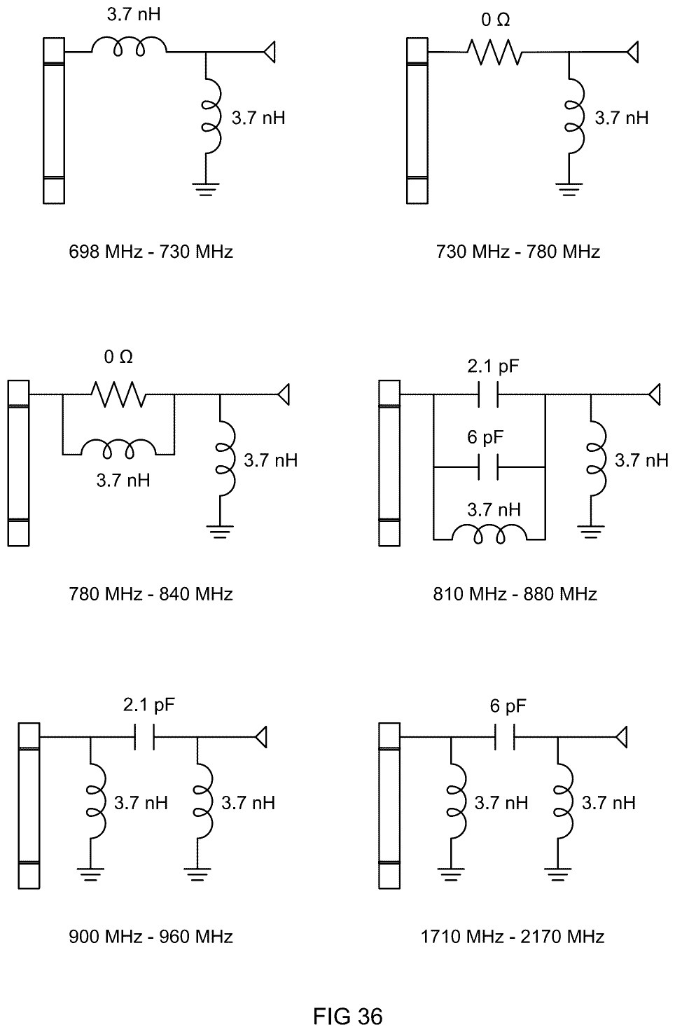

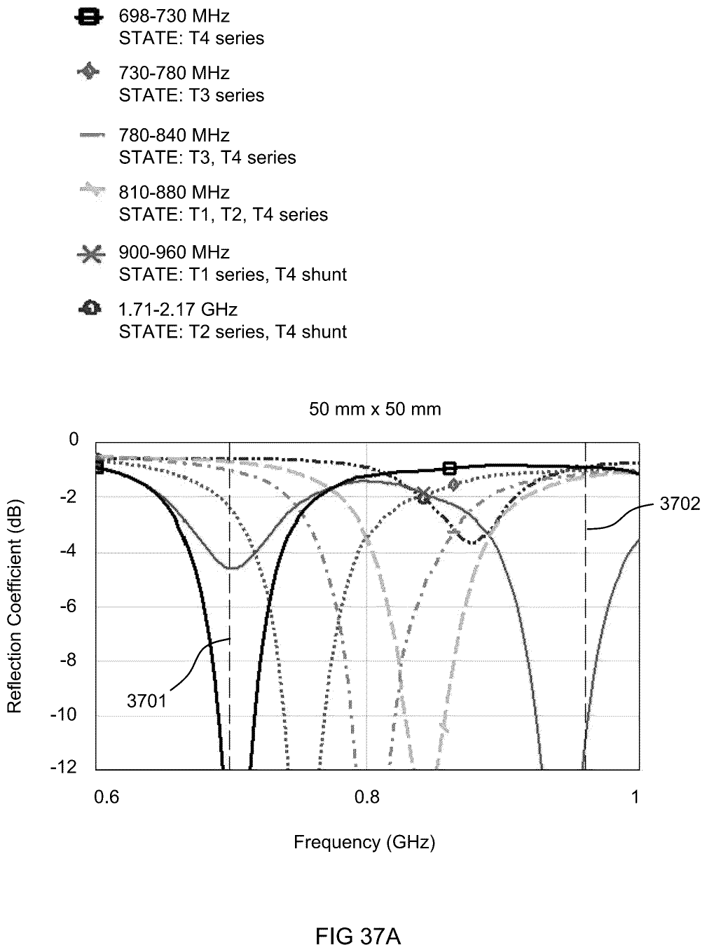

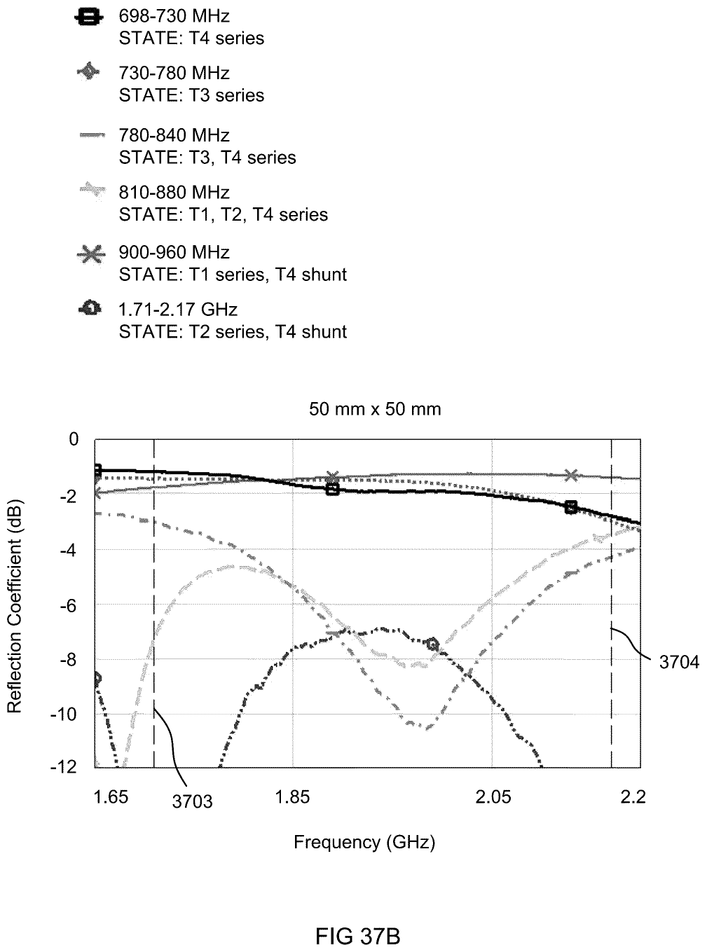

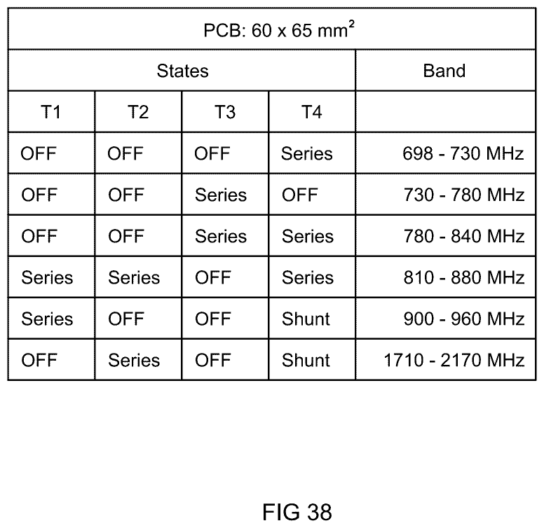

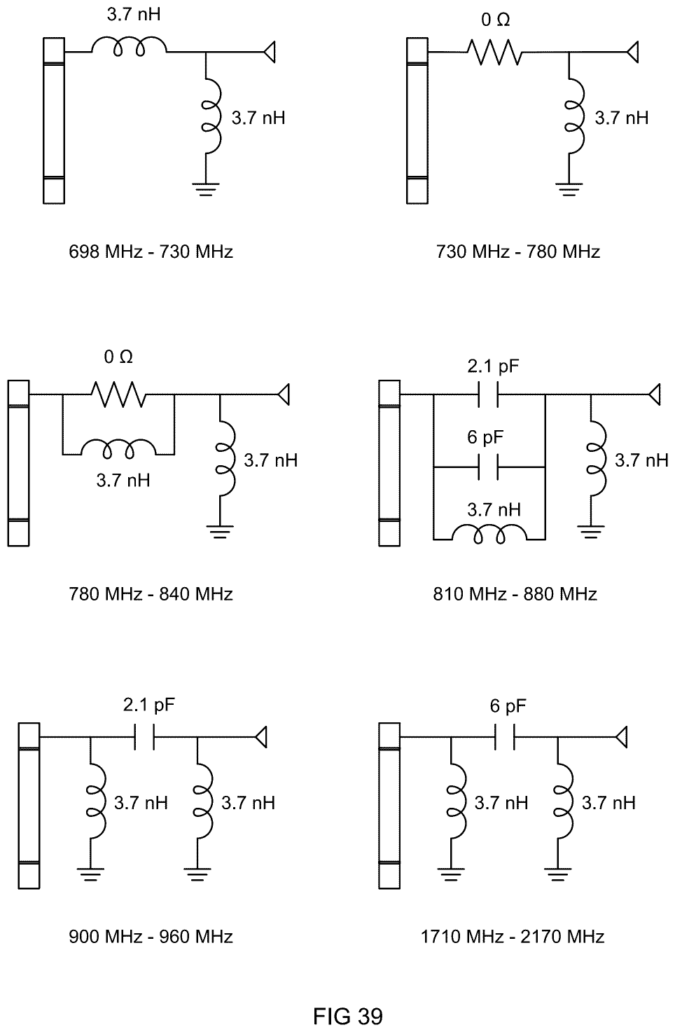

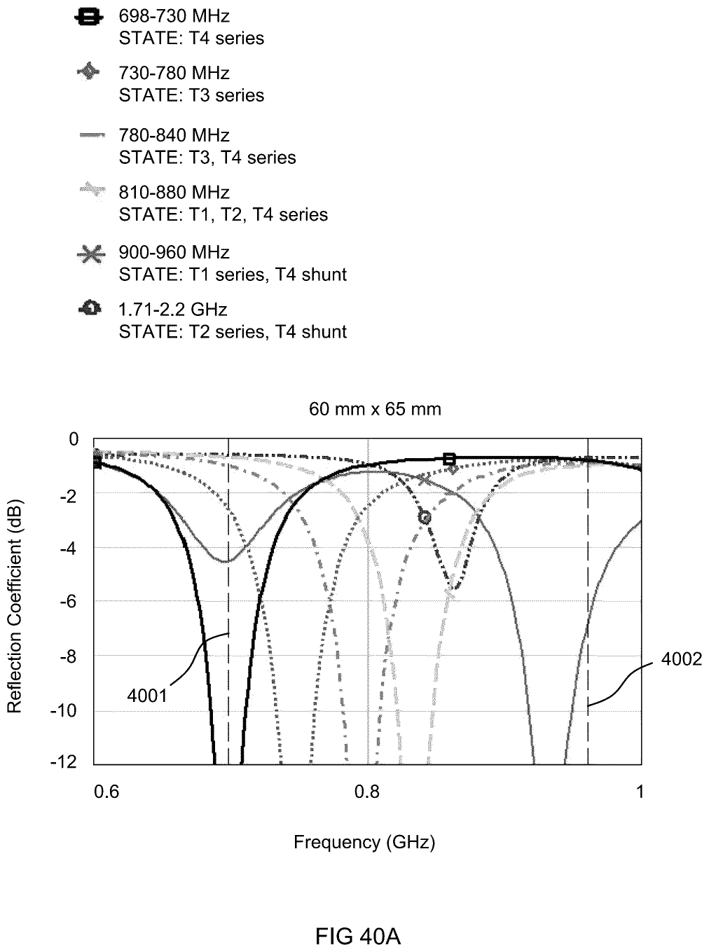

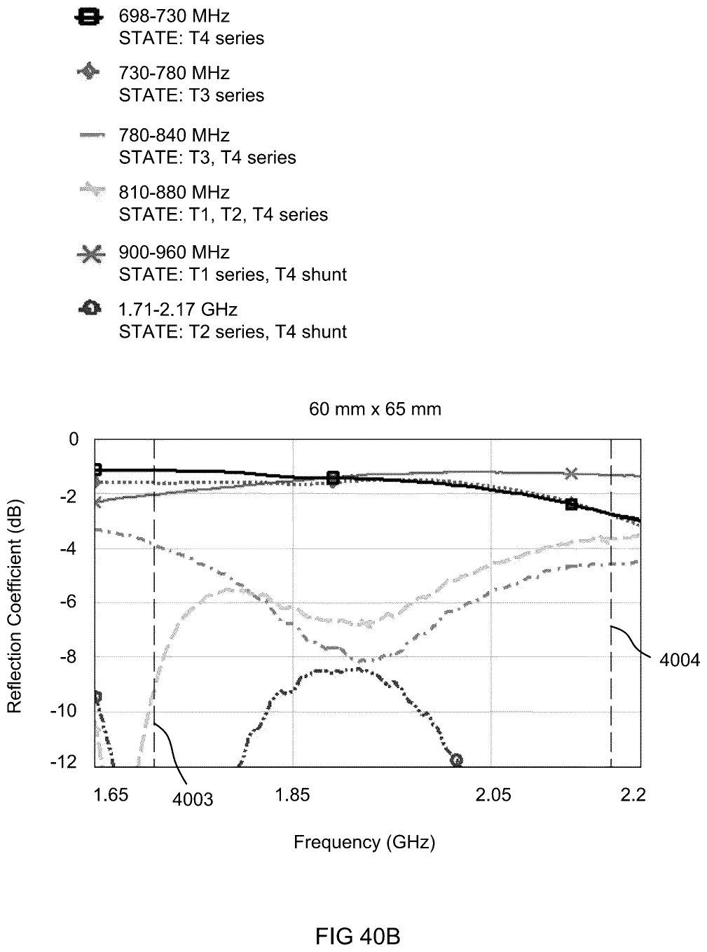

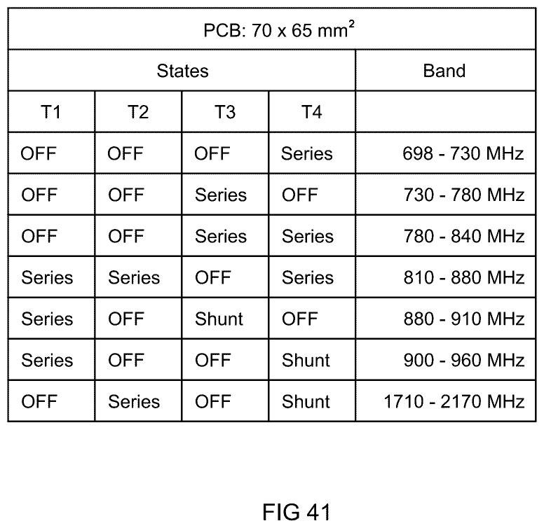

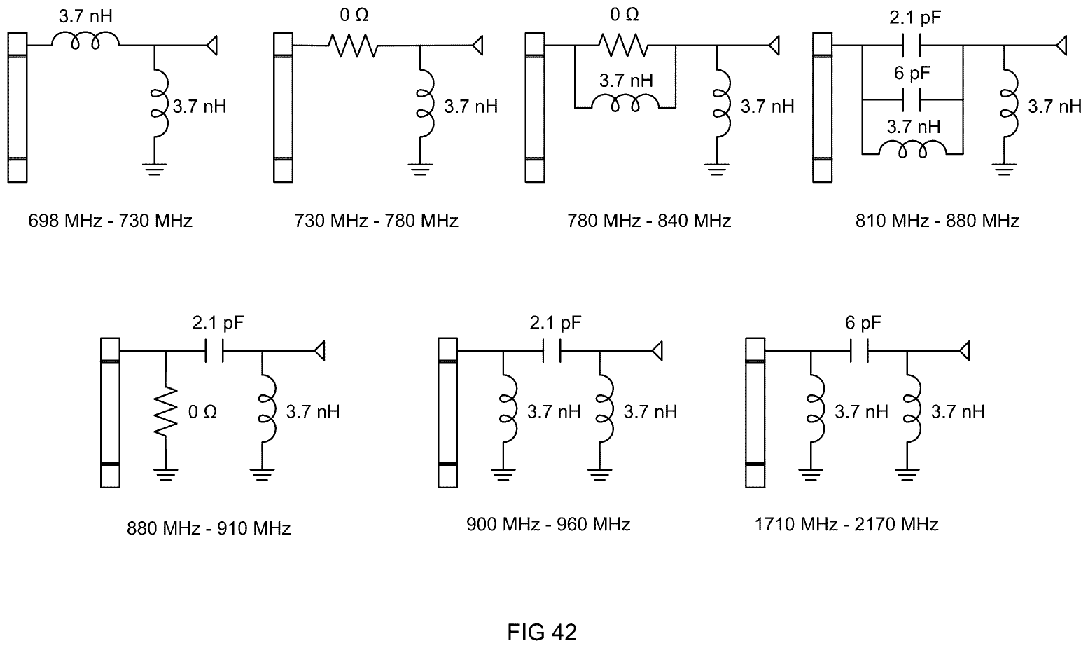

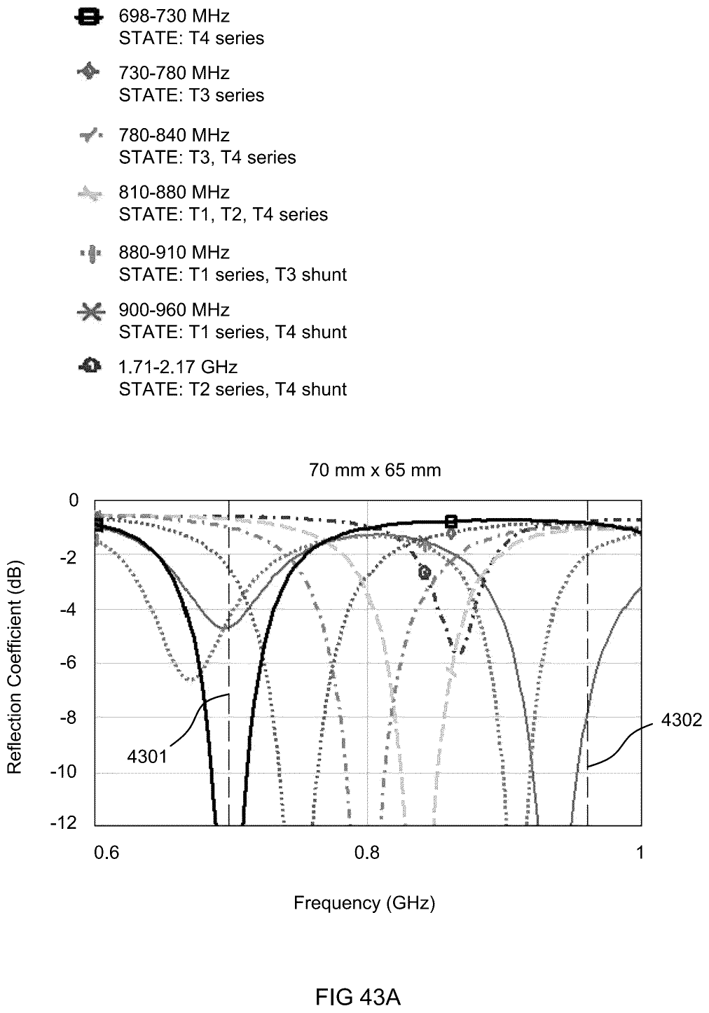

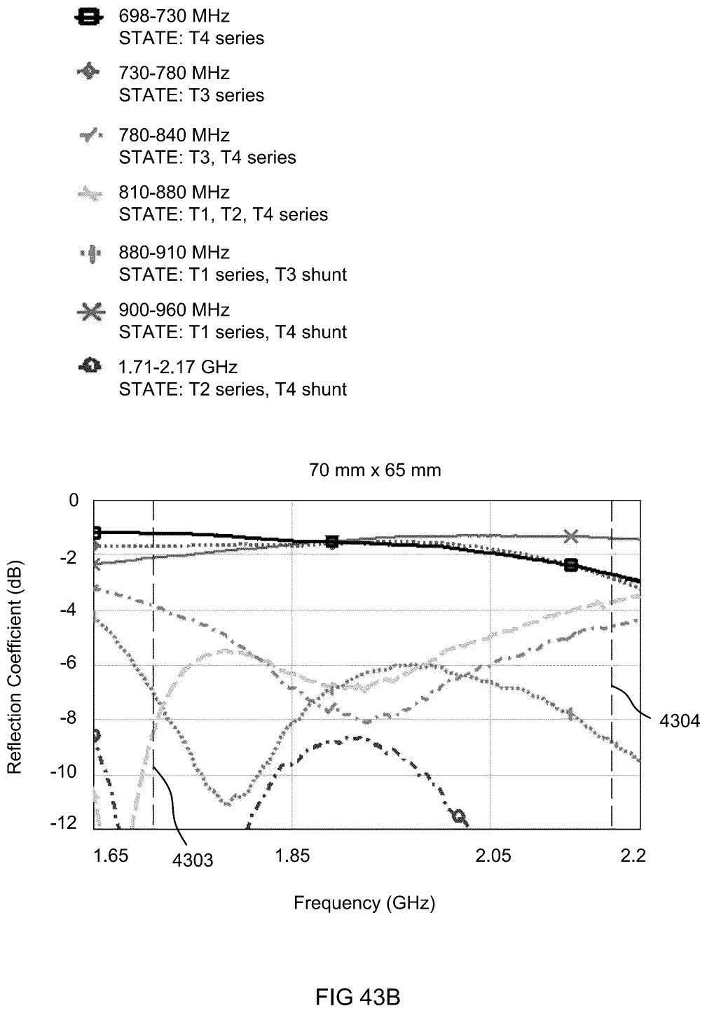

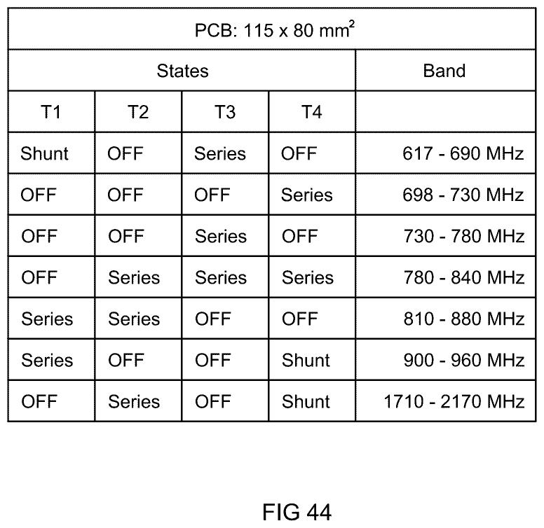

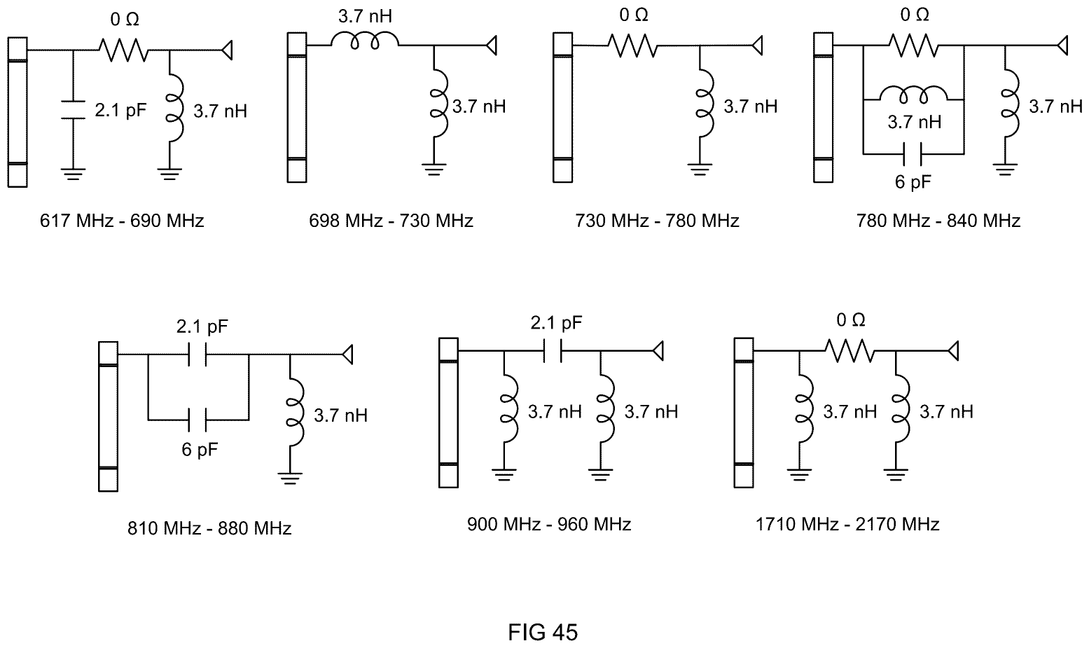

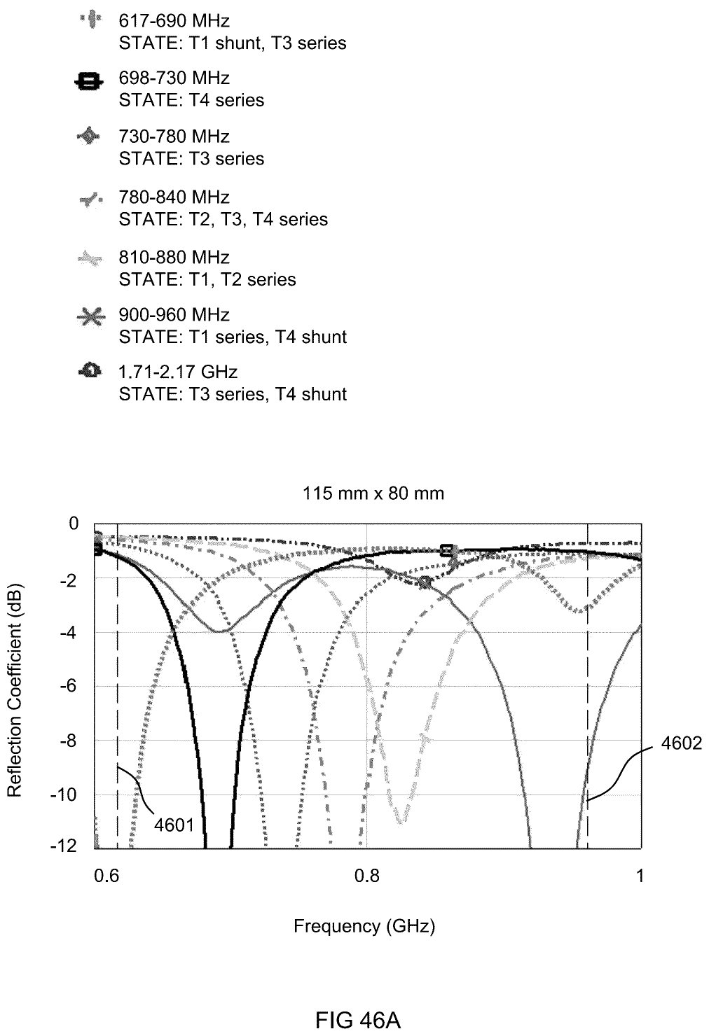

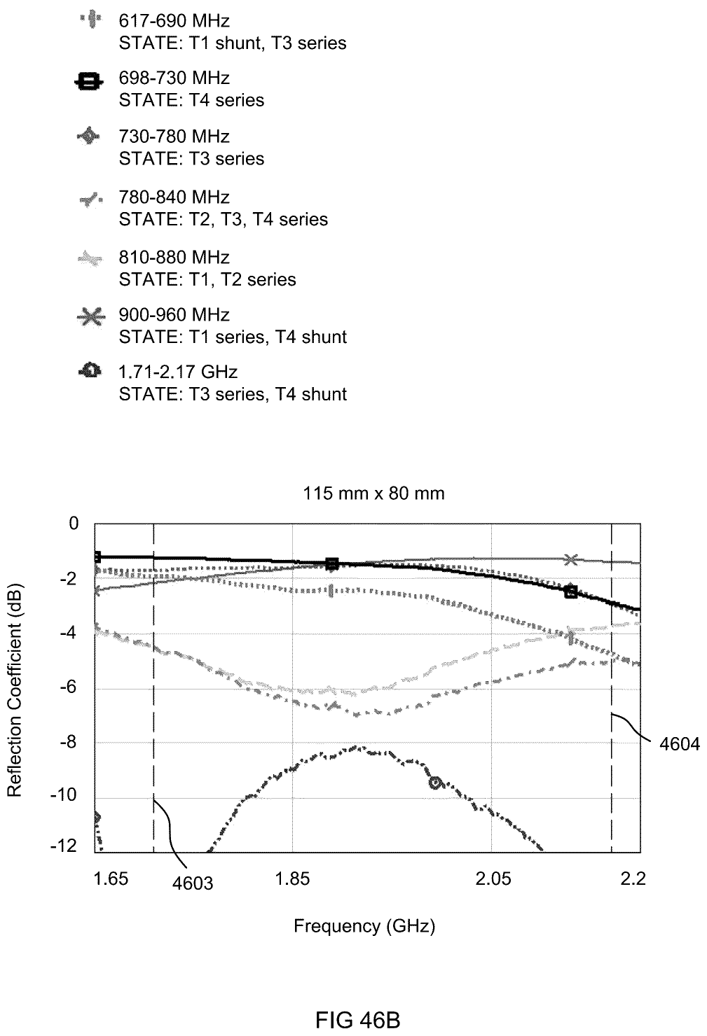

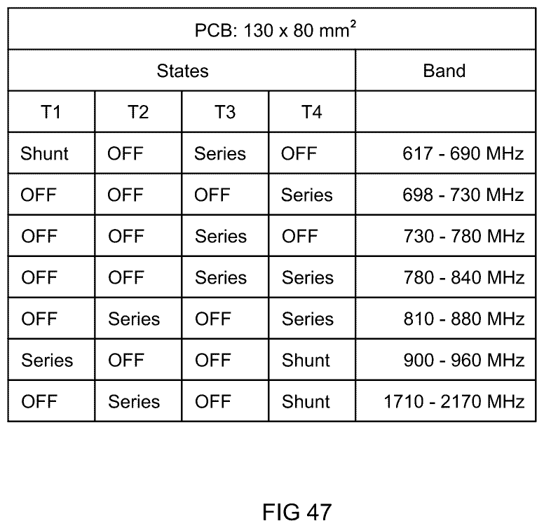

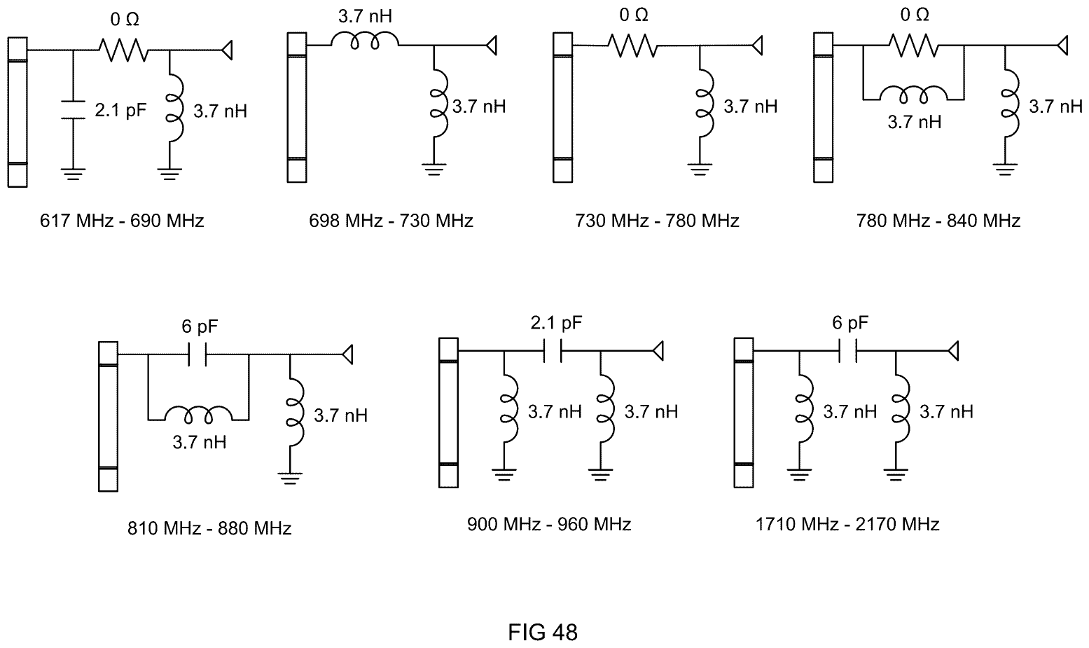

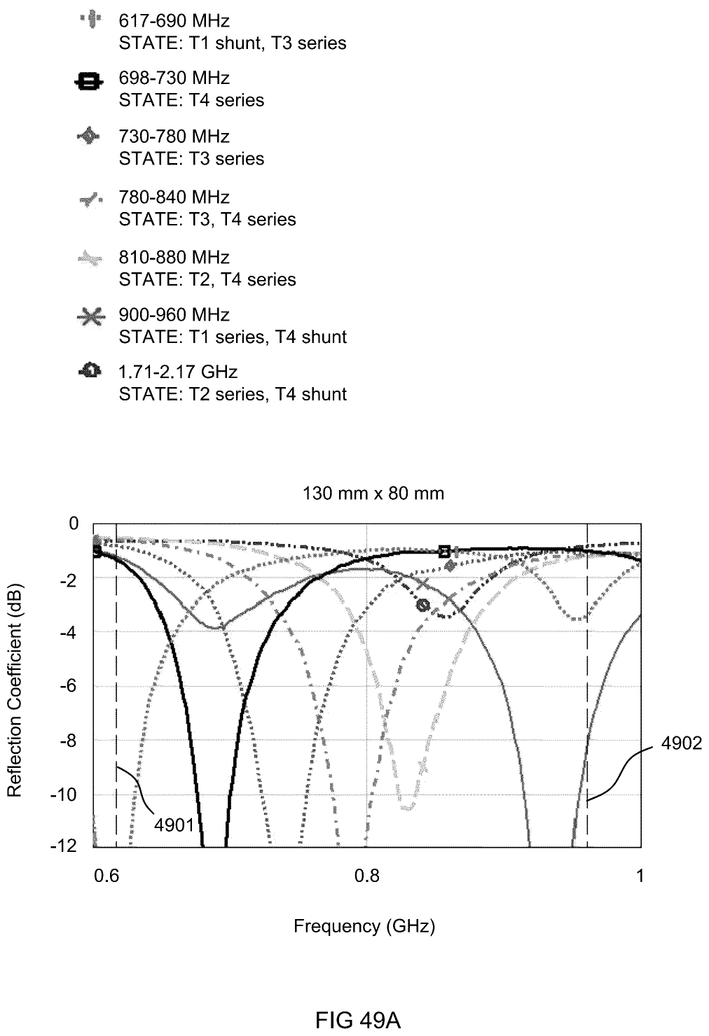

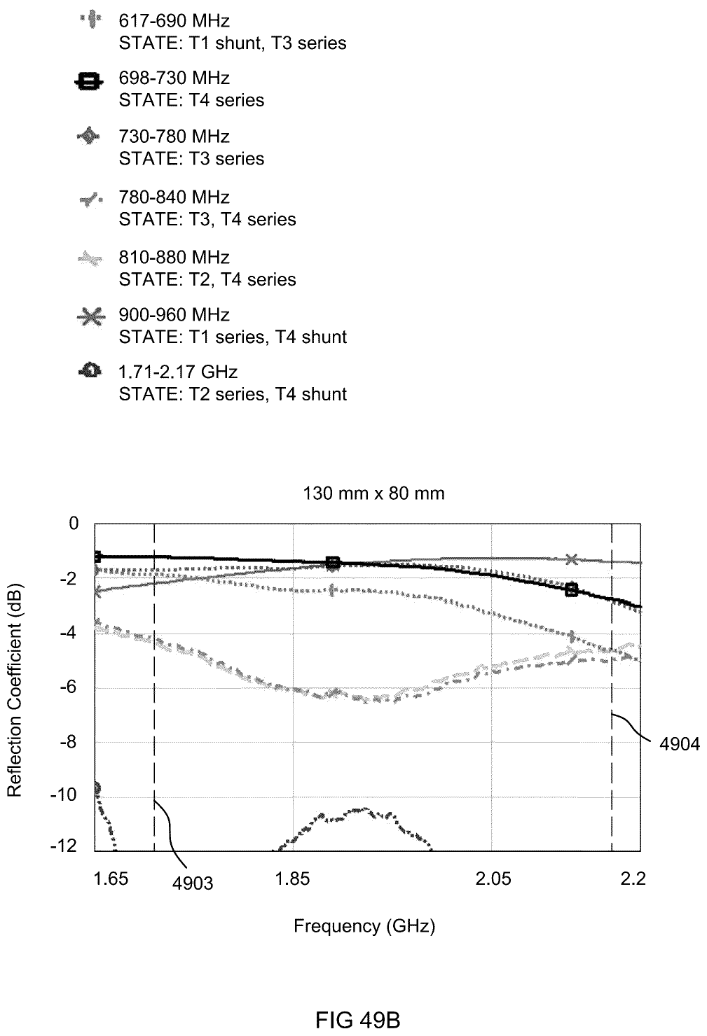

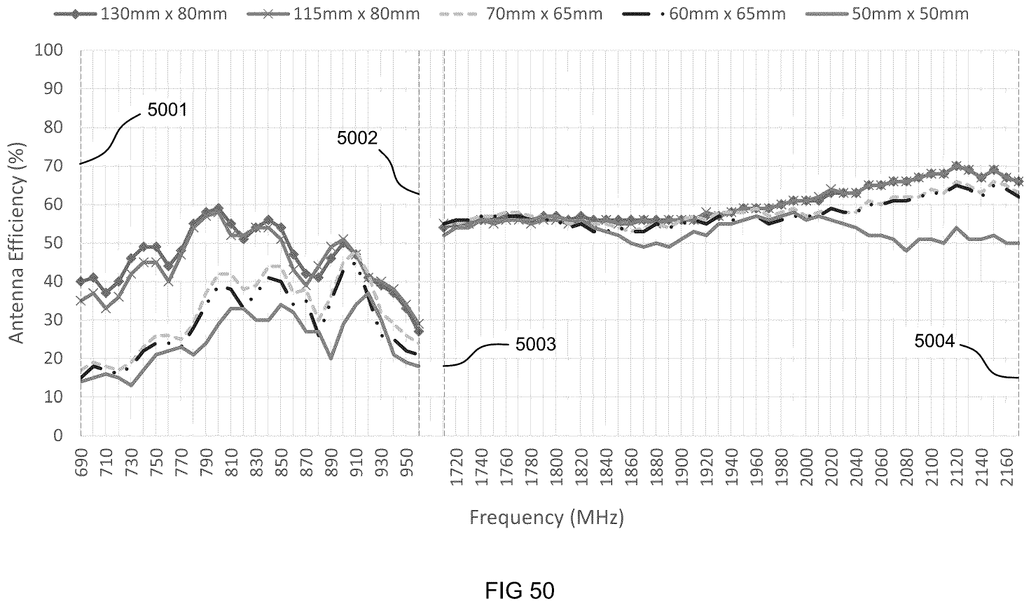

FIG. 34 provides a particular example of a SUMN that comprises a SP4T (single pole 4 throughs) multi-path switch 3401 able to connect one input P to more than one outputs (T1 to T4) at the same time, so that the matching elements connected to the switch outputs can be combined between them. Additionally, each output or through of the switch included in this particular example can be connected to an internal ground 3402, which enables to connect the matching elements in parallel configuration. Such a SUMN is able to match a wireless device or a wireless communications system featuring diverse dimensions. The SUMN comprises four MN booster sections 3403, each connected to a through T of the switch and comprising a circuit element or component 3404. More concretely, those matching network booster sections comprise in some embodiments a capacitor within the 1.7 pF to 2.5 pF range in a first MN booster section, preferably being within the 1.9 pF to 2.3 pF range in other embodiments; another capacitor within the 5.5 pF to 6.5 pF range in a second MN booster section, preferably being within the 5.8 pF to 6.2 pF range in some other embodiments; a 0 Ohms resistance in a third MN booster section; and an inductance within the 3.2 nH to 4.2 nH range in a fourth MN booster section, preferably being within the 3.5 nH to 3.9 nH range in other embodiments. The particular embodiment provided in FIG. 34 comprises a 2.1 pF capacitor in a first MN booster section, a 6 pF capacitor in a second MN booster section, a 0 Ohms resistance in a third MN booster section and a 3.7 nH inductance in a fourth MN booster section, all those MN booster sections connected to a non-resonant element and connected to the switch, the non-resonant element advantageously being in some embodiments a modular multi-stage element 3405, the modular multi-stage element being a multi-section component described in the patents US20200176855A1, EP3649697B1 and CN110870133A, and more concretely being in some embodiments the antenna component described and included in the embodiment from FIG. 29, or the one from FIG. 32 of FIG. 35, from the patents. This multi-stage or multi-section component is in some embodiments a TRIO mXTEND™ antenna component. The mentioned SUMN also comprises a MN transceiver section 3406 connected to the switch and to a transceiver. The MN transceiver section comprises at least one circuit element or component and can feature any topology. The MN transceiver section comprised in the embodiment from FIG. 34 advantageously features a T-topology, which provides versatility in view of the matching networks that can be implemented: an L-topology in some embodiments and, a single-element topology in other embodiments comprising only one circuit element or component, arranged in a series or a parallel configuration. The particular embodiment provided in FIG. 34 includes a parallel 3.7 nH inductance, being in some other embodiments an inductance of value within the 3.4 nH to 4 nH range. The SUMN embodiment from FIG. 34 comprises a parallel 3.7 nH inductance in the MN transceiver section and it also advantageously comprises a series inductance of the same value, 3.7 nH, in one of the MN booster sections. A SUMN embodiment comprising a MN transceiver section and at least one MN booster sections that comprises a substantially similar circuit component in both the MN transceiver section and a MN booster section is an advantageous solution, being substantially similar when their values are equal or within a range between the value plus a 2% of the value and the value minus a 2% of the value. The SUMN from FIG. 34 can be configured by selecting different switch states combinations to configure a plurality of matching network configurations, hereinafter MNCs, according to the size of the ground plane element or the PCB comprised in the radiating system and/or according to different environment conditions or frequency bands of operation. Such SUMN has been used to match a wireless device or a radiating system including a PCB of dimensions between Lb×Wb=50 mm×50 mm and 130 mm×80 mm for operating in two frequency regions going from 617 MHz to 960 MHz and from 1710 MHz to 2170 MHz. All the possible combinations of the states of the throughs T1 to T4 that provide an acceptable matching of the device or the radiating system at the sought frequencies, as well as their related matching networks, are examples of use of the self-adaptive universal matching network (SUMN) from FIG. 34. Some of these examples are here disclosed with the FIG. 35 to FIGS. 49A and 49B. Particularly, FIG. 35 provides a table with different states of the throughs T1 to T4 used to match the sub-bands indicated in the table. This states table is used for matching a device including a PCB of dimensions 50 mm×50 mm. FIG. 36 illustrates the equivalent matching networks resulting from applying the states indicated in the table from FIG. 35 for each sub-band, those sub-bands comprised in the frequency regions of operation going from 698 MHz to 960 MHz and from 1710 MHz to 2170 MHz. The topologies of the matching networks are the ones seen in FIG. 36 and the matching elements values are the ones included in the same figure. For example, a switch states T1 OFF, T2 OFF, T3 OFF and T4 series results in a SP topology comprising a series inductance of 3.7 nH and a parallel inductance of 3.7 nH. It is worth noting that the topologies used for matching the 730 MHz-780 MHz and the 780 MHz-840 MHz bands do not provide the same response because there is an impact of the strip lines that connect the resonant antenna to the switch (and to its matching elements) on the matching impedance at the throughs of the switch and, therefore, on the whole matching. FIG. 37A and FIG. 37B provide the reflection coefficient obtained at the end of each matching network from FIG. 36 (before the transceiver). FIG. 37A corresponds to the low-frequency region of operation and FIG. 37B corresponds to the high-frequency region of operation. As shown here, the SUMN provided in FIG. 34 allows to provide multi-band operation for different devices of different dimensions. FIGS. 38, 39, 40A and 40B provide the switch states used, the matching networks and reflection coefficient obtained for a PCB of dimensions 60 mm×65 mm. FIG. 39 provides the matching networks resulting from the states combinations provided in FIG. 38. Those matching networks are the same as the ones used for matching the device of PCB of 50 mm×50 mm. FIGS. 41, 42, 43A and 43B provide the switch states used, the matching networks and reflection coefficient obtained for a PCB of dimensions 70 mm×65 mm. FIG. 42 provides the matching networks resulting from the states combinations provided in FIG. 41. The topologies of the matching networks are the ones seen in FIG. 42 and the matching elements values are the ones included in the same figure or the previously described in the text for FIG. 34. FIGS. 44, 45, 46A and 46B provide the switch states used, the matching networks and reflection coefficient obtained for a PCB of dimensions 115 mm×80 mm. Again, the topologies of the matching networks are the ones illustrated in FIG. 45 and the matching elements values are the ones included in the same figure or the previously described in the text for FIG. 34. FIGS. 47, 48, 49A and 49B provide the switch states used, the matching networks and reflection coefficient obtained for a PCB of dimensions 130 mm×80 mm. The topologies of the matching networks are the ones illustrated in FIG. 48 and the matching elements values are the ones included in the same figure or the previously described in the text for FIG. 34. Finally, FIG. 50 provides the antenna efficiency obtained at the two frequency regions of operation when using the self-adaptive universal matching network from FIG. 34 for matching a device or a radiating system according to the present disclosure, including a PCB of dimensions 50 mm×50 mm, 60 mm×65 mm, 70 mm×65 mm, 115 mm×80 mm or 130 mm×80 mm. Good antenna efficiencies are obtained with the self-adaptive system, particularly at low frequencies for all the PCB dimensions.

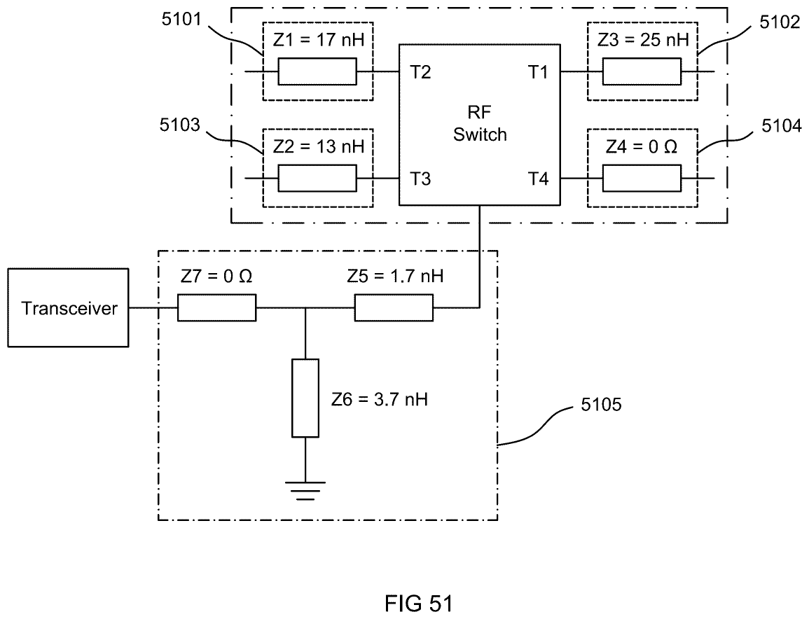

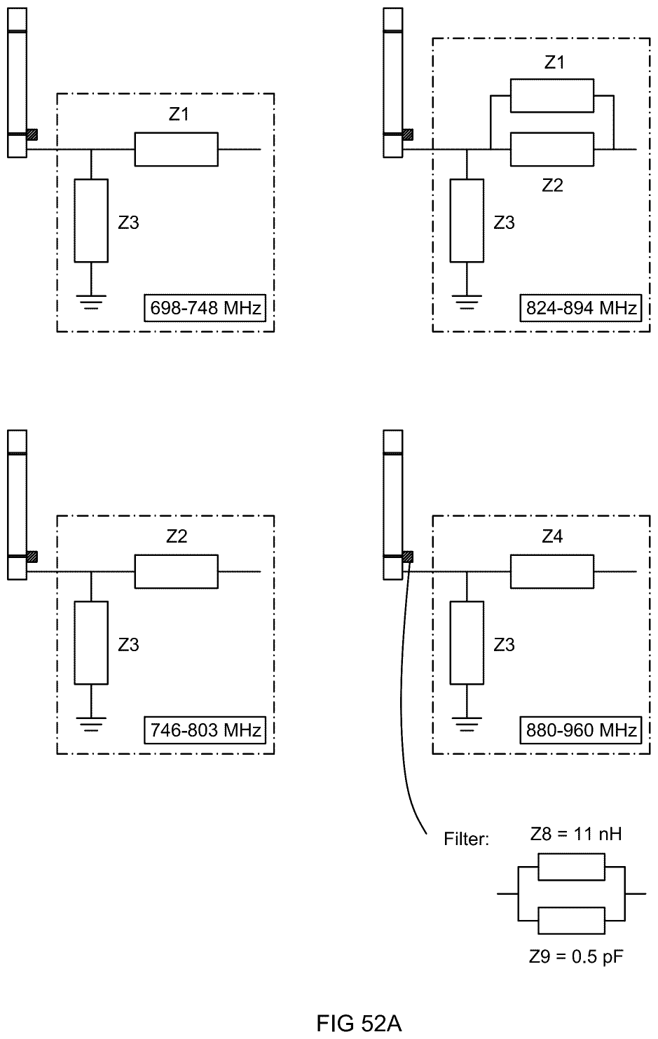

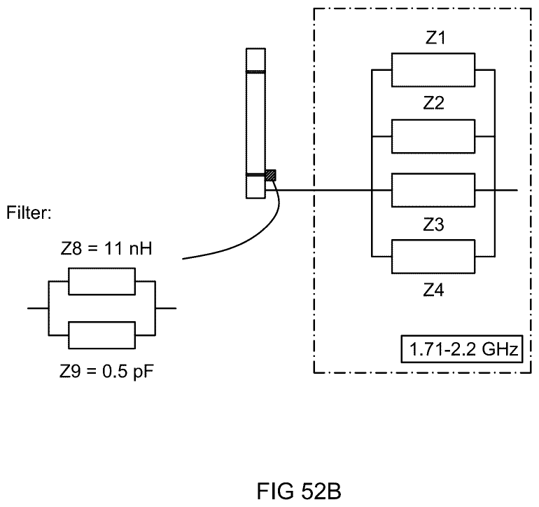

FIG. 51 provides an embodiment of a SMN that comprises a switches system including the switch used in FIG. 34 and previously described. The particular values used for the matching elements connected to the switch are the ones included in the FIG. 51, but those values could be different in other embodiments of such a SMN. More concretely, those matching elements are three inductances and a 0 Ohms resistance comprised in four MN booster sections 5101, 5102, 5103, 5104 and an inductance and a capacitor comprised in a MN transceiver section 5105. More concretely, the four MN booster sections comprise a 0 Ohms resistance and three inductances of a value within the ranges 10 nH to 16 nH, 14 nH to 20 nH and 22 nH to 28 nH, preferably being within the 12 nH to 14 nH range, the 16 nH to 18 nH range and the 24 nH to 26 nH range, in other embodiments. FIGS. 52A and 52B show the matching elements combinations of the matching elements comprised in the four MN booster sections 5101, 5102, 5103, 5104 configured for matching a radiating system comprising the SMN at a low-frequency region going from 698 MHz to 960 MHz, comprising the sub-bands: from 698 to 748 MHz, from 746 to 803 MHz, from 824 to 894 MHz and from 880 to 960 MHz, and at a high-frequency region going from 1.71 to 2.2 GHz. As already described, the SMN also comprises a MN transceiver section 5105, connected between the switch and a transceiver, this section comprising two circuit components of values 1.7 nH and 3.7 pF, or in some embodiments an inductance of value within the 1.4 nH to 2 nH range and a capacitor of value within the 3.4 pF to 4 pF range. A particular example of a radiating system or a wireless device comprising the SMN, comprises a PCB featuring 53 mm×53 mm dimensions, and a modular multi-stage element, the modular multi-stage element being a multi-section component described in the patents US20200176855A1, EP3649697B1 and CN110870133A, and more concretely, being in some embodiments, the antenna component described and included in the embodiment from FIG. 29, or the one from FIG. 32 or FIG. 35, from the patents. This multi-stage or multi-section component is in some embodiments a TRIO mXTEND™ antenna component. More particularly, the multi-stage element comprised in this embodiment comprises three sections or stages, two of which are connected between them by a filter as it is shown in FIGS. 52A and 52B. The filter provided in FIGS. 52A and 52B is a high-frequencies filter resonating around 2 GHz that comprises an inductor of 11 nH and a capacitor of 0.5 pF, but another filter could have been used in similar embodiments or examples. FIGS. 52A and 52B illustrate the matching elements combinations implemented without connection of the MN transceiver section for each sub-band of operation. For matching the sub-bands going from 698 MHz to 748 MHz, from 746 MHz to 803 MHz and from 880 to 960 MHz, a PS (Parallel Series) configuration is used. For matching the sub-band going from 824 MHz to 894 MHz, a PS configuration comprising two components arranged in parallel between them in the series position is used. For matching the high-frequency band going from 1.71 GHz to 2.2 GHz, a series configuration comprising four components arranged in parallel between them in the series position is used. The values of the matching elements or circuit components combined in those configurations are the ones provided in FIG. 51 or previously described in the text in relation to FIG. 51. As seen in FIG. 52A, the matching elements combinations implemented for matching at the mentioned low-frequency sub-bands are characterized by comprising a first common parallel inductance, the first common parallel inductance being connected to the multi-stage element comprised in the radiating system and connected to a ground. So, this SMN embodiment is an example of a SMN comprising at least a MN booster section and a MN transceiver section that implements different matching networks comprising a first common parallel circuit component.

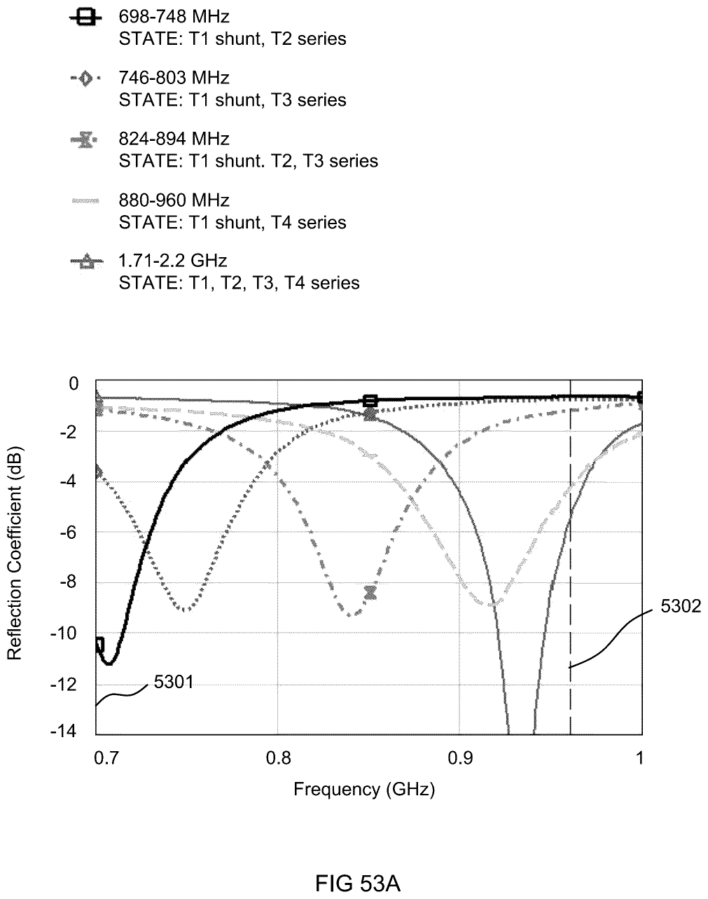

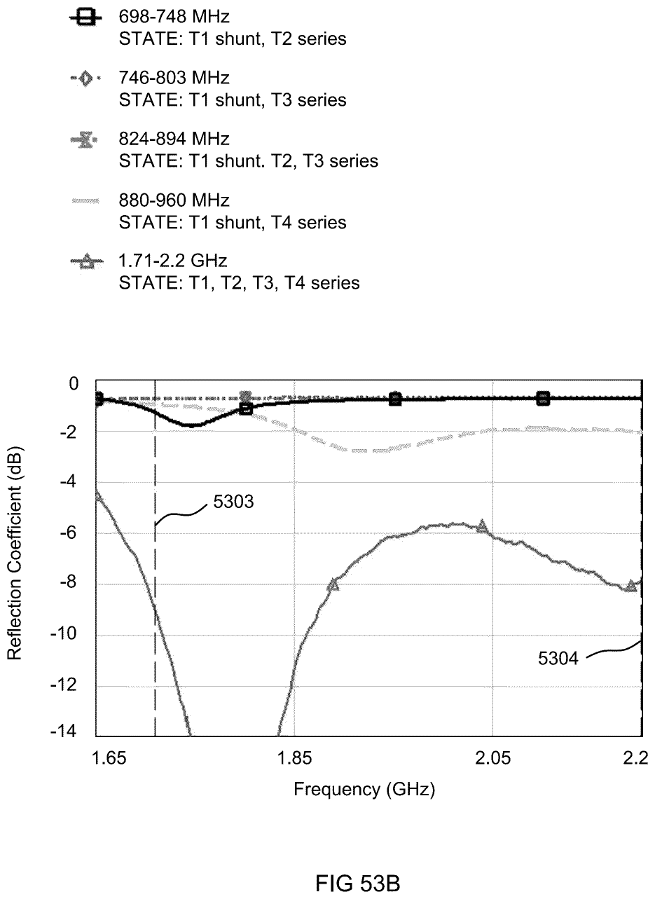

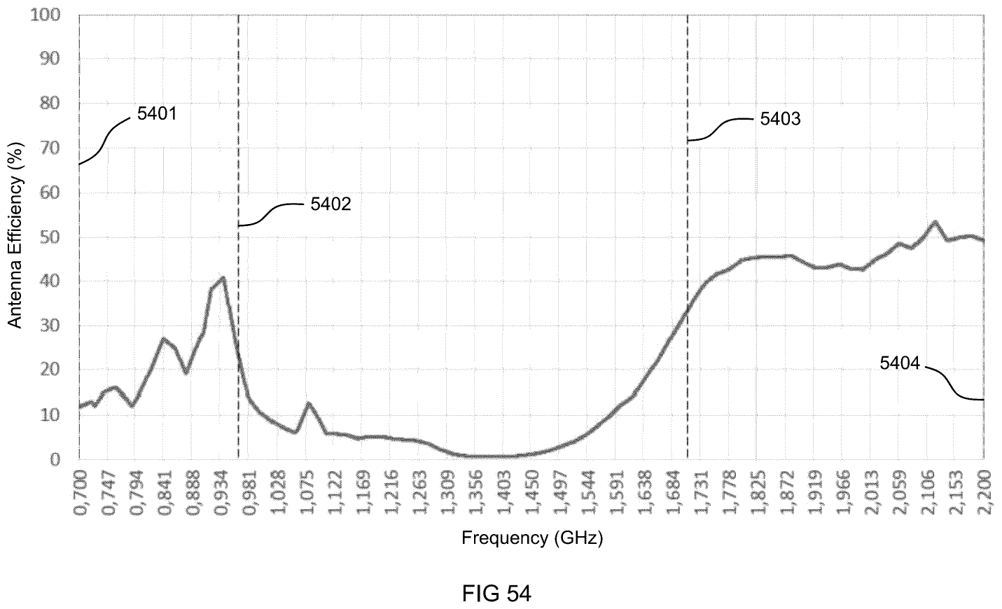

As already explained in this text, it has been found that by including a first parallel component that is common to the different configured matching networks, the matching impedance obtained before the MN transceiver section for every matching network can feature a value close to the matching impedances obtained for the other matching networks also before the MN transceiver section. Then, the different matchings at the different sub-bands can be easily completed with a common transceiver matching section, resulting in better reflection coefficients before the transceiver for all the operation sub-bands. The closer the matching impedances obtained before the MN transceiver section are between them and to a 50 Ohms impedance, the better reflection coefficients before the transceiver obtained and, so, the antenna efficiencies. Then, a UMN, a SMN or a SUMN comprising a common MN transceiver section for the different matching networks implemented with the UMN, the SMN or the SUMN, wherein the matching networks comprise a first or initial common parallel circuit component are advantageous embodiments of the present disclosure. The common parallel circuit component is, in some embodiments, an inductance, and in others, it can be a capacitor. For the particular example from FIG. 51, this common component is an inductance of 25 nH. FIGS. 53A and 53B provide the reflection coefficients obtained for the different sub-bands and frequency regions of operation (delimited by 5301 and 5302 in FIG. 53A and by 5303 and 5304 in FIG. 53B) of the example provided in FIG. 51 and FIGS. 52A and 52B. FIG. 54 shows the antenna efficiency obtained for the low-frequency and the high-frequency regions (delimited by the lines 5401 and 5402, and by 5403 and 5404, respectively). Good antenna efficiencies are obtained, particularly at the low-frequency region, which has been divided in sub-bands of operation. Antenna efficiencies between 10% and 40% obtained at low frequencies, as it is the frequency region going from 698 MHz to 960 MHz, are good efficiencies. By dividing the frequency region in sub-bands of operation, efficiency values up to 40%, within the mentioned range −10% to 40%—have been obtained.

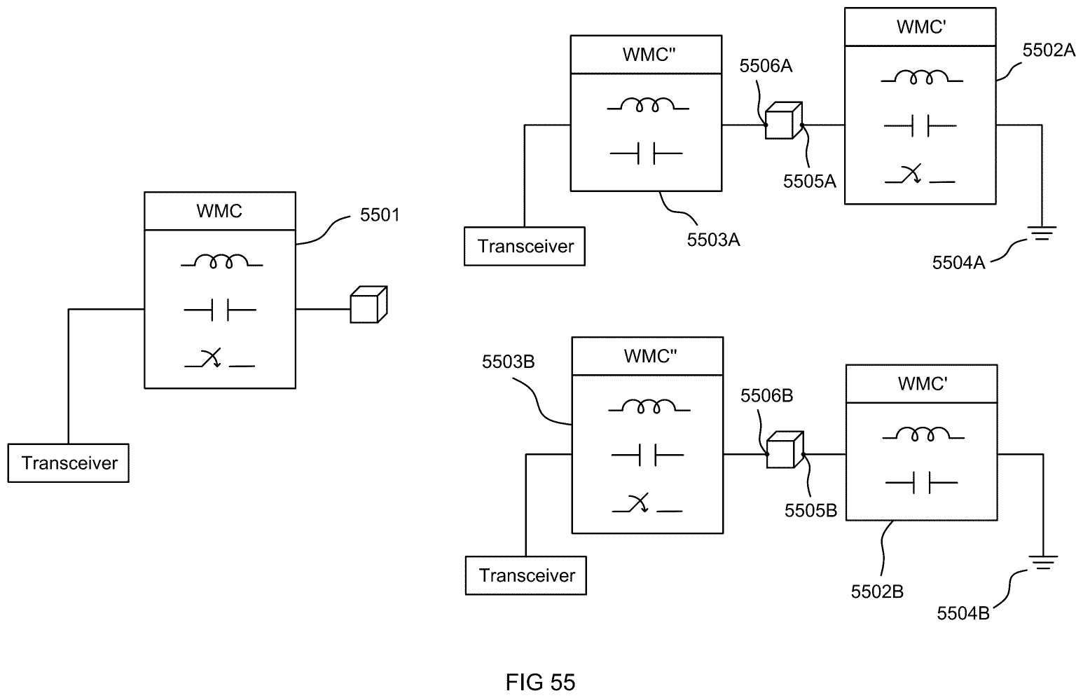

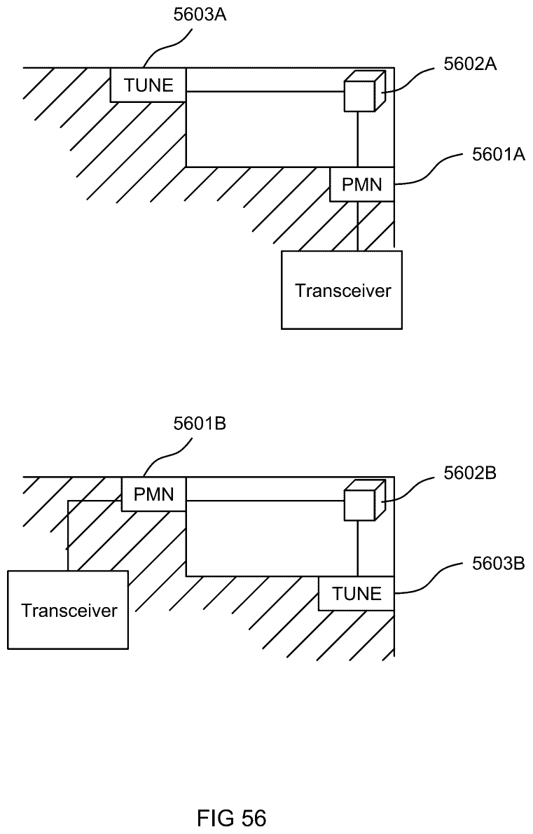

FIG. 55 provides some schematics of a radiating system according to the present disclosure. Different configurations of the WMC comprised in those radiating systems are illustrated. Some embodiments comprise a WMC comprising only one section 5501 that is connected to non-resonant element such as for instance a radiation booster comprised in the radiating system and to the transceiver. Other embodiments comprise a WMC comprising at least two sections: a first section WMC′, 5502A, 5502B connected to a ground 5504A, 5504B and to a first connection point 5505A, 5505B comprised in the radiation booster comprised in the radiating system, and a second section WMC″, 5503A, 5503B connected to a transceiver and to a second connection point 5506A, 5506B comprised in the radiation booster or non-resonant element or to a strip or connection means connecting to the radiation booster or non-radiating element. In some of these last embodiments, at least one of the sections comprised in the WMC comprises an active or a tunable element, in other embodiments, two sections comprised in the WMC comprise an active or a tunable element, and in other embodiments, one of the sections comprises at least one electronic component wherein, all the electronic components are passive components. Then, some embodiments can comprise more than one section including a tunable or an active component. In some embodiments, it is a tunable section the one connected to ground, and in other embodiments, it is a passive matching network the one connected to ground. FIG. 56 provides radiating system embodiments comprising a WMC that comprises at least two different sections, WMC′ and WMC″, wherein one is connected to a ground. More particularly, those embodiments comprise a passive matching network 5601A, 5601B connected to a transceiver and to a first connection point comprised in the radiation booster or non-resonant element 5602A, 5602B, and a tunable part 5603A, 5603B connected to a ground plane layer and to a second connection point comprised in the radiation booster or to a strip or connection means connecting to the radiation booster or non-radiating element.

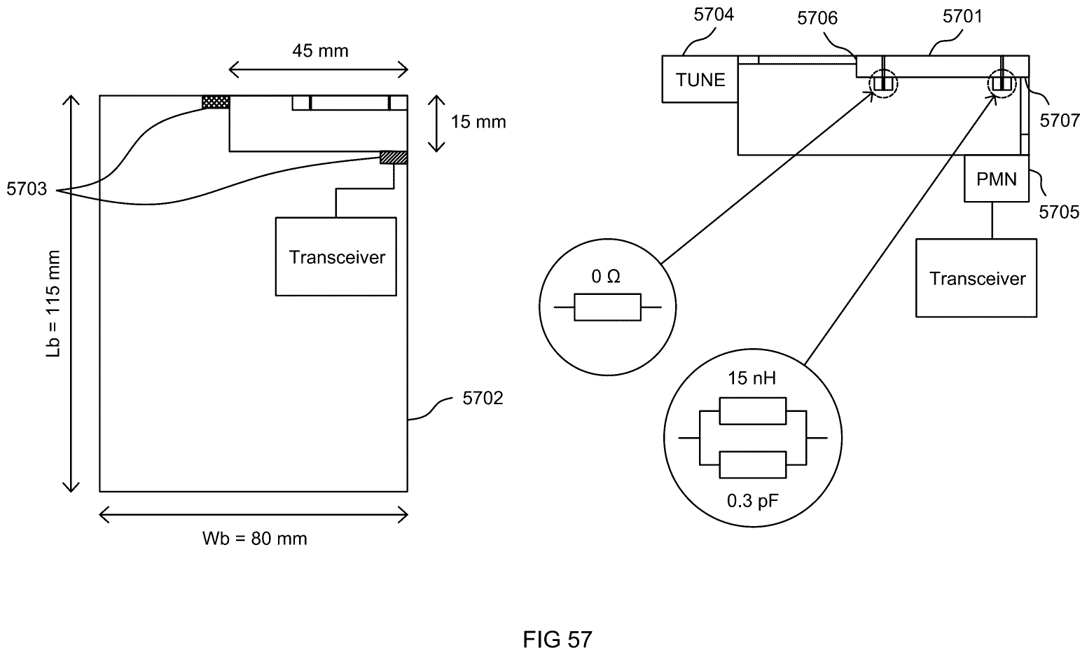

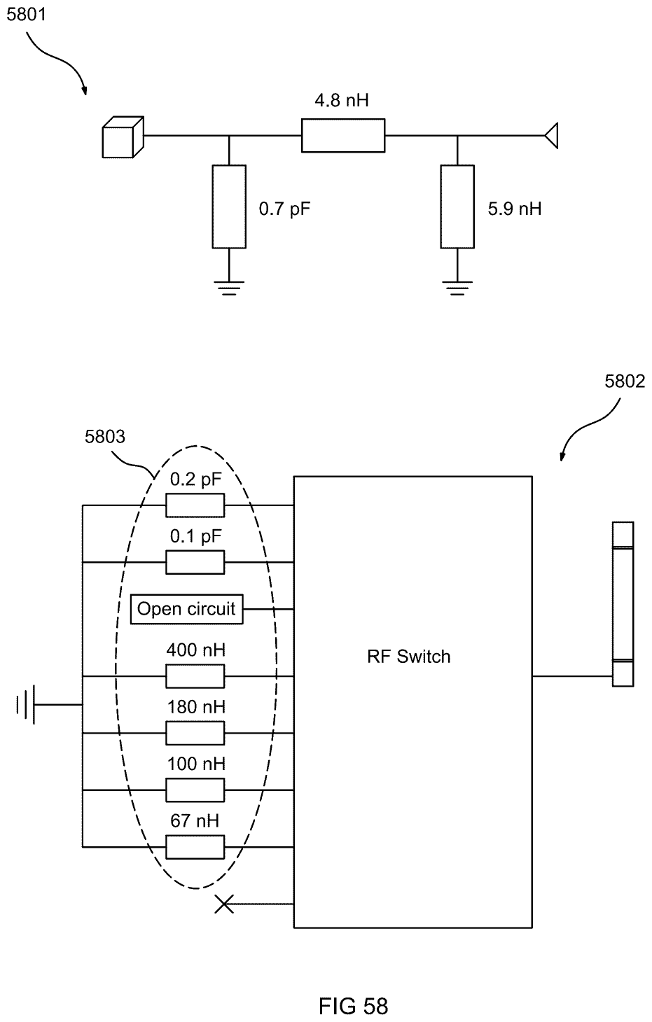

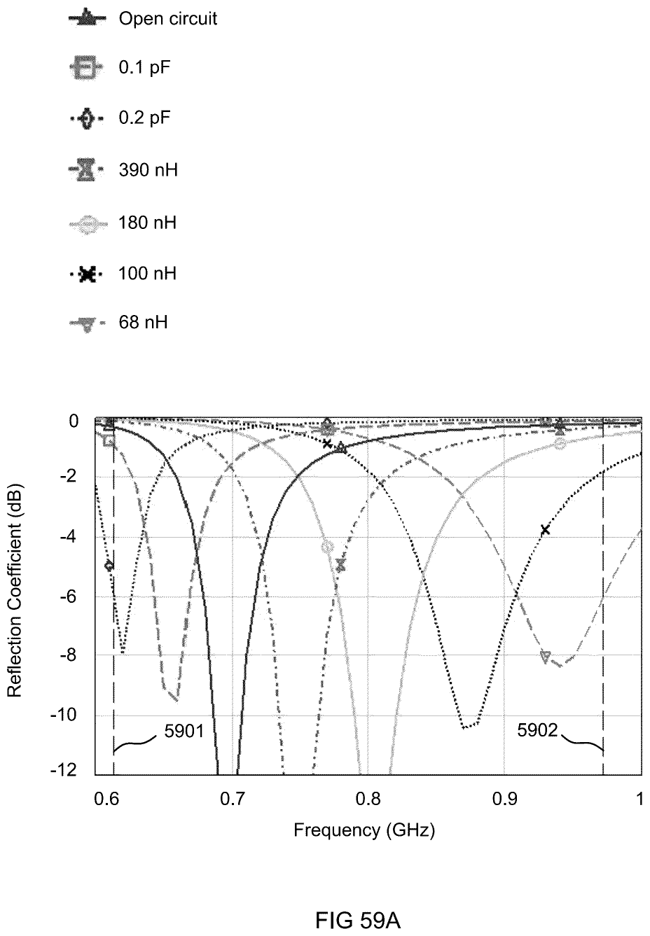

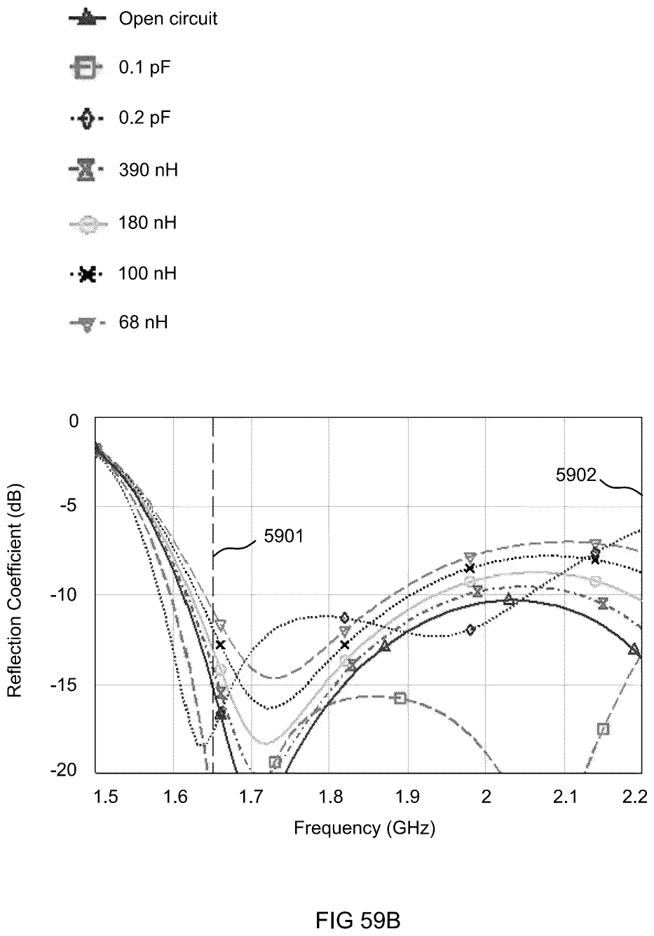

FIG. 57 shows a radiating system comprising a modular multi-stage element 5701, the modular multi-stage element being a multi-section component described in the patents US20200176855A1, EP3649697B1 and CN110870133A, and more concretely, being in some embodiments, the antenna component described and included in the embodiment from FIG. 29, or the one from FIG. 32 or FIG. 35, from the patents. A multi-stage or multi-section component is, in some embodiments, a TRIO mXTEND™ antenna component. The radiating system also comprises a ground plane layer 5702 and a wireless matching core (WMC) 5703, the WMC comprising a tunable part 5704 and a passive matching network 5705. The tunable part is connected to the ground plane layer and to a first point 5706 comprised in the multi-stage element, and the passive matching network is connected to a transceiver and to a second point 5707 comprised in the multi-stage element. In the detail provided in FIG. 57 it is disclosed how the different stages of the multi-stage element are connected between them, a 0 ohms resistance is used to connect a first stage or section to the middle stage or section of the multi-stage element, and a filter comprising a 15 nH inductance and a 0.3 pF capacitance is used for connecting a second stage or section also to the middle stage. The dimensions of the PCB containing the radiating system here described are also included in the figure, as well as the dimensions of the clearance area (45 mm×15 mm) where the multi-stage element is allocated. FIG. 58 provides the passive matching network and the tunable part included in the WMC comprised in the embodiment from FIG. 57. The element 5801 represents the passive matching network and the element 5802 represents the tunable part. The passive matching network features a PSP (Parallel Series Parallel) configuration and comprises a first parallel capacitor of a value within the range 0.6 pF to 0.8 pF, followed by a series inductance of a value within the range 4.5 nH to 5.1 nH, and a parallel inductance of a value within the range 5.5 nH to 6.3 nH. In a preferred example the first parallel capacitor is 0.7 pF, the following series inductance is 4.8 nH and the last parallel inductance is 5.9 nH. The tunable part 5802 comprises a switch connected to the multi-stage element and to different matching elements 5803 that are connected to the ground plane layer. Those matching elements are capacitors and inductances of the values provided in the FIG. 58. One of the output ports or throughs used is connected to an open circuit. FIGS. 59A and 59B provide the input reflection coefficient obtained for the embodiment from FIG. 57 that comprises the WMC shown in FIG. 58. The low-frequency region—LFR— covered goes from 617 MHz (dashed vertical line 5901) to 960 MHz (dashed vertical line 5902). The high-frequency region—HFR— covered goes from 1.695 GHz (dashed vertical line 5903) to 2.22 GHz (dashed vertical line 5904).

A radiating system according to the disclosure like the one provided in FIG. 33, comprising a SUMN like the one illustrated in FIG. 34 has been placed above different platforms of different materials.

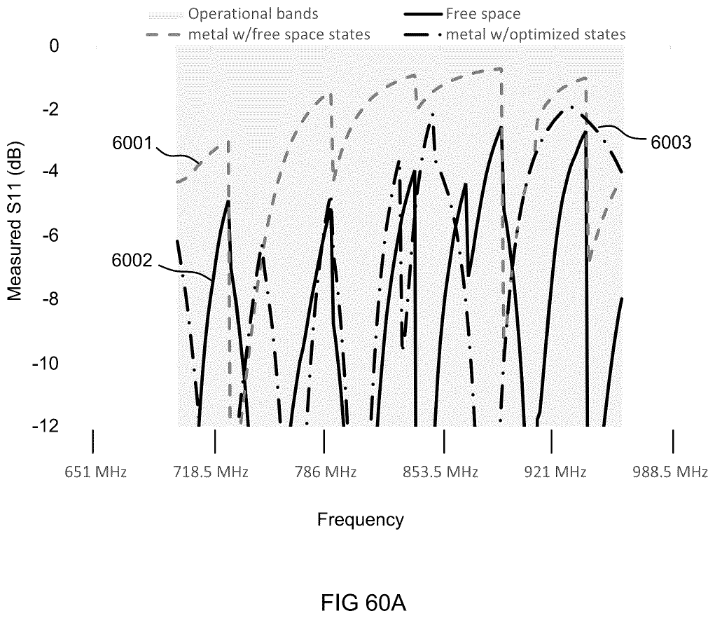

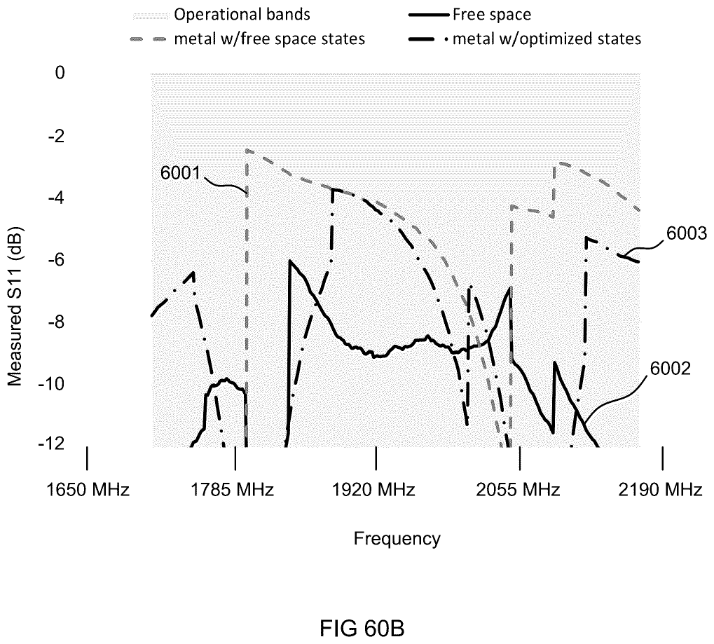

FIGS. 60A and 60B provide the input reflection coefficient obtained when it is placed at 7 mm above a metallic plate of 400 mm×400 mm. The results are compared to the response obtained at free space. It is clearly observed that the mismatch response when the radiating system is placed above the metallic plate, see curve 6001, gets worse with respect to the free space input reflection coefficient, curve 6002, when using the same switch states. The input reflection coefficient is improved, see curve 6003, when the switch states are programed for obtaining an optimized response when the radiating system is placed above the metallic plate.

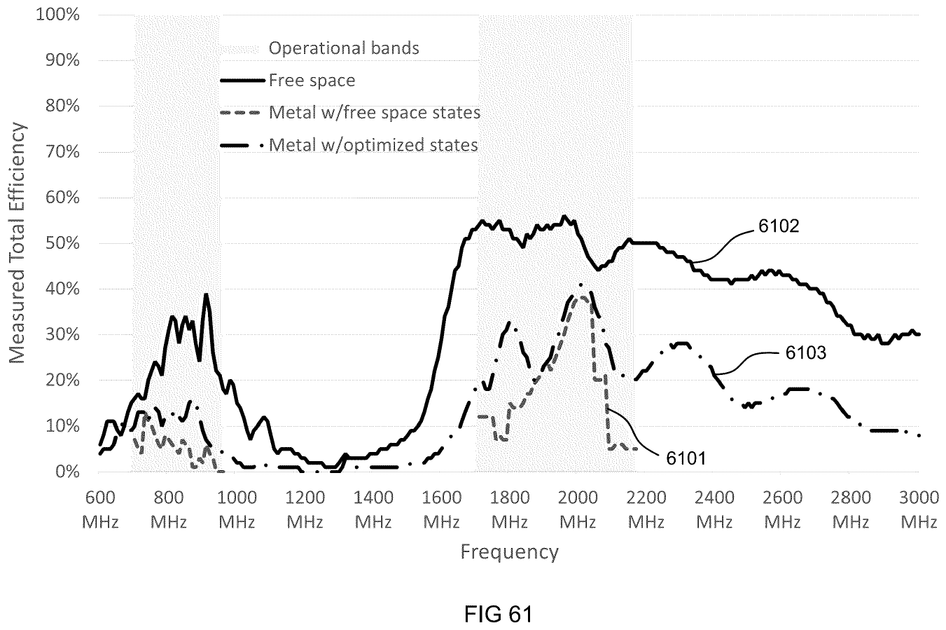

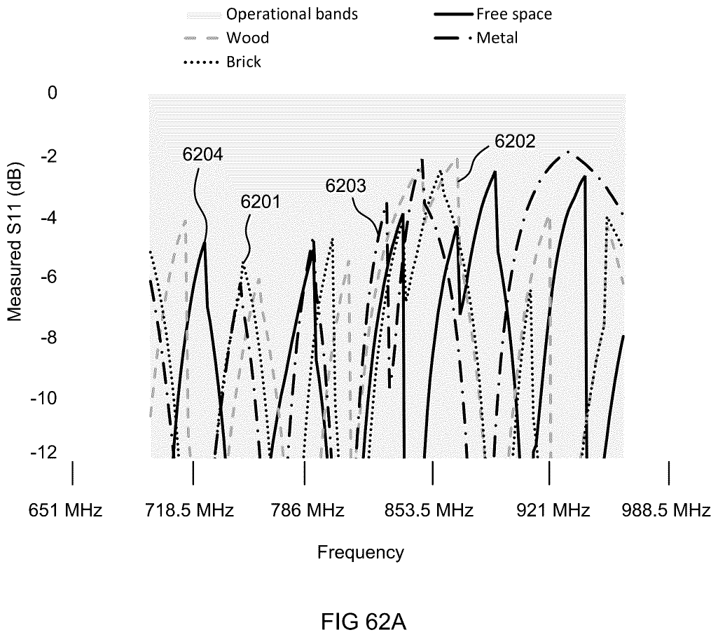

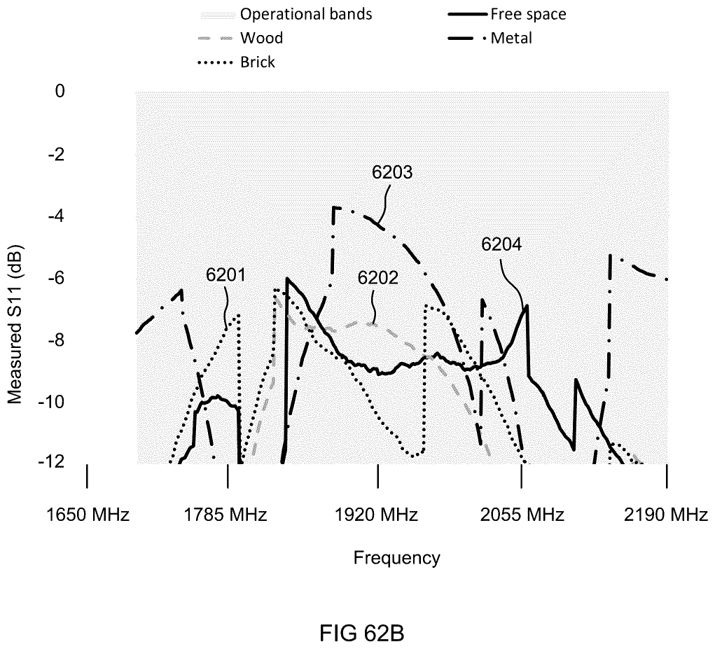

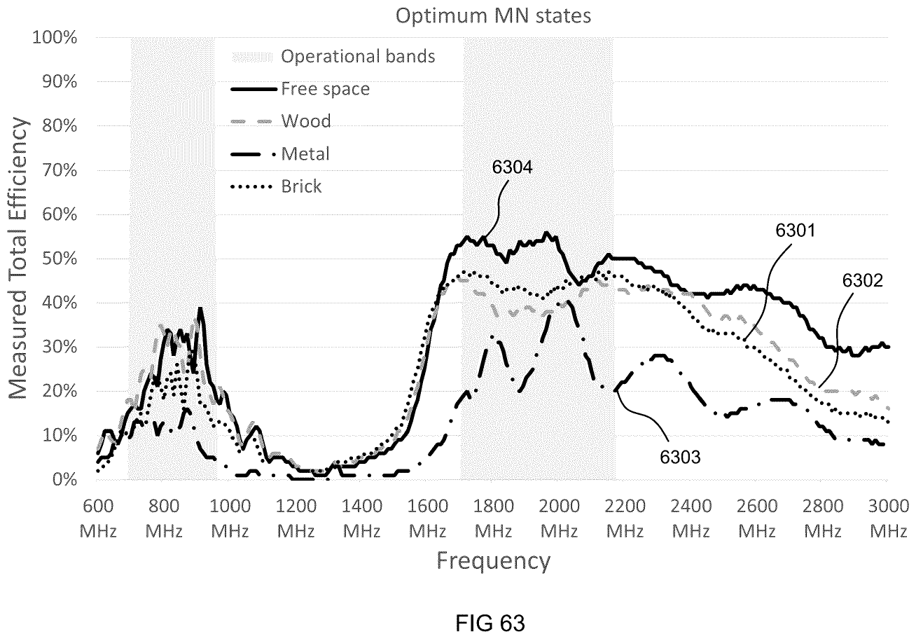

FIG. 60A provides the input reflection coefficient at LFR and FIG. 60B provides the input reflection coefficient at HFR. FIG. 61 provides the antenna efficiency measured for the radiating system from FIG. 33, comprising the SUMN from FIG. 34, when placed at 7 mm from a metallic plate of 400 mm×400 mm. It is shown that the antenna efficiency obtained is very poor at LFR and at some frequencies of HFR, see curve 6101. Compared to the response at free space, curve 6102, the input reflection coefficient decreases considerably, both at LFR and at HFR. When the switch states are optimized to improve the performance when the radiating system is placed above the metallic plate, the antenna efficiency is clearly increased both at LFR and at HFR, see curve 6103. FIGS. 62A and 62B and FIG. 63 show the input reflection coefficients and the antenna efficiencies measured when the radiating system is placed at 7 mm from a platform of different materials (distance measured between the platform and the bottom layer of the PCB comprised in the radiating system). The PCB features a 50 mm length×50 mm width and comprises a clearance area of 45 mm width×16 mm length that contains a modular multi-stage element 3405, the modular multi-stage element being a multi-section component described in the patents US20200176855A1, EP3649697B1 and CN110870133A, and more concretely, being in some embodiments, the antenna component described and included in the embodiment from FIG. 29, or the one from FIG. 32 or FIG. 35, from the patents. This multi-stage or multi-section component is in some embodiments a TRIO mXTEND™ antenna component. The different platforms tested are a brick, a metallic plate and a wood platform. The brick used is 40 cm×40 cm of 3.8 mm thickness, the metallic plate is 40 cm×40 cm of 2 mm thickness and the wood platform is 40 cm×40 cm of 15 mm thickness. FIGS. 62A and 62B show the measured input reflection coefficient obtained for the different cases and FIG. 63 provides the measured antenna efficiency obtained for the same cases. Those cases are compared to free space results. The SUMN comprised in the radiating system located above the different platforms has been configured for each platform case so that an optimum performance is obtained. The SUMN comprised in the WMC included in this radiating system embodiments is the one provided in FIG. 34. The switch states configured are different for each case. The antenna efficiency averages obtained for the different materials are a 26.48% for wood, a 10.89% for metal and a 18.85% for the brick at the LFR going from 698 MHz to 960 MHz, and a 40.51% for wood, a 27.74% for metal and a 44.36% above the brick at the HFR going from 1.71 GHz to 2.17 GHz. So, a radiating system able to operate at different environments has been implemented.

What is claimed is:

1. A wireless device comprising a radiating system that comprises:
a non-resonant element;
a ground plane element;
a transceiver;
a wireless matching core comprising a self-adaptive universal matching network configured to self-adapt upon reception of an electrical signal for acting thereon, the self-adaptive universal matching network comprising:
a reconfigurable circuit component configured to support a plurality of states, the reconfigurable circuit component comprising an RF switch;
first and second matching network sections each connected to the reconfigurable circuit component and the non-resonant element;
a third matching network section connected to the reconfigurable circuit component and the transceiver; and
a matching element in the first matching network sections or the second matching network section;
a processor;
a memory storing a table with a plurality of matching network configurations; and
an energy-supplying device;
wherein the processor is configured to act on the reconfigurable circuit component to select a particular state thereof by selecting a particular matching network configuration among the plurality of matching network configurations; and
wherein the self-adaptive universal matching network is configured to provide impedance matching in at least at one frequency band within at least a frequency region for the wireless device.

2. The wireless device of claim 1, wherein the RF switch is a multi-path switch comprising four throughs or outputs, wherein the first and second matching network sections comprise at least four matching network sections with each section being connected to a different through or output of the RF switch.

3. The wireless device of claim 1, wherein the matching element is connected to a ground internal connection of the RF switch.

4. The wireless device of claim 1, wherein at least one of the first, second, and third matching network sections comprises a plurality of circuit elements.

5. The wireless device of claim 4, wherein the plurality of circuit elements includes an inductor.

6. The wireless device of claim 1, wherein the plurality of matching network configurations include low-frequency matching network configurations for operating at a low-frequency region, which include a common circuit component connected to the non-resonant element and to ground.

7. The wireless device of claim 1, wherein the first matching network section or the second matching network section comprises a circuit component substantially equal to a circuit component of the third matching network section.

8. The wireless device of claim 1, wherein the first matching network section or the second matching network section comprises a 0 ohms resistance or no circuit components.

9. The wireless device of claim 1, wherein the self-adaptive universal matching network enables operation of the radiating system when the wireless device is mounted on a platform of a material among a plurality of materials.

10. A wireless device comprising a radiating system that comprises:
a non-resonant element;
a ground plane element;
a transceiver;
a wireless matching core comprising a self-adaptive universal matching network configured to self-adapt upon reception of an electrical signal for acting thereon, the self-adaptive universal matching network comprising:
a reconfigurable circuit component configured to support a plurality of states, the reconfigurable circuit component comprising an RF switch; and
a matching element;
a processor;
a memory storing a table with a plurality of matching network configurations; and
an energy-supplying device;
wherein the processor is configured to act on the reconfigurable circuit component to select a particular state thereof by selecting a particular matching network configuration among the plurality of matching network configurations; and
wherein the self-adaptive universal matching network is configured to provide impedance matching in at least at one frequency band within at least a frequency region for the wireless device.

11. The wireless device of claim 10, wherein the self-adaptive universal matching network is configured in an SPSPSP configuration, S being a series matching circuit and P being a parallel matching circuit, each matching circuit comprising one or more circuit components.

12. The wireless device of claim 11, wherein the self-adaptive universal matching network is in a System in a Package or in a System on a Soc.

13. The wireless device of claim 11, wherein the SPSPSP configuration of matching circuits is an SPSPPSS configuration of circuit components.

14. The wireless device of claim 10, wherein the self-adaptive universal matching network comprises nine circuit components arranged in an SPSPSPPSS configuration, S being a series matching circuit and P being a parallel matching circuit, each matching circuit comprising one or more circuit components.

15. The wireless device of claim 10, wherein one state of the reconfigurable circuit component configures the self-adaptive universal matching network in a multiband matching network configuration.

16. The wireless device of claim 10, wherein one state of the reconfigurable circuit component configures the self-adaptive universal matching network in a single-band matching network configuration.

17. The wireless device of claim 10, wherein a first state of the reconfigurable circuit component configures the self-adaptive universal matching network in a multiband matching network configuration and a second state of the reconfigurable circuit component configures the self-adaptive universal matching network in a single-band matching network configuration.

18. The wireless device of claim 17, wherein both the multiband matching network configuration and the single-band matching network configuration are universal matching networks.

19. The wireless device of claim 17, wherein the multiband matching network configuration provides operation at mobile frequencies, and the single-band matching network configuration provides operation at sub 1 GHz frequencies.

20. The wireless device of claim 10, further comprising:
a sensor to measure an environment-related parameter or physical magnitude corresponding to environmental conditions that the radiating system is in, wherein the processor is configured to process the environment-related parameter or physical magnitude from the sensor to determine environmental conditions that the radiating system is in, and wherein the processor is configured processes the table based on the environmental conditions that the radiating system is in.

21. The wireless device of claim 10, wherein the processor is configured to process the table based on a size of the ground plane element.

22. The wireless device of claim 10, wherein the processor is configured to select a state of the plurality of states based on impedance matching.

23. A method comprising:
storing a table with a plurality of matching network configurations in a memory of a wireless device;
providing, by a processor of the wireless device, at least one electrical signal for acting on a reconfigurable electronic component of a self-adaptive universal matching network of a radiating system of the wireless device for selecting a particular state thereof for selecting a particular matching network configuration of the plurality of matching network configurations by processing the table according to a predetermined matching network configuration selection process;
wherein the radiating system comprises:
a non-resonant element;
a ground plane element;
a transceiver;
a wireless matching core comprising the self-adaptive universal matching network that comprises:
a reconfigurable electronic component configured to support a plurality of states, the reconfigurable electronic component comprising an RF switch;
first and second matching network sections each connected to the reconfigurable electronic component and the non-resonant element;
a third matching network section connected to the reconfigurable electronic component and the transceiver; and
a matching element in first matching network section or the second matching network section; and
an energy-supplying device;
wherein the self-adaptive universal matching network is configured to provide impedance matching in at least at one frequency band within at least a frequency region, for the wireless device.

24. The method of claim 23, wherein the wireless device comprises a sensor to measure an environment-related parameter or physical magnitude corresponding to environmental conditions that the radiating system is in, the method further comprising:
processing, by the processor, the environment-related parameter or physical magnitude to determine environmental conditions that the radiating system is in, wherein the predetermined matching network configuration selection process comprises processing the table based on the environmental conditions that the radiating system is in.

25. The method of claim 24, further comprising arranging the radiating system on a platform of a predetermined material, wherein processing the table comprises selecting a state of the plurality of states that is associated with the predetermined material of the platform.

26. The method of claim 24, wherein the predetermined matching network configuration selection process comprises processing the table based on a size of the ground plane element.

27. The method of claim 26, further comprising, upon arranging the radiating system in the wireless device, providing data to the processor indicative of the size of the ground plane element.

28. The method of claim 23, wherein the predetermined matching network configuration selection process comprises sweeping over some or all states of the plurality of states to subsequently select a state of the plurality of states based on an impedance matching achieved by each swept state.

29. A computer program product comprising instructions which, when the program is executed by at least one processor of a wireless device, cause the wireless device to carry out the method of claim 23.
